(19) United States
(12) Patent Application Publication
(10) Pub. No.: US 2026/0282462 A1
(43) Pub. Date: Sep. 17, 2026

(54) SEMICONDUCTOR DEVICE

(71) Applicant: ROHM CO., LTD., Kyoto-shi (JP)

(72) Inventor: Ryoichi MAKINO, Kyoto-shi (JP)

(73) Assignee: ROHM CO., LTD., Kyoto-shi (JP)

(21) Appl. No.: 19/683,743

(22) Filed: May 21, 2026

Related U.S. Application Data
(63) Continuation of application No. PCT/JP2024/042409, filed on Nov. 29, 2024.

(30) Foreign Application Priority Data
Nov. 30, 2023 (JP) 2023-203160

(51) Int. Cl. H10D 62/10; H10D 30/66; H10D 62/60; H10D 62/832; H10D 64/27

(52) U.S. Cl. CPC H10D 62/107; H10D 30/665; H10D 30/668; H10D 62/126; H10D 62/8325; H10D 64/518; H10D 62/60

(57) ABSTRACT

There is provided a semiconductor device including a chip that has a main surface, a semiconductor region of a first conductivity type that is formed in a surface layer portion of the main surface, an active region that is provided in an inner portion of the main surface, an outer peripheral region that is provided in a peripheral edge portion of the main surface, a separating structure of a trench type that is formed in the main surface so as to be positioned in the semiconductor region and demarcates the active region and the outer peripheral region, and a well region of a second conductivity type that is formed in a region below the separating structure so as to be positioned in the semiconductor region and is electrically connected to the semiconductor region.

### CROSS-REFERENCE TO RELATED APPLICATIONS

The present application is a bypass continuation of International Patent Application No. PCT/JP2024/042409 filed on Nov. 29, 2024, which claims priority to Japanese Patent Application No. 2023-203160 filed on Nov. 30, 2023 in the Japan Patent Office, and the entire contents of those applications are hereby incorporated herein by reference.

### BACKGROUND

### 1. Field of the Disclosure

The present disclosure relates to a semiconductor device.

### 2. Description of the Related Art

US 2008/0277669 A1 discloses a semiconductor device having a terminal structure in an outer peripheral region of a drift layer.

### BRIEF DESCRIPTION OF THE DRAWINGS

FIG. 1 is a plan view illustrating a semiconductor device according to a first embodiment.

FIG. 2 is a sectional view taken along line II-II illustrated in FIG. 1.

FIG. 3 is a plan view illustrating a layout example of a first main surface.

FIG. 4 is an enlarged plan view illustrating one main portion of the first main surface illustrated in FIG. 3.

FIG. 5 is an enlarged plan view illustrating one main portion of the first main surface illustrated in FIG. 3.

FIG. 6 is a sectional view taken along line VI-VI illustrated in FIG. 4.

FIG. 7 is a sectional view taken along line VII-VII illustrated in FIG. 4.

FIG. 8 is an enlarged sectional view of one region illustrated in FIG. 6.

FIG. 9 is a sectional view illustrating a structure taken along line IX-IX illustrated in FIG. together with a deep well region according to a first configuration example.

FIG. 10 is a sectional view illustrating a sectional structure of an outer peripheral region taken along line X-X illustrated in FIG. 1.

FIG. 11A is a sectional view illustrating a deep well region according to a second configuration example.

FIG. 11B is a sectional view illustrating a deep well region according to a third configuration example.

FIG. 11C is a sectional view illustrating a deep well region according to a fourth configuration example.

FIG. 11D is a sectional view illustrating a deep well region according to a fifth configuration example.

FIG. 11E is a sectional view illustrating a deep well region according to a sixth configuration example.

FIG. 11F is a sectional view illustrating a deep well region according to a seventh configuration example.

FIG. 11G is a sectional view illustrating a deep well region according to an eighth configuration example.

FIG. 12 is a sectional view illustrating an active region of a semiconductor device according to a second embodiment.

FIG. 13 is a sectional view illustrating a deep well region of the semiconductor device illustrated in FIG. 12.

FIG. 14 is a sectional view illustrating an outer peripheral region of the semiconductor device illustrated in FIG. 12.

FIG. 15 is an enlarged plan view illustrating an active region of a semiconductor device according to a third embodiment.

FIG. 16 is a sectional view taken along line XVI-XVI illustrated in FIG. 15.

FIG. 17 is a sectional view taken along line XVII-XVII illustrated in FIG. 15.

FIG. 18 is a sectional view illustrating an outer peripheral region of the semiconductor device illustrated in FIG. 15.

FIG. 19 is a plan view illustrating a semiconductor device according to a fourth embodiment.

FIG. 20 is a sectional view illustrating a peripheral edge portion of an active region of the semiconductor device illustrated in FIG. 19 together with a terminal region according to a first configuration example.

FIG. 21A is a sectional view illustrating a terminal region according to a second configuration example.

FIG. 21B is a sectional view illustrating a terminal region according to a third configuration example.

FIG. 21C is a sectional view illustrating a terminal region according to a fourth configuration example.

FIG. 21D is a sectional view illustrating a terminal region according to a fifth configuration example.

FIG. 21E is a sectional view illustrating a terminal region according to a sixth configuration example.

FIG. 21F is a sectional view illustrating a terminal region according to a seventh configuration example.

FIG. 22 is a sectional view illustrating an active region of a semiconductor device according to a fifth embodiment.

FIG. 23 is a sectional view illustrating a peripheral edge portion of an active region of the semiconductor device illustrated in FIG. 22 together with the terminal region according to the first configuration example.

FIG. 24 is a sectional view illustrating an active region of a semiconductor device according to a sixth embodiment.

FIG. 25 is a sectional view illustrating a peripheral edge portion of an active region of the semiconductor device illustrated in FIG. 24 together with the terminal region according to the first configuration example.

FIG. 26 is a sectional view illustrating a semiconductor device according to a modification example.

### DETAILED DESCRIPTION OF THE PREFERRED EMBODIMENTS

Hereinafter, specific embodiments shall be described in detail with reference to attached drawings. The attached drawings are all schematic views and are not strictly illustrated, and relative positional relationships, scales, proportions, angles and the like thereof do not always match. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially equal” is used in this description, the wording includes a numerical value (shape) equal to a numerical value (shape) of a comparison target and also includes numerical errors (shape errors) in a range of =10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” The “n-type” may be referred to as the “first conductivity type” and the “p-type” may be referred to as the “second conductivity type” instead. The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

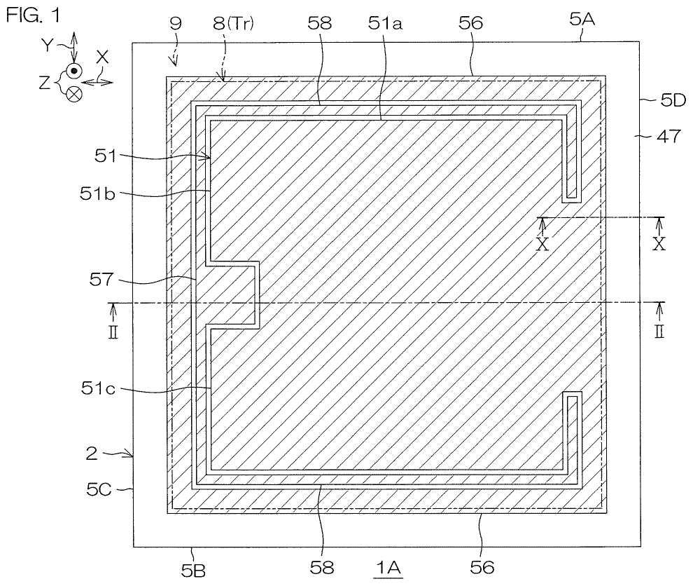

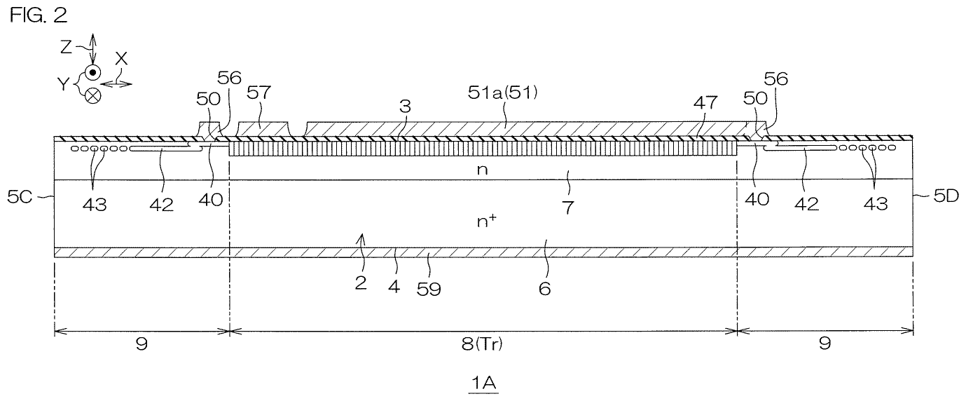

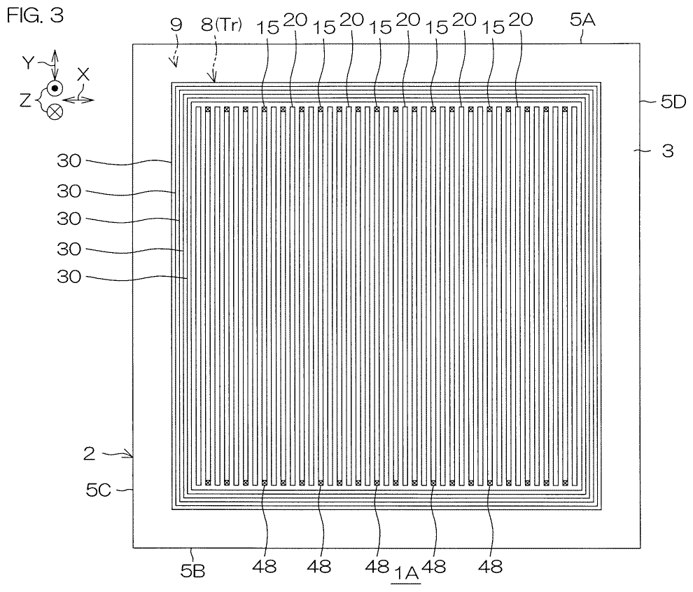

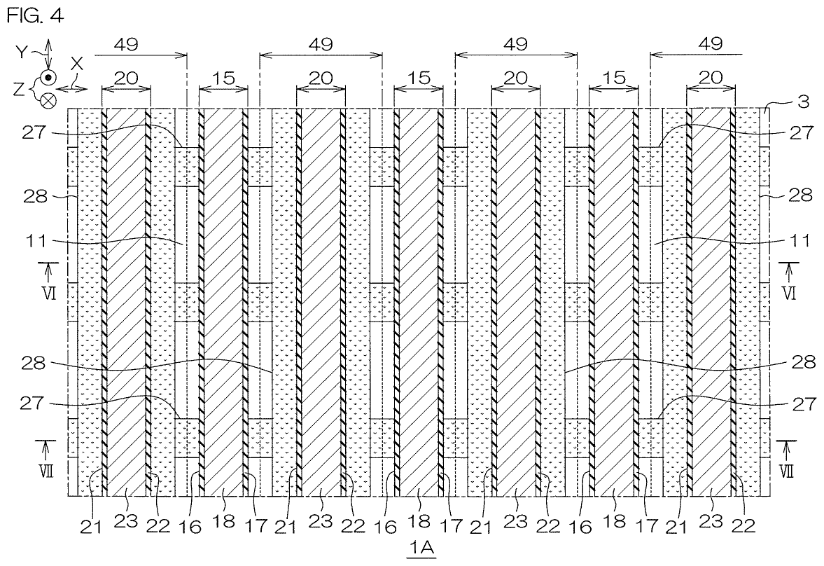

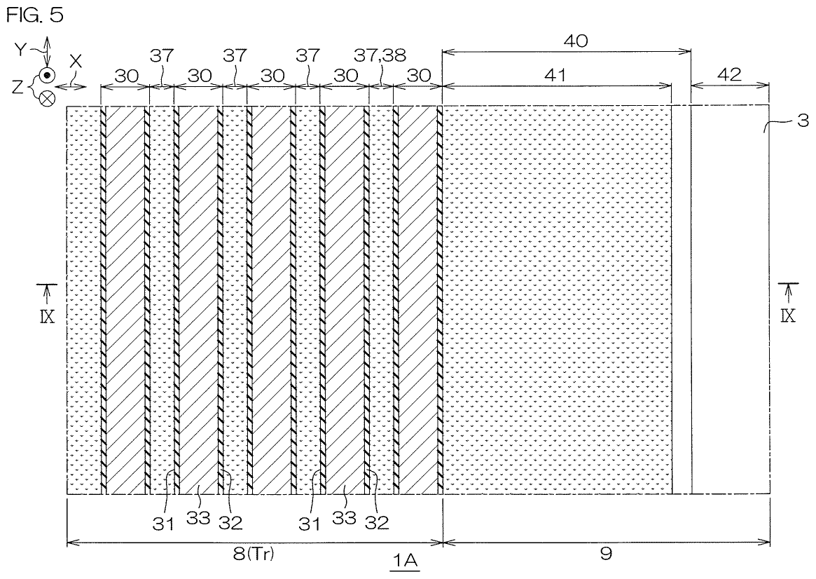

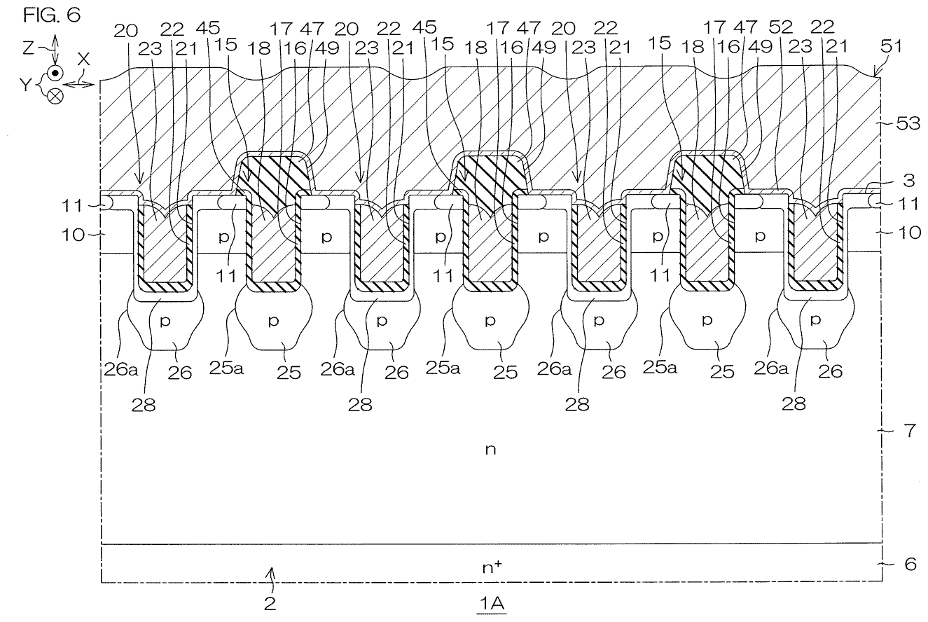

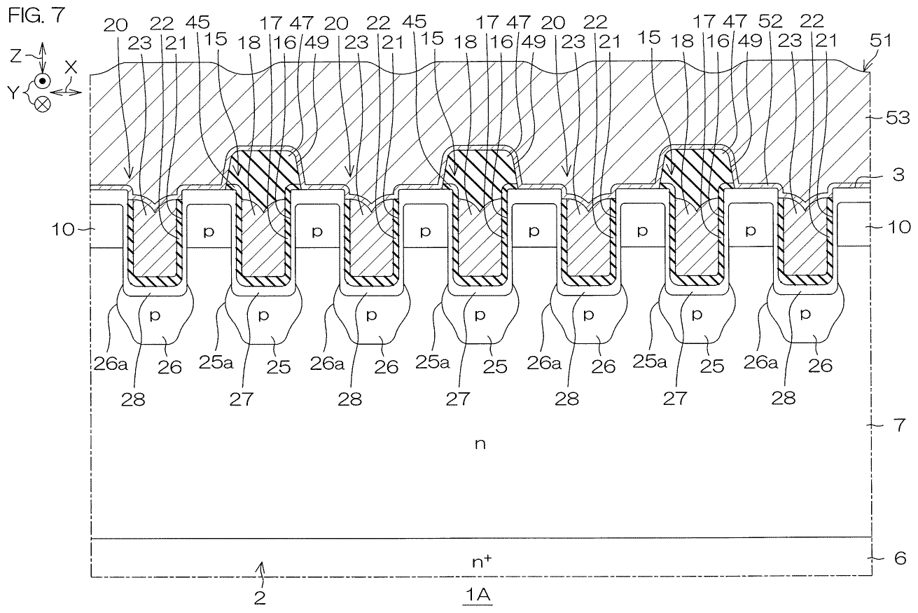

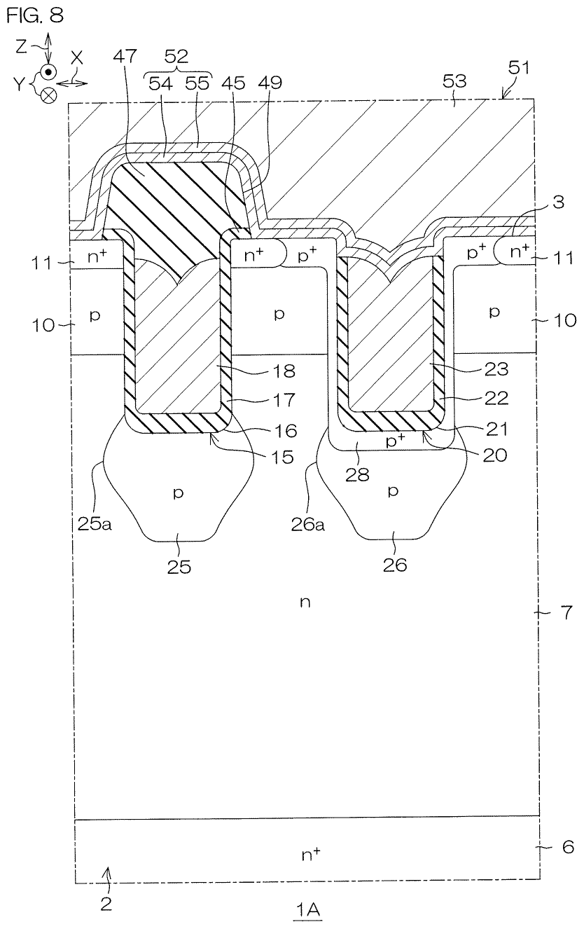

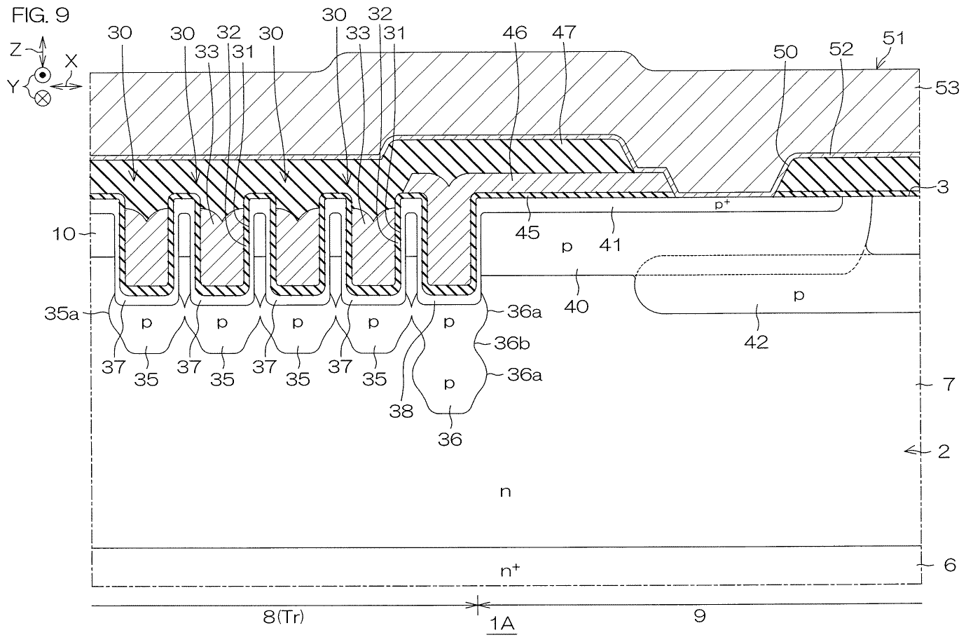

FIG. 1 is a plan view illustrating a semiconductor device 1A according to a first embodiment. FIG. 2 is a sectional view taken along line II-II illustrated in FIG. 1. FIG. 3 is a plan view illustrating a layout example of a first main surface 3. FIG. 4 is an enlarged plan view illustrating one main portion of the first main surface 3 illustrated in FIG. 3. FIG. 5 is an enlarged plan view illustrating one main portion of the first main surface 3 illustrated in FIG. 3. FIG. 6 is a sectional view taken along line VI-VI illustrated in FIG. 4. FIG. 7 is a sectional view taken along line VII-VII illustrated in FIG. 4. FIG. 8 is an enlarged sectional view of one region illustrated in FIG. 6. FIG. 9 is a sectional view taken along line IX-IX illustrated in FIG. 5.

Referring to FIG. 1 to FIG. 9, a semiconductor device 1A is a semiconductor switching device having a transistor structure Tr of an insulated gate type as an example of a device structure. The transistor structure Tr has a trench gate type vertical structure.

The semiconductor device 1A includes a chip 2 formed in a hexahedron shape (specifically, a rectangular parallelepiped shape). In this embodiment, the chip 2 includes a monocrystal of a wide bandgap semiconductor. That is, the semiconductor device 1A is a “wide bandgap semiconductor device.” The chip 2 may also be referred to as a “semiconductor chip” or a “wide bandgap semiconductor chip,” etc.

The wide bandgap semiconductor is a semiconductor that has a bandgap exceeding a bandgap of Si (silicon). GaN (gallium nitride), SiC (silicon carbide), C (diamond), etc., can be given as examples of the wide bandgap semiconductor. In this embodiment, the chip 2 is an “SiC chip” that includes, as an example of the wide bandgap semiconductor, an SiC monocrystal that is a hexagonal crystal. That is, the semiconductor device 1A is an “SiC semiconductor device.”

The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 includes the 4H-SiC monocrystal is given, but the chip 2 may include another polytype instead.

The chip 2 has the first main surface 3 on one side, a second main surface 4 on the other side, and first to fourth side surfaces 5A to 5D connected to the first main surface 3 and the second main surface 4. In a plan view as viewed from a vertical direction Z (hereinafter referred to simply as “plan view”), the first main surface 3 and the second main surface 4 are formed in quadrangle shapes. The vertical direction Z is also a thickness direction of the chip 2.

The first main surface 3 and the second main surface 4 are preferably formed by c-planes of the SiC monocrystal. In this case, preferably, the first main surface 3 is formed by a silicon plane (a (0001) plane) of the SiC monocrystal and the second main surface 4 is formed by a carbon plane (a (000-1) plane) of the SiC monocrystal.

The first side surface 5A and the second side surface 5B extend in a first direction X oriented along the first main surface 3 and are opposed in a second direction Y that intersects the first direction X along the first main surface 3. Specifically, the second direction Y is orthogonal to the first direction X. The third side surface 5C and the fourth side surface 5D extend in the second direction Y and are opposed in the first direction X.

In this embodiment, the first direction X is an m-axis direction (a [1-100] direction) of the SiC monocrystal and the second direction Y is an a-axis direction (a [11-20] direction) of the SiC monocrystal. The first direction X may instead be the a-axis direction of the SiC monocrystal and the second direction Y may instead be the m-axis direction of the SiC monocrystal. In the following, directions extending along the first main surface 3 are expressed at times as “horizontal directions.” The horizontal directions are also an XY plane (horizontal plane) formed by the first direction X and the second direction Y and are orthogonal to the vertical direction Z.

The chip 2 (the first main surface 3 and the second main surface 4) has an off angle inclined at a predetermined angle in a predetermined off direction with respect to the c-plane of the SiC monocrystal. That is, a c-axis (a (0001) axis) of the SiC monocrystal is inclined from a vertical line along the vertical direction Z toward the off direction by just the off angle. Also, the c-plane of the SiC monocrystal is inclined by just the off angle with respect to the horizontal plane.

Preferably, the off direction is the a-axis direction (in this embodiment, the second direction Y) of the SiC monocrystal. The off angle may exceed 0° but be not more than 10°. The off angle may have a value belonging to at least one range among exceeding 0° and not more than 1°, not less than 1° and not more than 2.5°, not less than 2.5° and not more than 5°, not less than 5° and not more than 7.5°, and not less than 7.5° and not more than 10°.

Preferably, the off angle is not more than 5°. Particularly preferably, the off angle is not less than 2° and not more than 4.5°. The off angle is typically set in a range of 4°+0.1°. This Description does not exclude an embodiment in which the off angle is 0° (that is, an embodiment in which the first main surface 3 is a just surface with respect to the c-plane).

The semiconductor device 1A includes a first semiconductor region 6 of an n-type formed in a surface layer portion of the second main surface 4. A drain potential is to be applied as a first potential (a high potential) to the first semiconductor region 6. The first semiconductor region 6 may be referred to as a “base region (layer),” a “semiconductor region (layer),” a “drain region (layer),” etc.

The first semiconductor region 6 extends in a layer shape along the second main surface 4, and is exposed from the second main surface 4 and the first to fourth side surfaces 5A to 5D. In this embodiment, the first semiconductor region 6 is constituted of a semiconductor layer of the n-type. Specifically, the first semiconductor region 6 is constituted of a substrate (an SiC substrate) that includes an SiC monocrystal (a semiconductor monocrystal), and forms the second main surface 4 and the first to fourth side surfaces 5A to 5D. The first semiconductor region 6 (the substrate) has the off direction and the off angle described above.

The first semiconductor region 6 may have a thickness of not less than 10 μm and not more than 500 μm. The thickness of the first semiconductor region 6 may have a value belonging to at least one range among not less than 10 μm and not more than 50 μm, not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, not less than 400 μm and not more than 500 μm.

The semiconductor device 1A includes a second semiconductor region 7 of the n-type formed in a surface layer portion of the first main surface 3. The second semiconductor region 7 may be referred to as a “semiconductor region (layer),” a “drift region (layer),” etc. The second semiconductor region 7 has an n-type impurity concentration less than an n-type impurity concentration of the first semiconductor region 6. The second semiconductor region 7 is formed in a region on the first main surface 3 side with respect to the first semiconductor region 6 in sectional view, and is electrically connected to the first semiconductor region 6.

The second semiconductor region 7 extends in a layer shape along the first main surface 3, and is exposed from the first main surface 3 and the first to fourth side surfaces 5A to 5D. In this embodiment, the second semiconductor region 7 is constituted of a semiconductor layer of the n-type. Specifically, the second semiconductor region 7 is constituted of an epitaxial layer (an SiC epitaxial layer) including an SiC monocrystal (a semiconductor monocrystal), and forms the first main surface 3 and the first to fourth side surfaces 5A to 5D.

The second semiconductor region 7 (the epitaxial layer) has the off direction and the off angle described above. Preferably, the second semiconductor region 7 has a thickness less than the thickness of the first semiconductor region 6. The thickness of the second semiconductor region 7 may be larger than the thickness of the first semiconductor region 6.

The thickness of the second semiconductor region 7 may be not less than 5 μm and not more than 15 μm. The thickness of the second semiconductor region 7 may have a value belonging to at least one range among not less than 5 μm and not more than 7.5 μm, not less than 7.5 μm and not more than 10 μm, not less than 10 μm and not more than 12.5 μm, not less than 12.5 μm and not more than 15 μm.

The semiconductor device 1A includes an active region 8 that is set in the chip 2. The active region 8 includes a device structure (a transistor structure Tr), and is a region in which an output current (a drain current) is generated. The active region 8 is set in an inner portion of the chip 2 at an interval from a peripheral edge (the first to fourth side surfaces 5A to 5D) of the first main surface 3.

The active region 8 is set in a polygonal shape (in this embodiment, a quadrangle shape) having four sides parallel to the peripheral edge of the chip 2 in plan view. A ratio (area ratio) of the plane area of the active region 8 to the plane area of the first main surface 3 may be not less than 0.5 and not more than 0.95. The area ratio may be a ratio of not less than 0.5 and not more than 0.6, not less than 0.6 and not more than 0.7, not less than 0.7 and not more than 0.8, not less than 0.8 and not more than 0.9, not less than 0.9 and not more than 0.95.

The semiconductor device 1A includes an outer peripheral region 9 that is set outside the active region 8 in the chip 2. The outer peripheral region 9 is a region that does not include the device structure (the transistor structure Tr). The outer peripheral region 9 is set in a peripheral edge portion of the chip 2. That is, the outer peripheral region 9 is provided in a region between the peripheral edge of the chip 2 and the active region 8 in plan view. The outer peripheral region 9 extends in a band shape along the active region 8 in plan view, and is set in a polygonal annular shape (in this embodiment, a quadrangle annular shape) that surrounds the active region 8.

The semiconductor device 1A includes the transistor structure Tr formed in the active region 8. Hereinafter, an arrangement in the active region 8 as an arrangement of the transistor structure Tr shall be described.

The semiconductor device 1A includes a body region 10 of a p-type formed in a surface layer portion of the first main surface 3 in the active region 8 (an inner portion of the first main surface 3). The body region 10 may be referred to as an “impurity region,” a “channel region,” etc. A source potential may be applied to the body region 10. The source potential may be a reference potential serving as a reference of a circuit operation. The reference potential may be a ground potential. The body region 10 has a p-type impurity concentration higher than the n-type impurity concentration of the second semiconductor region 7.

The body region 10 is formed in the inner portion of the first main surface 3 at an interval from the peripheral edge (the first to fourth side surfaces 5A to 5D) of the first main surface 3, and is not formed in the outer peripheral region 9. In this embodiment, the body region 10 is formed in an entire area of the active region 8. The body region 10 is formed in a surface layer portion of the second semiconductor region 7, and extends in a layer shape along the first main surface 3.

The body region 10 is formed at an interval toward the first main surface 3 side from a bottom portion of the second semiconductor region 7 (the first semiconductor region 6), and faces the first semiconductor region 6 with a portion of the second semiconductor region 7 interposed therebetween. The body region 10 is formed at an interval toward the first main surface 3 side from a depth position of an intermediate portion of the second semiconductor region 7.

The body region 10 is formed in a region on the first main surface 3 side with respect to the second semiconductor region 7 in sectional view, and is electrically connected to the second semiconductor region 7. The body region 10 forms a pn-junction portion (a body diode) with the second semiconductor region 7. The body region 10 spreads a depletion layer in the second semiconductor region 7 when a reverse bias voltage is applied. The depletion layer with the body region 10 as a starting point spreads in the second semiconductor region 7 in the horizontal direction and the thickness direction.

The semiconductor device 1A includes a source region 11 of the n-type formed in a surface layer portion of the first main surface 3 in the active region 8. A source potential is to be applied to the source region 11. The source region 11 has an n-type impurity concentration higher than the n-type impurity concentration of the second semiconductor region 7. The n-type impurity concentration of the source region 11 is higher than the p-type impurity concentration of the body region 10.

The source region 11 is formed in the inner portion of the first main surface 3 at an interval from the peripheral edge (the first to fourth side surfaces 5A to 5D) of the first main surface 3, and is not formed in the outer peripheral region 9. The source region 11 may be formed at an interval inward from the peripheral edge of the body region 10. The source region 11 is formed in a surface layer portion of the body region 10, and extends in a layer shape along the first main surface 3.

The source region 11 is formed at an interval toward the first main surface 3 side from a bottom portion of the body region 10, and faces the second semiconductor region 7 with a portion of the body region 10 interposed therebetween. The source region 11 is formed in a region on the first main surface 3 side with respect to the body region 10 in sectional view, and is electrically connected to the body region 10.

The semiconductor device 1A includes a plurality of gate structures 15 of a trench type (trench electrode type) formed in the inner portion of the first main surface 3. The gate structure 15 may be referred to as a “trench structure,” a “trench gate structure,” etc. A gate potential (gate signal) as a control potential is to be applied to the plurality of gate structures 15. The plurality of gate structures 15 control inversion and non-inversion of channels inside the body region 10 in response to the gate potential.

The plurality of gate structures 15 are formed in the inner portion of the first main surface 3 at an interval from the peripheral edge (the first to fourth side surfaces 5A to 5D) of the first main surface 3, and are not formed in the outer peripheral region 9. The plurality of gate structures 15 are aligned at an interval in the first direction X (=m-axis direction) in plan view, and respectively extend in a band shape in the second direction Y (=a-axis direction). In plan view, the plurality of gate structures 15 are aligned in a stripe shape extending in the second direction Y.

The extension direction of the plurality of gate structures 15 coincides with the off direction of the SiC monocrystal. In the second direction Y, both end portions of each of the plurality of gate structures 15 may be positioned in a region between the peripheral edge portion of the body region 10 and the peripheral edge portion of the source region 11. The plurality of gate structures 15 may be aligned at an interval in the second direction Y in plan view, and may respectively extend in a band shape in the first direction X.

The plurality of gate structures 15 penetrate through the body region 10 and the source region 11 so as to reach the second semiconductor region 7. The plurality of gate structures 15 are formed at an interval toward the first main surface 3 side from a depth position of a bottom portion of the second semiconductor region 7, and face the first semiconductor region 6 with a portion of the second semiconductor region 7 interposed therebetween.

The plurality of gate structures 15 may be formed at an interval toward the first main surface 3 side from the depth position of the intermediate portion of the second semiconductor region 7, or may be positioned on a bottom portion side of the second semiconductor region 7 with respect to the depth position of the intermediate portion of the second semiconductor region 7. The plurality of gate structures 15 are formed to be substantially perpendicular to the first main surface 3. The plurality of gate structures 15 may be formed in a shape tapering toward the bottom portion of the second semiconductor region 7.

Side walls (long sides) of the plurality of gate structures 15 are formed by an m-plane (a (1-100) plane) of the SiC monocrystal. The side walls (long sides) of the plurality of gate structures 15 may be formed by an a-plane (a (11-20) plane) of the SiC monocrystal in accordance with the extension direction of the gate structures 15. Bottom walls of the plurality of gate structures 15 are formed by a c-plane (an Si plane) of the SiC monocrystal. Preferably, the bottom walls of the plurality of gate structures 15 extend to be substantially flat along the horizontal direction. The bottom walls of the plurality of gate structures 15 may be curved in an arc shape toward the second main surface 4 side.

An inclination angle (absolute value) of the side wall (long side) of the gate structure 15 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, not less than 92.5° and not more than 95°. Preferably, the inclination angle is not less than 87° and not more than 93°.

The gate structure 15 may have a width of not less than 0.1 μm and not more than 2 μm. The width of the gate structure 15 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The gate structure 15 may have a depth of not less than 0.1 μm and not more than 3 μm. The depth of the gate structure 15 is a depth when the first main surface 3 is set as a reference. The depth of the gate structure 15 may have a value belonging to at least one range among of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm. Preferably, the depth of the gate structure 15 is a depth of not less than 0.5 μm and not more than 1.5 μm.

The gate structure 15 may have an aspect ratio of not less than 1 and not more than 3. The aspect ratio of the gate structure 15 is a ratio of the depth of the gate structure 15 to the width of the gate structure 15. The aspect ratio may have a value belonging to at least one range among of not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. Preferably, the aspect ratio is a ratio of not less than 1.5 and not more than 2.5.

Each of the plurality of gate structures 15 includes a first trench 16, a first insulating film 17, and a first embedded electrode 18. The first trench 16 is formed in the first main surface 3, and demarcates wall surfaces (side walls and a bottom wall) of the gate structure 15.

The first insulating film 17 may include at least one among a silicon oxide film, a silicon nitride film, and a silicon oxynitride film. In this embodiment, the first insulating film 17 has a single layer structure constituted of a silicon oxide film. Particularly preferably, the first insulating film 17 includes a silicon oxide film constituted of an oxide of the chip 2.

The first insulating film 17 covers wall surfaces of the first trench 16. The first insulating film 17 includes a first film portion and a second film portion. The first film portion covers side walls of the first trench 16 in a film shape. The second film portion covers a bottom wall of the first trench 16 in a film shape, and is continuous to the first film portion. The second film portion has a thickness larger than a thickness of the first film portion. The thickness of the second film portion may be substantially equal to the thickness of the first film portion.

The first insulating film 17 may have a thickness of not less than 10 nm and not more than 150 nm. The thickness of the first insulating film 17 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The first embedded electrode 18 is embedded in the first trench 16 with the first insulating film 17 interposed therebetween. The first embedded electrode 18 may include either or both of a p-type conductive polysilicon and an n-type conductive polysilicon. The first embedded electrode 18 faces the second semiconductor region 7, the body region 10, and the source region 11 with the first insulating film 17 interposed therebetween.

The first embedded electrode 18 has an electrode surface exposed from the first trench 16. The electrode surface is positioned on a bottom wall side of the first trench 16 with respect to a height position of the first main surface 3. The electrode surface is positioned on the first main surface 3 side with respect to a depth position of a bottom portion of the source region 11. The electrode surface has, in an inner portion, a recess that is recessed in a tapered shape toward the bottom wall of the first trench 16.

The semiconductor device 1A includes a plurality of source structures 20 of the trench type (trench electrode type) formed in the inner portion of the first main surface 3. The source structure 20 may be referred to as a “first source structure,” a “source structure,” a “second trench structure,” etc. The source potential is to be applied to the plurality of source structures 20.

The plurality of source structures 20 are formed in the inner portion of the first main surface 3 at an interval from the peripheral edge (the first to fourth side surfaces 5A to 5D) of the first main surface 3, and are not formed in the outer peripheral region 9. The plurality of source structures 20 are aligned at an interval in the first direction X (=m-axis direction) in plan view, and respectively extend in a band shape in the second direction Y (=a-axis direction).

The plurality of source structures 20 are respectively arranged in regions between the plurality of gate structures 15 at an interval in the first direction X from the plurality of gate structures 15, and face the plurality of gate structures 15 in the first direction X. That is, the plurality of source structures 20 are alternately aligned with the plurality of gate structures 15 in the first direction X, and each extend in a band shape in the second direction Y. The plurality of source structures 20 are aligned in a stripe shape extending in the second direction Y.

The extension direction of the plurality of source structures 20 coincides with the off direction of the SiC monocrystal. In the second direction Y, both end portions of each of the plurality of source structures 20 may be positioned in the region between the peripheral edge portion of the body region 10 and the peripheral edge portion of the source region 11. The plurality of source structures 20 may be aligned at an interval in the second direction Y in accordance with the extension direction of the plurality of gate structures 15, and may each extend in a band shape in the first direction X.

The plurality of source structures 20 penetrate through the body region 10 and the source region 11 so as to reach the second semiconductor region 7. The plurality of source structures 20 are formed at an interval toward the first main surface 3 side from the bottom portion of the second semiconductor region 7, and face the first semiconductor region 6 with a portion of the second semiconductor region 7 interposed therebetween.

The plurality of source structures 20 may be formed at an interval toward the first main surface 3 side from the depth position of the intermediate portion of the second semiconductor region 7, or may be positioned on a bottom portion side of the second semiconductor region 7 with respect to the depth position of the intermediate portion of the second semiconductor region 7. The plurality of source structures 20 are formed to be substantially perpendicular to the first main surface 3. The plurality of source structures 20 may be formed in a shape tapering toward the bottom portion of the second semiconductor region 7.

Side walls of the plurality of source structures 20 are each formed by an m-plane (a (1-100) plane) of the SiC monocrystal. The side walls of the plurality of source structures 20 may be formed by an a-plane (a (11-20) plane) of the SiC monocrystal in accordance with the extension direction of the source structures 20. Bottom walls of the plurality of source structures 20 are formed by a c-plane (an Si plane) of the SiC monocrystal. Preferably, the bottom walls of the plurality of source structures 20 extend to be substantially flat along the horizontal direction. The bottom walls of the plurality of source structures 20 may be curved in an arc shape toward the second main surface 4 side.

An inclination angle (absolute value) of the side wall of the source structure 20 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, not less than 92.5° and not more than 95°. Preferably, the inclination angle is not less than 87° and not more than 93°.

The source structure 20 has a width substantially equal to the width of the gate structure 15. The width of the source structure 20 may be larger than the width of the gate structure 15 or may be less than the width of the gate structure 15.

The width of the source structure 20 may be not less than 0.1 μm and not more than 2 μm. The width of the source structure 20 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The source structure 20 has a depth substantially equal to the depth of the gate structure 15. The depth of the source structure 20 is a depth when the first main surface 3 is set as a reference. The depth of the source structure 20 may be larger than the depth of the gate structure 15, or may be less than the depth of the gate structure 15.

A ratio (depth ratio) of the depth of the source structure 20 to the depth of the gate structure 15 may be 0.8 and not more than 1.2. The depth ratio may have a value belonging to at least one range among not less than 0.8 and not more than 0.85, not less than 0.85 and not more than 0.9, not less than 0.9 and not more than 0.95, not less than 0.95 and not more than 1, not less than 1 and not more than 1.05, not less than 1.05 and not more than 1.1, not less than 1.1 and not more than 1.15, and not less than 1.15 and not more than 1.2. Preferably, the depth ratio is not less than 0.95 and not more than 1.05.

The depth of the source structure 20 may be not less than 0.1 μm and not more than 3 μm. The depth of the source structure 20 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. Preferably, the depth of the source structure 20 is a depth of not less than 0.5 μm and not more than 1.5 μm.

The source structure 20 may have an aspect ratio of not less than 1 and not more than 3. The aspect ratio of the source structure 20 is a ratio of the depth of the source structure 20 to the width of the source structure 20. The aspect ratio may have a value belonging to at least one range among of not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. Preferably, the aspect ratio is a ratio of not less than 1.5 and not more than 2.5.

A pitch between a central portion of the source structure 20 and a central portion of the gate structure 15 may be not less than 0.1 μm and not more than 2.5 μm. The pitch may have a value belonging to at least one range among not less than 0.1 μm and not more than 0.25 μm, not less than 0.25 μm and not more than 0.5 μm, not less than 0.5 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

Each of the plurality of source structures 20 includes a second trench 21, a second insulating film 22, and a second embedded electrode 23. The second trench 21 is formed in the first main surface 3, and demarcates wall surfaces (side walls and a bottom wall) of the source structure 20.

The second insulating film 22 may include at least one among a silicon oxide film, a silicon nitride film, and a silicon oxynitride film. Preferably, the second insulating film 22 includes the same type of insulating material as the insulating material of the first insulating film 17. In this embodiment, the second insulating film 22 has a single layer structure constituted of a silicon oxide film. Particularly preferably, the second insulating film 22 includes the silicon oxide film constituted of the oxide of the chip 2.

The second insulating film 22 covers wall surfaces of the second trench 21. The second insulating film 22 includes a first film portion and a second film portion. The first film portion covers side walls of the second trench 21 in a film shape. The second film portion covers a bottom wall of the second trench 21 in a film shape, and is continuous to the first film portion.

The second film portion has a thickness larger than a thickness of the first film portion. The thickness of the second film portion may be substantially equal to the thickness of the first film portion. The thickness of the first film portion of the second insulating film 22 may be substantially equal to the thickness of the first film portion of the first insulating film 17. The thickness of the second film portion of the second insulating film 22 may be substantially equal to the thickness of the second film portion of the first insulating film 17.

The second insulating film 22 may have a thickness of not less than 10 nm and not more than 150 nm. The thickness of the second insulating film 22 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The second embedded electrode 23 is embedded in the second trench 21 with the second insulating film 22 interposed therebetween. The second embedded electrode 23 may include either or both of a p-type conductive polysilicon and an n-type conductive polysilicon. Preferably, the second embedded electrode 23 includes the same type of conductive material as the conductive material of the first embedded electrode 18. The second embedded electrode 23 faces the second semiconductor region 7, the body region 10, and the source region 11 with the second insulating film 22 interposed therebetween.

The second embedded electrode 23 has an electrode surface exposed from the second trench 21. The electrode surface is positioned on a bottom wall side of the second trench 21 with respect to a height position of the first main surface 3. The electrode surface is positioned on the first main surface 3 side with respect to the depth position of the bottom portion of the source region 11. The electrode surface has, in an inner portion, a recess that is recessed in a tapered shape toward the bottom wall of the second trench 21.

The semiconductor device 1A includes gate well regions 25 that are respectively formed in regions below the plurality of gate structures 15 in the chip 2 (the second semiconductor region 7) of the active region 8. The gate well region 25 may be referred to as a “first well region,” etc.

The source potential is to be applied to the gate well region 25. The gate well region 25 has a p-type impurity concentration higher than the n-type impurity concentration of the second semiconductor region 7. The p-type impurity concentration of the gate well region 25 may be higher than the p-type impurity concentration of the body region 10, or may be less than the p-type impurity concentration of the body region 10. Preferably, the p-type impurity (trivalent element) of the gate well region 25 is aluminum.

The plurality of gate well regions 25 are respectively formed in regions below (specifically, directly below) the plurality of gate structures 15 at an interval in the horizontal direction (the first direction X) in the second semiconductor region 7. The plurality of gate well regions 25 are respectively formed in thickness ranges between the bottom portion of the second semiconductor region 7 and the bottom walls of the plurality of gate structures 15, and overlap the plurality of gate structures 15 in a one-to-one correspondence in the thickness direction.

The plurality of gate well regions 25 each extend in a band shape in the second direction Y along the extension direction of the corresponding gate structures 15 in plan view. That is, in plan view, the plurality of gate well regions 25 are aligned in a stripe shape extending in the second direction Y.

The extension direction of the plurality of gate well regions 25 coincides with the off direction of the SiC monocrystal. The plurality of gate well regions 25 may extend in the first direction X in accordance with the extension direction of the plurality of gate structures 15. In this case, the plurality of gate well regions 25 intersect (specifically, are orthogonal to) the off direction.

The plurality of gate well regions 25 are formed at an interval inward from the peripheral edge (a plurality of separating structures 30) of the active region 8. In the second direction Y, both end portions of each of the plurality of gate well regions 25 may be positioned on the inner side of each of the plurality of gate structures 15 with respect to the both end portions of each of the plurality of gate structures 15, or may be positioned on the peripheral edge side of the active region 8 with respect to the both end portions of each of the plurality of gate structures 15.

The plurality of gate well regions 25 are formed at an interval toward the bottom wall side of each of the plurality of gate structures 15 from the bottom portion of the second semiconductor region 7, and face the first semiconductor region 6 with a portion of the second semiconductor region 7 interposed therebetween. Each of the plurality of gate well regions 25 has an upper end portion positioned on the bottom wall side of the corresponding gate structure 15, and a bottom portion positioned on the bottom portion side of the second semiconductor region 7 (the second main surface 4 side).

The upper end portion of each of the plurality of gate well regions 25 is formed at an interval toward the bottom wall side of the corresponding gate structure 15 from the bottom portion of the body region 10. The upper end portion of each of the plurality of gate well regions 25 may be connected to the bottom wall of the corresponding gate structure 15. The upper end portion of each of the plurality of gate well regions 25 may have portions along the side walls of the corresponding gate structure 15. The upper end portion of each of the plurality of gate well regions 25 may be formed at an interval toward the bottom portion side of the second semiconductor region 7 from the bottom wall of the corresponding gate structure 15.

The bottom portion of each of the plurality of gate well regions 25 may be positioned on the bottom wall side of each of the plurality of gate structures 15 with respect to the intermediate portion of the second semiconductor region 7, or may be positioned on the bottom portion side of the second semiconductor region 7 (the second main surface 4 side) with respect to the intermediate portion of the second semiconductor region 7.

Each of the plurality of gate well regions 25 has a bulging portion 25a. The bulging portion 25a protrudes in an arc shape in the horizontal direction from a region directly below the corresponding gate structure 15 toward both sides of the corresponding gate structure 15. Each of the plurality of gate well regions 25 is formed in a shape tapering toward the bottom portion from the bulging portion 25a.

The gate well region 25 may have a width larger than the width of the gate structure 15, or may have a width less than the width of the gate structure 15. A width of the gate well region 25 may be not less than 0.1 μm and not more than 2 μm. The width of the gate well region 25 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The gate well region 25 may have a depth less than the depth of the gate structure 15, or may have a depth larger than the depth of the gate structure 15. The depth of the gate well region 25 is a depth of the gate well region 25 when the bottom wall of the gate structure 15 is set as a reference.

A depth of the gate well region 25 may be larger than 0 μm and not more than 5 μm. The depth of the gate well region 25 may have a value belonging to at least one range among larger than 0 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The gate well region 25 may have an aspect ratio larger than 0 and not more than 2. The aspect ratio of the gate well region 25 is a ratio of the depth of the gate well region 25 to the width of the gate well region 25.

The aspect ratio may have a value belonging to at least one range among larger than 0 and not more than 0.25, not less than 0.25 and not more than 0.5, not less than 0.5 and not more than 0.75, not less than 0.75 and not more than 1, not less than 1 and not more than 1.25, not less than 1.25 and not more than 1.5, not less than 1.5 and not more than 1.75, and not less than 1.75 and not more than 2.

The gate well region 25 forms a pn-junction portion with the second semiconductor region 7. The gate well region 25 spreads a depletion layer in the second semiconductor region 7 when a reverse bias voltage is applied. The depletion layer with the gate well region 25 as a starting point spreads in the horizontal direction and the thickness direction, and relaxes the electric field with respect to the active region 8 (the gate structure 15).

The semiconductor device 1A includes a plurality of source well regions 26 that are respectively formed in regions below the plurality of source structures 20 in the chip 2 (the second semiconductor region 7) of the active region 8. The source well region 26 may be referred to as a “second well region,” etc. The source potential is to be applied to the source well region 26.

The source well region 26 has a p-type impurity concentration higher than the n-type impurity concentration of the second semiconductor region 7. The p-type impurity concentration of the source well region 26 may be higher than the p-type impurity concentration of the body region 10, or may be less than the p-type impurity concentration of the body region 10.

The p-type impurity concentration of the source well region 26 may be substantially equal to the p-type impurity concentration of the gate well region 25. The p-type impurity concentration of the source well region 26 may be higher than the p-type impurity concentration of the gate well region 25, or may be less than the p-type impurity concentration of the gate well region 25. Preferably, the p-type impurity (trivalent element) of the source well region 26 is aluminum.

The plurality of source well regions 26 are respectively formed in regions below (specifically, directly below) the plurality of source structures 20 at an interval from the plurality of gate well regions 25 in the horizontal direction (the first direction X) in the second semiconductor region 7. The plurality of source well regions 26 are respectively formed in thickness ranges between the bottom portion of the second semiconductor region 7 and the bottom walls of the plurality of source structures 20, and overlap the plurality of source structures 20 in a one-to-one correspondence in the thickness direction.

The plurality of source well regions 26 each extend in a band shape in the second direction Y along the extension direction of the corresponding source structures 20 in plan view. That is, in plan view, the plurality of source well regions 26 are aligned in a stripe shape extending in the second direction Y.

The extension direction of the plurality of source well regions 26 coincides with the off direction of the SiC monocrystal. The plurality of source well regions 26 may extend in the first direction X in accordance with the extension direction of the plurality of source structures 20. In this case, the plurality of source well regions 26 intersect (specifically, are orthogonal to) the off direction.

The plurality of source well regions 26 are formed at an interval inward from the peripheral edge of the active region 8. In the second direction Y, both end portions of each of the plurality of source well regions 26 may be positioned on the inner side of each of the plurality of source structures 20 with respect to the both end portions of each of the plurality of source structures 20, or may be positioned on the peripheral edge side of the active region 8 with respect to the both end portions of each of the plurality of source structures 20.

The plurality of source well regions 26 are formed at an interval toward the bottom wall side of each of the plurality of source structures 20 from the bottom portion of the second semiconductor region 7, and face the first semiconductor region 6 with a portion of the second semiconductor region 7 interposed therebetween. Each of the plurality of source well regions 26 has an upper end portion positioned on the bottom wall side of the corresponding source structure 20, and a bottom portion positioned on the bottom portion side of the second semiconductor region 7.

The upper end portion of each of the plurality of source well regions 26 may be connected to the bottom wall of the corresponding source structure 20. The upper end portion of each of the plurality of source well regions 26 may extend along side walls of the corresponding source structure 20, and may be connected to the body region 10. The upper end portion of each of the plurality of source well regions 26 may be formed at an interval toward the bottom portion side of the second semiconductor region 7 from the bottom wall of the corresponding source structure 20.

The bottom portion of each of the plurality of source well regions 26 may be positioned on the bottom wall side of each of the plurality of source structures 20 with respect to the intermediate portion of the second semiconductor region 7, or may be positioned on the bottom portion side of the second semiconductor region 7 (the second main surface 4 side) with respect to the intermediate portion of the second semiconductor region 7.

Each of the plurality of source well regions 26 has a bulging portion 26a. The bulging portion 26a protrudes in an arc shape in the horizontal direction from a region directly below the corresponding source structure 20 toward both sides of the corresponding source structure 20. Each of the plurality of source well regions 26 is formed in a shape tapering toward the bottom portion from the bulging portion 26a.

The source well region 26 may have a width substantially equal to the width of the gate well region 25. The width of the source well region 26 may be larger than the width of the gate well region 25, or may be less than the width of the gate well region 25. The width of the source well region 26 may be larger than the width of the source structure 20, or may be less than the width of the source structure 20.

A width of the source well region 26 may be not less than 0.1 μm and not more than 2 μm. The width of the source well region 26 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The source well region 26 may have a depth substantially equal to the depth of the gate well region 25. That is, the bottom portion of the source well region 26 may be positioned at a depth substantially equal to the depth of the bottom portion of the gate well region 25. The depth of the source well region 26 is the depth of the source well region 26 when the bottom wall of the source structure 20 is set as a reference. The depth of the source well region 26 may be larger than the depth of the gate well region 25, or may be less than the depth of the gate well region 25.

A depth of the source well region 26 may be a depth larger than 0 μm and not more than 5 μm. The depth of the source well region 26 may have a value belonging to at least one range among larger than 0 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The source well region 26 may have an aspect ratio larger than 0 and not more than 2. The aspect ratio of the source well region 26 is a ratio of the depth of the source well region 26 to the width of the source well region 26.

The aspect ratio may have a value belonging to at least one range among larger than 0 and not more than 0.25, not less than 0.25 and not more than 0.5, not less than 0.5 and not more than 0.75, not less than 0.75 and not more than 1, not less than 1 and not more than 1.25, not less than 1.25 and not more than 1.5, not less than 1.5 and not more than 1.75, and not less than 1.75 and not more than 2.

A pitch between the central portion of the source well region 26 and the central portion of the gate well region 25 (a pitch between the source well regions 26) is substantially equal to the pitch between the source structure 20 and the gate structure 15. The pitch between the source well regions 26 may be not less than 0.1 μm and not more than 2.5 μm.

The pitch between the source well regions 26 may have a value belonging to at least one range among not less than 0.1 μm and not more than 0.25 μm, not less than 0.25 μm and not more than 0.5 μm, not less than 0.5 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

The source well region 26 forms a pn-junction portion with the second semiconductor region 7. The source well region 26 spreads a depletion layer in the second semiconductor region 7 when a reverse bias voltage is applied. The depletion layer with the source well region 26 as a starting point spreads in the horizontal direction and the thickness direction, and relaxes the electric field with respect to the active region 8 (the source structure 20). The depletion layer with the source well region 26 as a starting point becomes integral with the depletion layer with the gate well region 25 as a starting point.

The semiconductor device 1A includes a plurality of gate contact regions 27 formed in the chip 2 (the second semiconductor region 7) in the active region 8. The gate contact region 27 may be referred to as a “first contact region,” etc. The source potential is to be applied to the gate contact region 27.

The gate contact region 27 has a p-type impurity concentration higher than the n-type impurity concentration of the second semiconductor region 7. The p-type impurity concentration of the gate contact region 27 is higher than the p-type impurity concentration of the body region 10. The p-type impurity concentration of the gate contact region 27 is higher than the p-type impurity concentration of the gate well region 25.

The plurality of gate contact regions 27 are respectively formed in regions along the plurality of gate structures 15 at an interval from the plurality of source structures 20. The plurality of gate contact regions 27 are formed in a multiple-to-one correspondence with the plurality of gate structures 15. The plurality of gate contact regions 27 are formed at an interval in the second direction Y along the extension direction of the corresponding gate structures 15.

With respect to the one gate structure 15 and the other gate structures 15, the plurality of gate contact regions 27 along one gate structure 15 face the plurality of gate contact regions 27 along the other gate structures 15 in the first direction X in plan view. That is, the plurality of gate contact regions 27 are aligned in a matrix at an interval in the first direction X and the second direction Y as a whole in plan view.

The plurality of gate contact regions 27 on one side may face regions between the plurality of gate contact regions 27 on the other side in the first direction X in plan view. That is, the plurality of gate contact regions 27 may be aligned in a staggered manner at an interval in the first direction X and the second direction Y as a whole in plan view.

In this embodiment, the plurality of gate contact regions 27 extend in a band shape along the plurality of gate structures 15 in plan view. The lengths of the plurality of gate contact regions 27 in the second direction Y may be equal to each other, or may be different from each other. The lengths of the plurality of gate contact regions 27 in the second direction Y are adjusted in accordance with the channel area to be formed.

The channel area is the total area of portions of the source region 11 that are exposed from regions between the plurality of gate structures 15 and the plurality of source structures 20. That is, the channel area decreases and increases in accordance with an increase and a decrease in the ratio of the total plane area of the plurality of gate contact regions 27. Preferably, the total plane area of the plurality of gate contact regions 27 is less than the channel area.

That is, in the region between one gate structure 15 and one source structure 20 adjacent to each other, preferably, the total plane area of the plurality of gate contact regions 27 is less than the plane area of the source region 11. According to such an arrangement, an increase in the resistance value (on-resistance) caused by the short channel is prevented.

The length of the gate contact region 27 may be larger than the width of the gate structure 15, or may be smaller than the width of the gate structure 15. The length of the gate contact region 27 may be larger than the pitch between the gate structure 15 and the source structure 20, or may be smaller than the pitch between the gate structure 15 and the source structure 20. The length of the gate contact region 27 may be larger than the pitch between two adjacent gate structures 15, or may be smaller than the pitch between two adjacent gate structures 15.

The interval between the plurality of gate contact regions 27 may be larger than the width of the gate structure 15, or may be smaller than the width of the gate structure 15. The interval between the gate contact regions 27 may be larger than the pitch between the gate structure 15 and the source structure 20, or may be smaller than the pitch between the gate structure 15 and the source structure 20. The interval between the gate contact regions 27 may be larger than the pitch between two adjacent gate structures 15, or may be smaller than the pitch between two adjacent gate structures 15.

The plurality of gate contact regions 27 are respectively interposed in regions between bottom walls of the plurality of gate structures 15 and bottom portions of the plurality of gate well regions 25. Each of the plurality of gate contact regions 27 is connected to the bottom wall of the corresponding gate structure 15 and the corresponding gate well region 25.

Each of the plurality of gate contact regions 27 increases the p-type impurity concentration of the upper end portion of the corresponding gate well region 25. The gate contact region 27 has an extension portion that protrudes from a region directly below the gate structure 15 to both sides of the gate structure 15 and extends along side walls of the gate structure 15.

A thickness of a portion (the extension portion) of the gate contact region 27 along the side walls of the gate structure 15 in the horizontal direction (the first direction X) may be less than a thickness of a portion of the gate contact region 27 along the bottom wall of the gate structure 15 in the vertical direction Z.

The extension portion of the gate contact region 27 is electrically connected to the body region 10 in the surface layer portion of the first main surface 3, and electrically connects the corresponding gate well region 25 to the body region 10. Thereby, the gate well region 25 is prevented from being put in an electrically floating state, and the electrical response characteristics of the gate well region 25 are improved.

The gate contact region 27 has an upper end portion exposed from the first main surface 3. In this embodiment, the upper end portion of the gate contact region 27 is exposed from the side wall of the first trench 16 at an opening end of the first trench 16. The upper end portion of the gate contact region 27 may extend in the horizontal direction in the surface layer portion of the body region 10.

The semiconductor device 1A includes a plurality of source contact regions 28 formed in the chip 2 (the second semiconductor region 7). The source contact region 28 may be referred to as a “second contact region,” etc. The source potential is to be applied to the source contact region 28.

The source contact region 28 has a p-type impurity concentration higher than the n-type impurity concentration of the second semiconductor region 7. The p-type impurity concentration of the source contact region 28 is higher than the p-type impurity concentration of the body region 10.

The p-type impurity concentration of the source contact region 28 is higher than the p-type impurity concentration of the source well region 26. The p-type impurity concentration of the source contact region 28 may be substantially equal to the p-type impurity concentration of the gate contact region 27. The p-type impurity concentration of the source contact region 28 may be higher than the p-type impurity concentration of the gate contact region 27, or may be lower than the p-type impurity concentration of the gate contact region 27.

The plurality of source contact regions 28 are respectively formed in regions along the plurality of source structures 20 at an interval from the plurality of gate structures 15. The plurality of source contact regions 28 has a planar layout different from the planar layout of the plurality of gate contact regions 27. In this embodiment, the plurality of source contact regions 28 are formed in a one-to-one correspondence with the plurality of source structures 20.

The plurality of source contact regions 28 extend in a band shape along the extension direction of the corresponding source structures 20 in the second direction Y. That is, the plurality of source contact regions 28 are formed in a stripe shape extending along the plurality of source structures 20 in plan view.

The plurality of source contact regions 28 have a length larger than the length of the plurality of gate contact regions 27 in the second direction Y, and cross the plurality of gate contact regions 27 in the second direction Y. In the second direction Y, the plurality of source contact regions 28 may have a length larger than the length of the plurality of source structures 20, or may have a length less than the length of the plurality of source structures 20.

Preferably, the plurality of source contact regions 28 have a total plane area larger than the total plane area of the plurality of gate contact regions 27. The total plane area of the plurality of source contact regions 28 may be larger than the channel area, or may be less than the channel area.

As with the plurality of gate contact regions 27, the plurality of source contact regions 28 may be formed in a multiple-to-one correspondence with the plurality of source structures 20. In this case, in relation to one source structure 20 and the other source structure 20, the plurality of gate contact regions 27 along one source structure 20 may face the plurality of source contact regions 28 along the other source structure 20 in the first direction X in plan view.

That is, the plurality of source contact regions 28 may be aligned in a matrix at an interval in the first direction X and the second direction Y as a whole in plan view. The plurality of source contact regions 28 on one side may face regions between the plurality of source contact regions 28 on the other side in the first direction X in plan view. That is, the plurality of source contact regions 28 may be aligned in a staggered manner at an interval in the first direction X and the second direction Y as a whole in plan view.

The plurality of source contact regions 28 are respectively interposed in regions between the bottom wall of the corresponding source structure 20 and the bottom portion of the corresponding source well region 26. Each of the plurality of source contact regions 28 is connected to the bottom wall of the corresponding source structure 20 and the corresponding source well region 26.

Each of the plurality of source contact regions 28 increases the p-type impurity concentration of the upper end portion of the corresponding source well region 26. Each of the plurality of source contact regions 28 has an extension portion that protrudes from a region directly below the source structure 20 to both sides of the source structure 20 and extends along side walls of the source structure 20.

A thickness of a portion (the extension portion) of the source contact region 28 along the side walls of the source structure 20 in the horizontal direction (the first direction X) may be less than a thickness of a portion of the source contact region 28 along the bottom wall of the source structure 20 in the vertical direction Z.

The extension portion of the source contact region 28 is electrically connected to the body region 10 in the surface layer portion of the first main surface 3, and electrically connects the corresponding source well region 26 to the body region 10. Thereby, the source well region 26 is prevented from being put in an electrically floating state, and the electrical response characteristics of the source well region 26 are improved.

The source contact region 28 has an upper end portion exposed from the first main surface 3. In this embodiment, the upper end portion of the source contact region 28 is exposed from the side wall of the second trench 21 at an opening end of the second trench 21. The upper end portion of the source contact region 28 may extend in the horizontal direction in the surface layer portion of the body region 10.

The upper end portions of the source contact regions 28 are electrically connected to the upper end portions of the plurality of adjacent gate contact regions 27 in the body region 10. In this embodiment, the upper end portion of the source contact region 28 is integrally formed with the upper end portion of the gate contact region 27.

The semiconductor device 1A includes one or more (in this embodiment, a plurality) of the separating structures 30 of the trench type (trench electrode type) formed in the first main surface 3 in the active region 8. The separating structure 30 may be referred to as a “trench structure,” a “third trench structure,” a “dummy structure,” etc.

The number of the separating structures 30 is arbitrary. The number of the separating structures 30 may be not less than 1 and not more than 15. The number of the separating structures 30 may be 1, 2, 3, 4, 5, 6, 7, 8, 9, 10, 11, 12, 13, 14, or 15. The number of the separating structures 30 is typically not less than 1 and not more than 10. In this embodiment, the semiconductor device 1A includes five separating structures 30 as an example.

At least one or all of the plurality of separating structures 30 may be formed in an electrically floating state. The source potential may be applied to at least one or all of the plurality of separating structures 30. The plurality of separating structures 30 may include one or a plurality of the separating structures 30 formed in an electrically floating state, and one or a plurality of the separating structures 30 to which the source potential is to be applied.

The plurality of separating structures 30 are formed in the inner portion of the first main surface 3 at an interval from the peripheral edge (the first to fourth side surfaces 5A to 5D) of the first main surface 3. The plurality of separating structures 30 demarcate the active region 8 on the inner portion side of the first main surface 3, and demarcate the outer peripheral region 9 on the peripheral edge portion side of the first main surface 3. The inner side than the outermost separating structure 30 is the active region 8, and the outer side than the outermost separating structure 30 is the outer peripheral region 9.

The plurality of separating structures 30 are arranged at the peripheral edge portion of the active region 8 at intervals from the plurality of gate structures 15 and the plurality of source structures 20. The plurality of separating structures 30 are aligned at an interval from each other, and are adjacent to each other in the horizontal direction with a portion of the chip 2 interposed therebetween. Each of the plurality of separating structures 30 extends in a band shape along the peripheral edge of the first main surface 3. Each of the plurality of separating structures 30 has a portion extending in the first direction X and a portion extending in the second direction Y.

That is, each of the plurality of separating structures 30 has a portion extending in the extension direction (the second direction Y) of the plurality of gate structures 15 (the plurality of source structures 20) and a portion extending in a direction (first direction X) intersecting the extension direction of the plurality of gate structures 15 (the plurality of source structures 20). The plurality of separating structures 30 may be formed in a polygonal annular shape (a quadrangle annular shape) collectively surrounding the plurality of gate structures 15 and the plurality of source structures 20 in plan view.

The plurality of separating structures 30 are formed in a region outside the source region 11, and penetrate through just the body region 10. The plurality of separating structures 30 may penetrate through the source region 11. The plurality of separating structures 30 are formed at an interval toward the first main surface 3 side from the bottom portion of the second semiconductor region 7, and face the first semiconductor region 6 with a portion of the second semiconductor region 7 interposed therebetween.

The plurality of separating structures 30 may be formed at an interval toward the first main surface 3 side from the depth position of the intermediate portion of the second semiconductor region 7, or may be positioned on a bottom portion side of the second semiconductor region 7 with respect to the depth position of the intermediate portion of the second semiconductor region 7. The plurality of separating structures 30 are formed to be substantially perpendicular to the first main surface 3. The plurality of separating structures 30 may be formed in a shape tapering toward the bottom portion of the second semiconductor region 7.

Side walls of the plurality of separating structures 30 are formed by an m-plane (a (1-100) plane) of the SiC monocrystal and an a-plane (a (11-20) plane) of the SiC monocrystal. Bottom walls of the plurality of separating structures 30 are formed by a c-plane (an Si plane) of the SiC monocrystal. Preferably, the bottom walls of the plurality of separating structures 30 extend to be substantially flat along the horizontal direction. The bottom walls of the plurality of separating structures 30 may be curved in an arc shape toward the second main surface 4 side.

An inclination angle (absolute value) of the side wall of the separating structure 30 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, not less than 92.5° and not more than 95°. Preferably, the inclination angle is not less than 87° and not more than 93°.

The separating structure 30 may have a width substantially equal to the width of the gate structure 15. The width of the separating structure 30 may be larger than the width of the gate structure 15, or may be less than the width of the gate structure 15. The width of the separating structure 30 may be substantially equal to the width of the source structure 20. The width of the separating structure 30 may be larger than the width of the source structure 20, or may be less than the width of the source structure 20.

The width of the separating structure 30 may be not less than 0.1 μm and not more than 2 μm. The width of the separating structure 30 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The separating structure 30 may have a depth not less than the depth of the gate structure 15. The depth of the separating structure 30 is a depth when the first main surface 3 is set as a reference. The depth of the separating structure 30 may be larger than the depth of the gate structure 15, or may be less than the depth of the gate structure 15. In this embodiment, the depth of the separating structure 30 is substantially equal to the depth of the gate structure 15.

The separating structure 30 may have a depth not less than the depth of the source structure 20. The depth of the separating structure 30 may be larger than the depth of the source structure 20, or may be less than the depth of the source structure 20. In this embodiment, the depth of the separating structure 30 is substantially equal to the depth of the source structure 20.

A ratio (depth ratio) of the depth of the separating structure 30 to the depth of the gate structure 15 (the source structure 20) may be not less than 0.8 and not more than 1.2. The depth ratio may have a value belonging to at least one range among not less than 0.8 and not more than 0.85, not less than 0.85 and not more than 0.9, not less than 0.9 and not more than 0.95, not less than 0.95 and not more than 1, not less than 1 and not more than 1.05, not less than 1.05 and not more than 1.1, not less than 1.1 and not more than 1.15, and not less than 1.15 and not more than 1.2. Preferably, the depth ratio is not less than 0.95 and not more than 1.05.

The depth of the separating structure 30 may be not less than 0.1 μm and not more than 3 μm. The depth of the separating structure 30 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. Preferably, the depth of the separating structure 30 is not less than 0.5 μm and not more than 1.5 μm.

The separating structure 30 may have an aspect ratio of not less than 1 and not more than 3. The aspect ratio of the separating structure 30 is the ratio of the depth of the separating structure 30 to the width of the separating structure 30. The aspect ratio may have a value belonging to at least one range among of not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. Preferably, the aspect ratio is a ratio of not less than 1.5 and not more than 2.5.

Preferably, the pitch between the central portions of the plurality of separating structures 30 (the pitch between the separating structures 30) is less than the pitch between the gate structure 15 and the source structure 20. The pitch between the plurality of separating structures 30 may be larger than the pitch between the gate structure 15 and the source structure 20.

The pitch between the separating structures 30 may be not less than 0.1 μm and not more than 2.5 μm. The pitch between the separating structures 30 may have a value belonging to at least one range among not less than 0.1 μm and not more than 0.25 μm, not less than 0.25 μm and not more than 0.5 μm, not less than 0.5 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

Each of the plurality of separating structures 30 includes a third trench 31, a third insulating film 32, and a third embedded electrode 33. The third trench 31 is formed in the first main surface 3, and demarcates wall surfaces (side walls and a bottom wall) of the separating structure 30.

The third insulating film 32 may include at least one among a silicon oxide film, a silicon nitride film, and a silicon oxynitride film. Preferably, the third insulating film 32 includes the same type of insulating material as the insulating material of the first insulating film 17 (the second insulating film 22). In this embodiment, the third insulating film 32 has a single layer structure constituted of a silicon oxide film. Particularly preferably, the third insulating film 32 includes the silicon oxide film constituted of the oxide of the chip 2.

The third insulating film 32 covers wall surfaces of the third trench 31. The third insulating film 32 includes a first film portion and a second film portion. The first film portion covers the side walls of the third trench 31 in a film shape. The second film portion covers the bottom wall of the third trench 31 in a film shape, and is continuous to the first film portion.

The second film portion has a thickness larger than a thickness of the first film portion. The thickness of the second film portion may be substantially equal to the thickness of the first film portion. The thickness of the first film portion of the third insulating film 32 may be substantially equal to the thickness of the first film portion of the first insulating film 17. The thickness of the second film portion of the third insulating film 32 may be substantially equal to the thickness of the second film portion of the first insulating film 17.

The third insulating film 32 may have a thickness of not less than 10 nm and not more than 150 nm. The thickness of the third insulating film 32 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The third embedded electrode 33 is embedded in the third trench 31 with the third insulating film 32 interposed therebetween. The third embedded electrode 33 may include either or both of a p-type conductive polysilicon and an n-type conductive polysilicon. Preferably, the third embedded electrode 33 includes the same type of conductive material as the conductive material of the first embedded electrode 18. The third embedded electrode 33 faces the second semiconductor region 7 and the body region 10 with the third insulating film 32 interposed therebetween. The third embedded electrode 33 may have a portion facing the source region 11.

The third embedded electrode 33 has an electrode surface exposed from the third trench 31. The electrode surface is positioned on a bottom wall side of the third trench 31 with respect to a height position of the first main surface 3. The electrode surface is positioned on the first main surface 3 side with respect to the depth position of the bottom portion of the source region 11. The electrode surface has, in an inner portion, a recess that is recessed in a tapered shape toward the bottom wall of the third trench 31.

The semiconductor device 1A includes one or a plurality of (in this embodiment, four) shallow well regions 35 formed in the chip 2 (the second semiconductor region 7). The shallow well region 35 may be referred to as a “third well region,” a “first separation well region,” etc. The source potential is to be applied to the shallow well region 35. The number of the shallow well regions 35 is less than the number of the separating structures 30.

The shallow well region 35 has a p-type impurity concentration higher than the n-type impurity concentration of the second semiconductor region 7. The p-type impurity concentration of the shallow well region 35 may be higher than the p-type impurity concentration of the body region 10, or may be less than the p-type impurity concentration of the body region 10.

The p-type impurity concentration of the shallow well region 35 may be substantially equal to the p-type impurity concentration of the gate well region 25. The p-type impurity concentration of the shallow well region 35 may be higher than the p-type impurity concentration of the gate well region 25, or may be lower than the p-type impurity concentration of the gate well region 25.

The p-type impurity concentration of the shallow well region 35 may be substantially equal to the p-type impurity concentration of the source well region 26. The p-type impurity concentration of the shallow well region 35 may be higher than the p-type impurity concentration of the source well region 26, or may be lower than the p-type impurity concentration of the source well region 26. Preferably, the p-type impurity (trivalent element) of the shallow well region 35 is aluminum.

The plurality of shallow well regions 35 are respectively formed in regions below (specifically, directly below) the plurality of separating structures 30 so as to be adjacent to each other in the horizontal direction in the second semiconductor region 7. The plurality of shallow well regions 35 are respectively formed in regions below the plurality of (in this embodiment, four) separating structures 30 positioned on the active region 8 side among the plurality of separating structures 30.

The plurality of shallow well regions 35 are respectively formed in thickness ranges between the bottom portion of the second semiconductor region 7 and the bottom walls of the plurality of separating structures 30, and overlap the plurality of separating structures 30 in a one-to-one correspondence in the thickness direction. The plurality of shallow well regions 35 are not formed in regions below one or a plurality (in this embodiment, one) of the separating structures 30 positioned on the peripheral edge side of the first main surface 3 (the outer peripheral region 9 side) among the plurality of separating structures 30.

The plurality of shallow well regions 35 extend in a band shape along the corresponding separating structures 30 in plan view. Each of the plurality of shallow well regions 35 has a portion extending in the first direction X along the corresponding separating structure 30 in plan view and a portion extending in the second direction Y along the corresponding separating structure 30. In this embodiment, each of the plurality of shallow well regions 35 extends in a polygonal annular shape (in this embodiment, a quadrangle annular shape) along the corresponding separating structure 30 in plan view.

The plurality of shallow well regions 35 are formed at an interval in the horizontal direction from the plurality of gate well regions 25 and the plurality of source well regions 26. In this embodiment, the plurality of shallow well regions 35 are connected to each other in the horizontal direction. The plurality of shallow well regions 35 may be formed at an interval in the horizontal direction, and may face each other in the horizontal direction with a portion of the second semiconductor region 7 interposed therebetween.

The plurality of shallow well regions 35 are formed at an interval toward the bottom wall side of each of the plurality of separating structures 30 from the bottom portion of the second semiconductor region 7, and face the first semiconductor region 6 with a portion of the second semiconductor region 7 interposed therebetween. Each of the plurality of shallow well regions 35 has an upper end portion positioned on the bottom wall side of the corresponding separating structure 30, and a bottom portion positioned on the bottom portion side of the second semiconductor region 7.

The upper end portion of each of the plurality of shallow well regions 35 may be connected to the bottom wall of the corresponding separating structure 30. The upper end portion of each of the plurality of shallow well regions 35 may extend along side walls of the corresponding separating structure 30, and may be connected to the body region 10. The upper end portion of each of the plurality of shallow well regions 35 may be formed at an interval toward the bottom portion side of the second semiconductor region 7 from the bottom wall of the corresponding separating structure 30.

The bottom portion of each of the plurality of shallow well regions 35 may be positioned on the bottom wall side of the corresponding separating structure 30 with respect to the intermediate portion of the second semiconductor region 7, or may be positioned on the bottom portion side of the second semiconductor region 7 (the second main surface 4 side) with respect to the intermediate portion of the second semiconductor region 7.

Each of the plurality of shallow well regions 35 has a bulging portion 35a. The bulging portion 35a protrudes in an arc shape in the horizontal direction from a region directly below the corresponding separating structure 30 toward both sides of the corresponding separating structure 30. A plurality of the bulging portions 35a are connected to each other in the horizontal direction. Each of the plurality of shallow well regions 35 is formed in a shape tapering toward the bottom portion from the bulging portion 35a.

The shallow well region 35 may have a width larger than the width of the separating structure 30, or may have a width less than the width of the separating structure 30. The width of the shallow well region 35 may be larger than the width of the gate structure 15, or may be less than the width of the gate structure 15. The width of the shallow well region 35 may be larger than the width of the source structure 20, or may be less than the width of the source structure 20.

The width of the shallow well region 35 may be substantially equal to the width of the gate well region 25. The width of the shallow well region 35 may be larger than the width of the gate well region 25, or may be less than the width of the gate well region 25. The width of the shallow well region 35 may be substantially equal to the width of the source well region 26. The width of the shallow well region 35 may be larger than the width of the source well region 26, or may be less than the width of the source well region 26.

A width of the shallow well region 35 may be not less than 0.1 μm and not more than 2 μm. The width of the shallow well region 35 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The shallow well region 35 may have a depth substantially equal to the depth of the gate well region 25. The depth of the shallow well region 35 is the depth of the shallow well region 35 when the bottom wall of the separating structure 30 is set as a reference. The bottom portion of the shallow well region 35 may be positioned at a depth substantially equal to the depth of the bottom portion of the gate well region 25. The depth of the shallow well region 35 may be larger than the depth of the gate well region 25, or may be less than the depth of the gate well region 25.

The depth of the shallow well region 35 may be substantially equal to the depth of the source well region 26. The bottom portion of the shallow well region 35 may be positioned at a depth substantially equal to the depth of the bottom portion of the source well region 26. The depth of the shallow well region 35 may be larger than the depth of the source well region 26, or may be less than the depth of the source well region 26.

The depth of the shallow well region 35 may be a depth larger than 0 μm and not more than 5 μm. The depth of the shallow well region 35 may have a value belonging to at least one range among larger than 0 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The shallow well region 35 may have an aspect ratio larger than 0 and not more than 2. The aspect ratio of the shallow well region 35 is a ratio of the depth of the shallow well region 35 to the width of the shallow well region 35.

The aspect ratio may have a value belonging to at least one range among larger than 0 and not more than 0.25, not less than 0.25 and not more than 0.5, not less than 0.5 and not more than 0.75, not less than 0.75 and not more than 1, not less than 1 and not more than 1.25, not less than 1.25 and not more than 1.5, not less than 1.5 and not more than 1.75, and not less than 1.75 and not more than 2.

The pitch between the central portions of the plurality of shallow well regions 35 (the pitch between the shallow well regions 35) is substantially equal to the pitch between the plurality of separating structures 30. In this embodiment, the pitch between the shallow well regions 35 is less than the pitch between the gate structure 15 and the source structure 20. The pitch between the shallow well regions 35 may be substantially equal to the pitch between the gate structure 15 and the source structure 20, or may be larger than the pitch between the gate structure 15 and the source structure 20.

In this embodiment, the pitch between the shallow well regions 35 is less than the pitch between the gate well region 25 and the source well region 26. The pitch between the shallow well regions 35 may be substantially equal to the pitch between the gate well region 25 and the source well region 26, or may be larger than the pitch between the gate well region 25 and the source well region 26.

A pitch between the shallow well regions 35 may be not less than 0.1 μm and not more than 2.5 μm. The pitch between the shallow well regions 35 may have a value belonging to at least one range among not less than 0.1 μm and not more than 0.25 μm, not less than 0.25 μm and not more than 0.5 μm, not less than 0.5 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

The shallow well region 35 forms a pn-junction portion with the second semiconductor region 7. The shallow well region 35 spreads a depletion layer in the second semiconductor region 7 when a reverse bias voltage is applied. The depletion layer with the shallow well region 35 as a starting point spreads in the horizontal direction and the thickness direction, and becomes integral with the depletion layer with the body region 10 (the inner portion of the active region 8) as a starting point. The shallow well region 35 expands the depletion layer with the body region 10 as a starting point toward the peripheral edge of the first main surface 3, and relaxes the electric field in the plurality of separating structures 30 (the peripheral edge portion of the active region 8).

The semiconductor device 1A includes one or a plurality (in this embodiment, one) of deep well regions 36 formed in the chip 2 (the second semiconductor region 7). The deep well region 36 may be referred to as a “fourth well region,” a “second separation well region,” etc. The source potential is to be applied to the deep well region 36.

The number of the deep well regions 36 is less than the number of the separating structures 30. The number of deep well regions 36 is less than the number of shallow well regions 35. The number of the deep well regions 36 may be larger than the number of the shallow well regions 35. The number of the deep well regions 36 may be the same as the number of the shallow well regions 35.

The deep well region 36 has a p-type impurity concentration higher than the n-type impurity concentration of the second semiconductor region 7. The p-type impurity concentration of the deep well region 36 may be higher than the p-type impurity concentration of the body region 10, or may be less than the p-type impurity concentration of the body region 10.

The p-type impurity concentration of the deep well region 36 may be substantially equal to the p-type impurity concentration of the gate well region 25. The p-type impurity concentration of the deep well region 36 may be higher than the p-type impurity concentration of the gate well region 25, or may be lower than the p-type impurity concentration of the gate well region 25.

The p-type impurity concentration of the deep well region 36 may be substantially equal to the p-type impurity concentration of the source well region 26. The p-type impurity concentration of the deep well region 36 may be higher than the p-type impurity concentration of the source well region 26, or may be lower than the p-type impurity concentration of the source well region 26.

The p-type impurity concentration of the deep well region 36 may be substantially equal to the p-type impurity concentration of the shallow well region 35. The p-type impurity concentration of the deep well region 36 may be higher than the p-type impurity concentration of the shallow well region 35, or may be lower than the p-type impurity concentration of the shallow well region 35. Preferably, the p-type impurity (trivalent element) of the deep well region 36 is aluminum.

The deep well region 36 is positioned on the peripheral edge side of the first main surface 3 (the outer peripheral region 9 side) with respect to the plurality of shallow well regions 35 in the chip 2 (the second semiconductor region 7). That is, the deep well region 36 is formed in a region below (specifically, directly below) the separating structure 30 positioned on the outer peripheral region 9 side (the peripheral edge side of the first main surface 3) among the plurality of separating structures 30.

The deep well region 36 is formed at an interval toward the outer peripheral region 9 side from the separating structure 30 for the shallow well region 35, and does not overlap the separating structure 30 for the shallow well region 35 in the thickness direction. In this embodiment, the deep well region 36 is formed in a region below the outermost separating structure 30 that is arranged closest to the outer peripheral region 9 side among the plurality of separating structures 30.

The deep well region 36 is formed in a thickness range between the bottom portion of the second semiconductor region 7 and the bottom wall of the outermost separating structure 30, and overlaps the outermost separating structure 30 in a one-to-one correspondence in the thickness direction. The deep well region 36 is not formed in a region below one or a plurality (in this embodiment, a plurality) of the separating structures 30 positioned on the peripheral edge side of the first main surface 3 (the outer peripheral region 9 side) among the plurality of separating structures 30.

The deep well region 36 extends in a band shape along the outermost separating structure 30 in plan view. The deep well region 36 has a portion extending in the first direction X along the outermost separating structure 30 and a portion extending in the second direction Y along the outermost separating structure 30 in plan view.

In this embodiment, the deep well region 36 is formed in a polygonal annular shape (in this embodiment, a quadrangle annular shape) extending along the outermost separating structure 30 in plan view. The deep well region 36 is formed at an interval in the horizontal direction from the plurality of gate well regions 25 and the plurality of source well regions 26.

In this embodiment, the deep well region 36 is connected to the outermost shallow well region 35 in the horizontal direction. The deep well region 36 may be formed at an interval from the outermost shallow well region 35 in the horizontal direction. The deep well region 36 is formed at an interval toward the bottom wall side of the outermost separating structure 30 from the bottom portion of the second semiconductor region 7, and faces the first semiconductor region 6 with a portion of the second semiconductor region 7 interposed therebetween.

The deep well region 36 has a depth larger than the depth of the plurality of shallow well regions 35, and is formed in a vertically long columnar shape extending in the thickness direction of the chip 2. The depth of the deep well region 36 is the depth of the deep well region 36 when the bottom wall of the outermost separating structure 30 is set as a reference.

The depth of the deep well region 36 is larger than the depth of the gate well region 25. The depth of the deep well region 36 is larger than the depth of the source well region 26. The depth of the deep well region 36 may be larger than the depth of the outermost separating structure 30, or may be less than the depth of the outermost separating structure 30.

The depth of the deep well region 36 may be larger than the depth of the gate structure 15, or may be less than the depth of the gate structure 15. The depth of the deep well region 36 may be larger than the depth of the source structure 20, or may be less than the depth of the source structure 20.

The depth of the deep well region 36 may be a depth larger than 0 μm and not more than 5 μm. The depth of the deep well region 36 may have a value belonging to at least one range among larger than 0 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The deep well region 36 may have an aspect ratio larger than 0 and not more than 5. The aspect ratio of the deep well region 36 is a ratio of the depth of the deep well region 36 to the width of the deep well region 36.

The aspect ratio may have a value belonging to at least one range among larger than 0 and not more than 1, not less than 1 and not more than 1.5, not less than 1.5 and not more than 2, not less than 2 and not more than 2.5, not less than 2.5 and not more than 3, not less than 3 and not more than 3.5, not less than 3.5 and not more than 4, not less than 4 and not more than 4.5, and not less than 4.5 and not more than 5. Preferably, the aspect ratio of the deep well region 36 is larger than 1.

The deep well region 36 has an upper end portion positioned on the bottom wall side of the outermost separating structure 30 and a bottom portion positioned on the bottom portion side of the second semiconductor region 7. The upper end portion of the deep well region 36 is positioned on the separating structure 30 side with respect to the bottom portions of the plurality of gate well regions 25, the bottom portions of the plurality of source well regions 26, and the bottom portions of the plurality of shallow well regions 35. The upper end portion of the deep well region 36 faces the plurality of gate well regions 25, the plurality of source well regions 26, and the plurality of shallow well regions 35 in the horizontal direction.

The upper end of the deep well region 36 may be connected to the bottom wall of the outermost separating structure 30. The upper end portion of the deep well region 36 may extend along side walls of the outermost separating structure 30, and may be connected to the body region 10. The upper end portion of the deep well region 36 may be formed at an interval toward the bottom portion side of the second semiconductor region 7 from the bottom wall of the outermost separating structure 30.

The bottom portion of the deep well region 36 is positioned on the bottom portion side of the second semiconductor region 7 with respect to the bottom portions of the plurality of gate well regions 25, the bottom portions of the plurality of source well regions 26, and the bottom portions of the plurality of shallow well regions 35. The bottom portion of the deep well region 36 does not face the plurality of gate well regions 25, the plurality of source well regions 26, and the plurality of shallow well regions 35 in the horizontal direction.

The bottom portion of the deep well region 36 may be positioned on the bottom wall side of the outermost separating structure 30 with respect to the intermediate portion of the second semiconductor region 7, or may be positioned on the bottom portion side of the second semiconductor region 7 (the second main surface 4 side) with respect to the intermediate portion of the second semiconductor region 7.

The deep well region 36 has a plurality of (in this embodiment, two) bulging portions 36a and one or a plurality (in this embodiment, one) of constricted portions 36b in the thickness direction of the chip 2.

The plurality of bulging portions 36a are respectively formed at different depth positions in the thickness direction of the chip 2. The plurality of bulging portions 36a are respectively formed by a plurality of (in this embodiment, two) impurity regions (36a) of the p-type positioned at different depths along the thickness direction of the chip 2. The plurality of bulging portions 36a respectively protrude in an arc shape in the horizontal direction from a region directly below the outermost separating structure 30 to both sides of the outermost separating structure 30.

The plurality of bulging portions 36a include the bulging portion 36a on the upper side (the separating structure 30 side) and the bulging portion 36a on the lower side (the bottom portion side of the second semiconductor region 7). The upper bulging portion 36a is positioned at a depth substantially equal to the depth of the bulging portion 35a of each of the plurality of shallow well regions 35. The upper bulging portion 36a is connected to the bulging portion 35a of the outermost shallow well region 35. The upper bulging portion 36a may be formed at an interval in the horizontal direction from the outermost shallow well region 35.

The upper bulging portion 36a is positioned at a depth substantially equal to the depth of the bulging portion 25a of the gate well region 25. With respect to a depth position of the bulging portion 25a of the gate well region 25, the upper bulging portion 36a may be positioned on the first main surface 3 side or may be positioned on the bottom portion side of the second semiconductor region 7.

The upper bulging portion 36a is positioned at a depth substantially equal to the depth of the bulging portion 26a of the source well region 26. With respect to a depth position of the bulging portion 26a of the source well region 26, the upper bulging portion 36a may be positioned on the first main surface 3 side or may be positioned on the bottom portion side of the second semiconductor region 7.

The lower bulging portion 36a is positioned on the bottom portion side of the second semiconductor region 7 with respect to a depth position of the bottom portion of each of the plurality of shallow well regions 35, and does not face the plurality of shallow well regions 35 in the horizontal direction. The lower bulging portion 36a does not face the plurality of gate well regions 25 in the horizontal direction. The lower bulging portion 36a does not face the plurality of source well regions 26 in the horizontal direction.

The lower bulging portion 36a is formed in a shape tapering toward the bottom portion. Preferably, a p-type impurity concentration of an intermediate portion of the lower bulging portion 36a is lower than a p-type impurity concentration of an intermediate portion of the upper bulging portion 36a. That is, preferably, the p-type impurity concentration of the plurality of bulging portions 36a gradually decrease toward the bottom portion side of the second semiconductor region 7.

The bulging portion 36a may have a width larger than the width of the outermost separating structure 30, or may have a width less than the width of the outermost separating structure 30. The width of the bulging portion 36a may be larger than the width of the gate structure 15, or may be less than the width of the gate structure 15. The width of the bulging portion 36a may be larger than the width of the source structure 20, or may be less than the width of the source structure 20.

The width of the bulging portion 36a may be substantially equal to the width of the gate well region 25. The width of the bulging portion 36a may be larger than the width of the gate well region 25, or may be less than the width of the gate well region 25. The width of the bulging portion 36a may be substantially equal to the width of the source well region 26. The width of the bulging portion 36a may be larger than the width of the source well region 26, or may be less than the width of the source well region 26.

The width of the bulging portion 36a may be substantially equal to the width of the shallow well region 35. The width of the bulging portion 36a may be larger than the width of the shallow well region 35, or may be less than the width of the shallow well region 35.

The width of the bulging portion 36a may be not less than 0.1 μm and not more than 2 μm. The width of the bulging portion 36a may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The constricted portion 36b forms a connection portion between the plurality of bulging portions 36a in a region between the plurality of bulging portions 36a, and is recessed in an arc shape from the plurality of bulging portions 36a toward the inside in the horizontal direction. That is, the constricted portion 36b is formed by the connection portion between the plurality of impurity regions (36a) overlapping in the vertical direction.

The constricted portion 36b includes a p-type impurity on a lower end portion side of the upper bulging portion 36a and a p-type impurity on an upper end portion side of the lower bulging portion 36a. The p-type impurity concentration of the constricted portion 36b may be higher than the p-type impurity concentration on the lower end portion side of the upper bulging portion 36a and the p-type impurity concentration on the upper end portion side of the lower bulging portion 36a. The p-type impurity concentration of the constricted portion 36b may be lower than the p-type impurity concentration of an intermediate portion of the upper bulging portion 36a and the p-type impurity concentration of an intermediate portion of the lower bulging portion 36a.

The constricted portion 36b is formed at an interval in the horizontal direction from the outermost shallow well region 35. The constricted portion 36b is formed in a region on the separating structure 30 side with respect to the bottom portion of the outermost shallow well region 35, and faces the outermost shallow well region 35 in the horizontal direction. The constricted portion 36b may be positioned on the bottom portion side of the second semiconductor region 7 with respect to the bottom portion of the outermost shallow well region 35.

The constricted portion 36b has a width less than the width of the bulging portion 36a. The width of the constricted portion 36b may be larger than the width of the outermost separating structure 30, or may be less than the width of the outermost separating structure 30. The width of the constricted portion 36b may be larger than the width of the gate structure 15, or may be less than the width of the gate structure 15. The width of the constricted portion 36b may be larger than the width of the source structure 20, or may be less than the width of the source structure 20.

The width of the constricted portion 36b may be larger than the width of the gate well region 25, or may be less than the width of the gate well region 25. The width of the constricted portion 36b may be larger than the width of the source well region 26, or may be less than the width of the source well region 26. The width of the constricted portion 36b may be substantially equal to the width of the shallow well region 35. The width of the constricted portion 36b may be larger than the width of the shallow well region 35, or may be less than the width of the shallow well region 35.

The width of the constricted portion 36b may be not less than 0.1 μm and not more than 2 μm. The width of the constricted portion 36b may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

A pitch of the central portion of the deep well region 36 with respect to the central portion of the shallow well region 35 (a pitch between the deep well regions 36) is substantially equal to the pitch between the plurality of separating structures 30. The pitch between the deep well regions 36 is less than the pitch between the gate structure 15 and the source structure 20. The pitch between the deep well regions 36 may be substantially equal to the pitch between the gate structure 15 and the source structure 20, or may be larger than the pitch between the gate structure 15 and the source structure 20.

In this embodiment, the pitch between the deep well regions 36 is less than the pitch between the gate well region 25 and the source well region 26. The pitch between the deep well regions 36 may be substantially equal to the pitch between the gate well region 25 and the source well region 26, or may be larger than the pitch between the gate well region 25 and the source well region 26.

The pitch between the deep well regions 36 is substantially equal to the pitch between the shallow well regions 35. The pitch between the deep well regions 36 may be larger than the pitch between the shallow well regions 35, or may be smaller than the pitch between the shallow well regions 35.

A pitch between the deep well regions 36 may be not less than 0.1 μm and not more than 2.5 μm. The pitch between the deep well regions 36 may have a value belonging to at least one range among not less than 0.1 μm and not more than 0.25 μm, not less than 0.25 μm and not more than 0.5 μm, not less than 0.5 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

The deep well region 36 forms a pn-junction portion with the second semiconductor region 7. The deep well region 36 spreads a depletion layer in the second semiconductor region 7 when a reverse bias voltage is applied. The depletion layer with the deep well region 36 as a starting point spreads in the horizontal direction and the thickness direction, and becomes integral with the depletion layer with the shallow well region 35 as a starting point.

The depletion layer with the deep well region 36 as a starting point is formed in a region below the second semiconductor region 7 with respect to the depletion layer with the shallow well region 35 as a starting point. The deep well region 36 expands the depletion layer with the shallow well region 35 as a starting point toward the peripheral edge of the first main surface 3, and relaxes the electric field in the plurality of separating structures 30 (the peripheral edge portion of the active region 8).

The semiconductor device 1A includes one or a plurality of (in this embodiment, four) shallow contact regions 37 formed in the chip 2 (the second semiconductor region 7). The shallow contact region 37 may be referred to as a “third contact region,” etc. The source potential is to be applied to the shallow contact region 37. The shallow contact region 37 has a p-type impurity concentration higher than the n-type impurity concentration of the second semiconductor region 7. The p-type impurity concentration of the shallow contact region 37 is higher than the p-type impurity concentration of the body region 10.

The p-type impurity concentration of the shallow contact region 37 is higher than the p-type impurity concentration of the shallow well region 35. The p-type impurity concentration of the shallow contact region 37 is higher than the p-type impurity concentration of the deep well region 36. The p-type impurity concentration of the shallow contact region 37 is higher than the p-type impurity concentration of the gate well region 25. The p-type impurity concentration of the shallow contact region 37 is higher than the p-type impurity concentration of the source well region 26.

The p-type impurity concentration of the shallow contact region 37 may be substantially equal to the p-type impurity concentration of the gate contact region 27. The p-type impurity concentration of the shallow contact region 37 may be higher than the p-type impurity concentration of the gate contact region 27, or may be lower than the p-type impurity concentration of the gate contact region 27.

The p-type impurity concentration of the shallow contact region 37 may be substantially equal to the p-type impurity concentration of the source contact region 28. The p-type impurity concentration of the shallow contact region 37 may be higher than the p-type impurity concentration of the source contact region 28, or may be lower than the p-type impurity concentration of the source contact region 28.

The plurality of shallow contact regions 37 are respectively formed in regions along the plurality of separating structures 30 for the shallow well regions 35. The plurality of shallow contact regions 37 are formed at an interval in regions between the plurality of separating structures 30, and face each other with a portion of the second semiconductor region 7 interposed therebetween. The plurality of shallow contact regions 37 may be connected to each other in regions between the plurality of separating structures 30.

The plurality of shallow contact regions 37 are respectively formed at an interval from the plurality of gate structures 15 and the plurality of source structures 20. The plurality of shallow contact regions 37 are formed in a one-to-one correspondence with the plurality of separating structures 30. The plurality of shallow contact regions 37 are respectively interposed in regions between the bottom walls of the corresponding separating structures 30 and the bottom portions of the corresponding shallow well regions 35, and respectively extend in a band shape along the corresponding separating structures 30.

Each of the plurality of shallow contact regions 37 has a portion extending in the first direction X along the corresponding separating structure 30 in plan view and a portion extending in the second direction Y along the corresponding separating structure 30. In this embodiment, each of the plurality of shallow contact regions 37 extends in a polygonal annular shape (in this embodiment, a quadrangle annular shape) along the corresponding separating structure 30 in plan view.

The plurality of shallow contact regions 37 may be formed at an interval along the extension direction of the corresponding separating structures 30. In this case, the plurality of shallow contact regions 37 may respectively extend in a band shape along the extension direction of the corresponding separating structures 30.

Each of the plurality of shallow contact regions 37 is connected to the bottom wall of the corresponding separating structure 30 and the corresponding shallow well region 35. Each of the plurality of shallow contact regions 37 increases the p-type impurity concentration of the upper end portion of the corresponding shallow well region 35. Each of the plurality of shallow contact regions 37 has an extension portion that protrudes from a region directly below the separating structure 30 to both sides of the separating structure 30 and extends along the side walls of the corresponding separating structure 30.

A thickness of the portion (the extension portion) of each of the plurality of shallow contact regions 37 along the side walls of the separating structure 30 in the horizontal direction (the first direction X) may be less than a thickness of the portion of each of the plurality of shallow contact regions 37 along the bottom wall of the separating structure 30 in the vertical direction Z.

The extension portion of each of the plurality of shallow contact regions 37 is electrically connected to the body region 10 in the surface layer portion of the first main surface 3, and electrically connects the corresponding shallow well region 35 to the body region 10. Thereby, each of the plurality of shallow well regions 35 is prevented from being put in an electrically floating state, and the electrical response characteristics of each of the plurality of shallow well region 35 are improved.

Each of the plurality of shallow contact regions 37 has an upper end portion exposed from the first main surface 3. In this embodiment, the upper end portion of each of the plurality of shallow contact regions 37 is exposed from the side wall of the third trench 31 at an opening end of the third trench 31.

The upper end portion of each of the plurality of shallow contact regions 37 may extend in the horizontal direction in the surface layer portion of the body region 10. The upper end portions of the plurality of shallow contact regions 37 are electrically connected to each other in the body region 10. In this embodiment, the upper end portions of the plurality of shallow contact regions 37 are integrally formed in the body region 10.

The semiconductor device 1A includes one or a plurality (one) of deep contact regions 38 formed in the chip 2 (the second semiconductor region 7). The deep contact region 38 may be referred to as a “fourth contact region,” etc. The source potential is to be applied to the deep contact region 38. The deep contact region 38 has a p-type impurity concentration higher than the n-type impurity concentration of the second semiconductor region 7. The p-type impurity concentration of the deep contact region 38 is higher than the p-type impurity concentration of the body region 10.

The p-type impurity concentration of the deep contact region 38 is higher than the p-type impurity concentration of the deep well region 36. The p-type impurity concentration of the deep contact region 38 is higher than the p-type impurity concentration of the shallow well region 35. The p-type impurity concentration of the deep contact region 38 is higher than the p-type impurity concentration of the gate well region 25. The p-type impurity concentration of the deep contact region 38 is higher than the p-type impurity concentration of the source well region 26.

The p-type impurity concentration of the deep contact region 38 may be substantially equal to the p-type impurity concentration of the shallow contact region 37. The p-type impurity concentration of the deep contact region 38 may be higher than the p-type impurity concentration of the shallow contact region 37, or may be lower than the p-type impurity concentration of the shallow contact region 37.

The p-type impurity concentration of the deep contact region 38 may be substantially equal to the p-type impurity concentration of the gate contact region 27. The p-type impurity concentration of the deep contact region 38 may be higher than the p-type impurity concentration of the gate contact region 27, or may be lower than the p-type impurity concentration of the gate contact region 27.

The p-type impurity concentration of the deep contact region 38 may be substantially equal to the p-type impurity concentration of the source contact region 28. The p-type impurity concentration of the deep contact region 38 may be higher than the p-type impurity concentration of the source contact region 28, or may be lower than the p-type impurity concentration of the source contact region 28.

The deep contact region 38 is formed in a region along the separating structure 30 (in this embodiment, the outermost separating structure 30) for the deep well region 36. The deep contact region 38 is formed at an interval from the separating structure 30 for the shallow well region 35.

The deep contact region 38 is formed at an interval from the outermost shallow contact region 37 in the region between the plurality of separating structures 30, and faces the outermost shallow contact region 37 with a portion of the second semiconductor region 7 interposed therebetween. The deep contact region 38 may be connected to the outermost shallow contact region 37 in the region between the plurality of separating structures 30.

The deep contact region 38 is formed at an interval from the plurality of gate structures 15 and the plurality of source structures 20. The deep contact region 38 is formed in a one-to-one correspondence with the corresponding separating structure 30 (that is, the outermost separating structure 30).

The deep contact region 38 is interposed in a region between the bottom wall of the outermost separating structure 30 and the bottom portion of the deep well region 36, and extends in a band shape along the outermost separating structure 30. The deep contact region 38 has a portion extending in the first direction X along the outermost separating structure 30 and a portion extending in the second direction Y along the outermost separating structure 30 in plan view. In this embodiment, the deep contact region 38 extends in a polygonal annular shape (in this embodiment, a quadrangle annular shape) along the outermost separating structure 30 in plan view.

The deep contact region 38 may be formed at an interval along the extension direction of the outermost separating structure 30. In this case, the deep contact region 38 may respectively extend in a band shape along the extension direction of the outermost separating structure 30.

The deep contact region 38 is connected to the bottom wall of the outermost separating structure 30 and the deep well region 36. The deep contact region 38 increases the p-type impurity concentration of the upper end portion of the deep well region 36. The deep contact region 38 has an extension portion that protrudes from a region directly below the separating structure 30 to both sides of the separating structure 30 and extends along the side walls of the outermost separating structure 30.

The deep contact region 38 has an extension portion on one side that extends along the side wall of the outermost separating structure 30 on the active region 8 side and an extension portion on the other side that extends along the side wall of the outermost separating structure 30 on the outer peripheral region 9 side. A thickness of the portion (the extension portion) of the deep contact region 38 along the side walls of the outermost separating structure 30 in the horizontal direction (the first direction X) may be less than a thickness of the portion of the deep contact region 38 along the bottom wall of the outermost separating structure 30 in the vertical direction Z.

The extension portion of the deep contact region 38 is electrically connected to the body region 10 in the surface layer portion of the first main surface 3, and electrically connects the deep well region 36 to the body region 10. Thereby, each of the plurality of deep well regions 36 is prevented from being put in an electrically floating state, and the electrical response characteristics of each of the plurality of deep well regions 36 are improved.

The deep contact region 38 has an upper end portion exposed from the first main surface 3. In this embodiment, the upper end portion of the deep contact region 38 is exposed from the side wall of the third trench 31 at an opening end of the third trench 31.

The upper end portion of the deep contact region 38 may extend in the horizontal direction in the surface layer portion of the body region 10. The upper end portion of the deep contact region 38 is electrically connected to the shallow contact region 37 in the body region 10. In this embodiment, the upper end portion of the deep contact region 38 is integrally formed with the shallow contact region 37 in the body region 10.

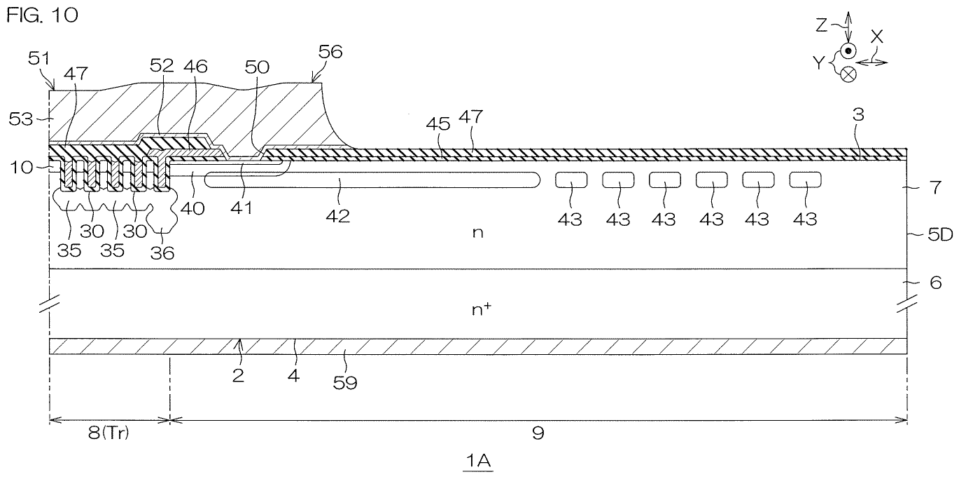

With reference to FIG. 9 and FIG. 10, the semiconductor device 1A includes an outer well region 40 of the p-type formed in the surface layer portion of the first main surface 3 in the outer peripheral region 9. The source potential is to be applied to the outer well region 40. The outer well region 40 has a p-type impurity concentration higher than the n-type impurity concentration of the second semiconductor region 7.

The p-type impurity concentration of the outer well region 40 is less than the p-type impurity concentration of the deep contact region 38. The p-type impurity concentration of the outer well region 40 is less than the p-type impurity concentration of the shallow contact region 37. The p-type impurity concentration of the outer well region 40 is less than the p-type impurity concentration of the gate contact region 27. The p-type impurity concentration of the outer well region 40 is less than the p-type impurity concentration of the source contact region 28.

The p-type impurity concentration of the outer well region 40 may be substantially equal to the p-type impurity concentration of the deep well region 36. The p-type impurity concentration of the outer well region 40 may be higher than the p-type impurity concentration of the deep well region 36, or may be less than the p-type impurity concentration of the deep well region 36. The p-type impurity concentration of the outer well region 40 may be substantially equal to the p-type impurity concentration of the shallow well region 35. The p-type impurity concentration of the outer well region 40 may be higher than the p-type impurity concentration of the shallow well region 35, or may be less than the p-type impurity concentration of the shallow well region 35.

The p-type impurity concentration of the outer well region 40 may be substantially equal to the p-type impurity concentration of the gate well region 25. The p-type impurity concentration of the outer well region 40 may be higher than the p-type impurity concentration of the gate well region 25, or may be less than the p-type impurity concentration of the gate well region 25.

The p-type impurity concentration of the outer well region 40 may be substantially equal to the p-type impurity concentration of the source well region 26. The p-type impurity concentration of the outer well region 40 may be higher than the p-type impurity concentration of the source well region 26, or may be less than the p-type impurity concentration of the source well region 26.

The p-type impurity concentration of the outer well region 40 may be substantially equal to the p-type impurity concentration of the body region 10. The p-type impurity concentration of the outer well region 40 may be higher than the p-type impurity concentration of the body region 10, or may be less than the p-type impurity concentration of the body region 10.

The outer well region 40 is formed in a region between the peripheral edge of the first main surface 3 and the outermost separating structure 30 (the active region 8). The outer well region 40 is formed in the surface layer portion of the second semiconductor region 7, and is electrically connected to the second semiconductor region 7. The outer well region 40 extends in a layer shape along the first main surface 3.

The outer well region 40 is formed at an interval from the peripheral edge (the first to fourth side surfaces 5A to 5D) of the first main surface 3 toward the inner side of the first main surface 3 (the active region 8 side). The outer well region 40 extends in a band shape along the outermost separating structure 30 in plan view. The outer well region 40 has a portion extending in the first direction X along the outermost separating structure 30 and a portion extending in the second direction Y along the outermost separating structure 30 in plan view.

In this embodiment, the outer well region 40 is formed in a polygonal annular shape (in this embodiment, a quadrangle annular shape) having four sides parallel to the peripheral edge of the chip 2 in plan view, and surrounds the inner portion of the first main surface 3 (the active region 8). The outer well region 40 may have an edge portion that connects a portion extending in the first direction X and a portion extending in the second direction Y in an arc shape (preferably, a quarter arc shape).

The outer well region 40 has an inner edge portion on the outermost separating structure 30 side (the inner side of the first main surface 3) and an outer edge portion on the peripheral edge side of the first main surface 3. In this embodiment, the inner edge portion of the outer well region 40 is connected to the outermost separating structure 30. The inner edge portion of the outer well region 40 may be formed at an interval toward the peripheral edge side of the first main surface 3 from the outermost separating structure 30.

The outer well region 40 is formed at an interval toward the first main surface 3 side from the bottom portion of the second semiconductor region 7, and faces the first semiconductor region 6 with a portion of the second semiconductor region 7 interposed therebetween. Preferably, the outer well region 40 is formed at an interval toward the first main surface 3 side from the depth position of the intermediate portion of the second semiconductor region 7.

The outer well region 40 has an upper end portion exposed from the first main surface 3 and a bottom portion positioned in the second semiconductor region 7. The bottom portion of the outer well region 40 is positioned on the bottom portion side of the second semiconductor region 7 with respect to a depth position of the bottom portion of the body region 10. The bottom portion of the outer well region 40 may be positioned on the first main surface 3 side with respect to the depth position of the bottom portion of the body region 10.

The bottom portion of the outer well region 40 is positioned on the first main surface 3 side with respect to a depth position of the bottom portion of the deep well region 36. The bottom portion of the outer well region 40 may be positioned on the bottom portion side of the second semiconductor region 7 with respect to the depth position of the bottom portion of the deep well region 36. The bottom portion of the outer well region 40 is positioned on the first main surface 3 side with respect to the depth position of the bottom portion of the shallow well region 35. The bottom portion of the outer well region 40 may be positioned on the bottom portion side of the second semiconductor region 7 with respect to the depth position of the bottom portion of the shallow well region 35.

The bottom portion of the outer well region 40 is positioned on the first main surface 3 side with respect to a depth position of the bottom portion of the gate well region 25. The bottom portion of the outer well region 40 may be positioned on the bottom portion side of the second semiconductor region 7 with respect to the depth position of the bottom portion of the gate well region 25. The bottom portion of the outer well region 40 is positioned on the first main surface 3 side with respect to a depth position of the bottom portion of the source well region 26. The bottom portion of the outer well region 40 may be positioned on the bottom portion side of the second semiconductor region 7 with respect to the depth position of the bottom portion of the source well region 26.

The bottom portion of the outer well region 40 is positioned on the first main surface 3 side with respect to a depth position of the bottom wall of the separating structure 30. The bottom portion of the outer well region 40 may be positioned on the bottom portion side of the second semiconductor region 7 with respect to the depth position of the bottom wall of the separating structure 30. The bottom portion of the outer well region 40 is positioned on the first main surface 3 side with respect to a depth position of the bottom wall of the gate structure 15. The bottom portion of the outer well region 40 may be positioned on the bottom portion side of the second semiconductor region 7 with respect to the depth position of the bottom wall of the gate structure 15.

The bottom portion of the outer well region 40 is positioned on the first main surface 3 side with respect to a depth position of the bottom wall of the source structure 20. The bottom portion of the outer well region 40 may be positioned on the bottom portion side of the second semiconductor region 7 with respect to the depth position of the bottom wall of the source structure 20.

In this embodiment, the outer well region 40 is formed at an interval toward the first main surface 3 side, and does not have a direct connection portion with the deep well region 36 from the depth position of the upper end portion of the deep well region 36.

In a case where the bottom portion of the outer well region 40 is positioned on the bottom portion side of the second semiconductor region 7 with respect to the depth position of the bottom wall of the separating structure 30, the outer well region 40 may have a portion connected to the deep well region 36. The bottom portion of the outer well region 40 may be connected to the upper end portion of the deep well region 36.

The outer well region 40 has a width larger than the width of the deep well region 36. The width of the outer well region 40 is larger than the width of the outermost separating structure 30. The width of the outer well region 40 may be larger than the total width of the plurality of separating structures 30. The width of the outer well region 40 may be larger than the total width of the plurality of shallow well regions 35 and deep well regions 36.

The width of the outer well region 40 may be larger than 0 μm and not more than 300 μm. The width of the outer well region 40 may have a value belonging to at least one range among larger than 0 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, and not less than 275 μm and not more than 300 μm.

A depth (thickness) of the outer well region 40 may be larger than 0 μm and not more than 5 μm. The depth of the outer well region 40 may have a value belonging to at least one range among larger than 0 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The outer well region 40 forms a pn-junction portion with the second semiconductor region 7. The outer well region 40 spreads a depletion layer in the second semiconductor region 7 when a reverse bias voltage is applied. The depletion layer with the outer well region 40 as a starting point spreads in the horizontal direction and the thickness direction, and becomes integral with the depletion layer with the deep well region 36 as a starting point. The outer well region 40 expands the depletion layer with the deep well region 36 as a starting point toward the peripheral edge of the first main surface 3, and relaxes the electric field in the peripheral edge portion (the outer peripheral region 9) of the first main surface 3.

The semiconductor device 1A includes an outer contact region 41 of the p-type formed in the surface layer portion of the first main surface 3 in the outer peripheral region 9. The source potential is to be applied to the outer contact region 41. The outer contact region 41 has a p-type impurity concentration higher than the n-type impurity concentration of the second semiconductor region 7. The p-type impurity concentration of the outer contact region 41 is higher than the p-type impurity concentration of the body region 10.

The p-type impurity concentration of the outer contact region 41 is higher than the p-type impurity concentration of the deep well region 36. The p-type impurity concentration of the outer contact region 41 is higher than the p-type impurity concentration of the shallow well region 35. The p-type impurity concentration of the outer contact region 41 is higher than the p-type impurity concentration of the gate well region 25. The p-type impurity concentration of the outer contact region 41 is higher than the p-type impurity concentration of the source well region 26.

The p-type impurity concentration of the outer contact region 41 may be substantially equal to the p-type impurity concentration of the deep contact region 38. The p-type impurity concentration of the outer contact region 41 may be higher than the p-type impurity concentration of the deep contact region 38, or may be lower than the p-type impurity concentration of the deep contact region 38.

The p-type impurity concentration of the outer contact region 41 may be substantially equal to the p-type impurity concentration of the shallow contact region 37. The p-type impurity concentration of the outer contact region 41 may be higher than the p-type impurity concentration of the shallow contact region 37, or may be lower than the p-type impurity concentration of the shallow contact region 37.

The p-type impurity concentration of the outer contact region 41 may be substantially equal to the p-type impurity concentration of the gate contact region 27. The p-type impurity concentration of the outer contact region 41 may be higher than the p-type impurity concentration of the gate contact region 27, or may be lower than the p-type impurity concentration of the gate contact region 27.

The p-type impurity concentration of the outer contact region 41 may be substantially equal to the p-type impurity concentration of the source contact region 28. The p-type impurity concentration of the outer contact region 41 may be higher than the p-type impurity concentration of the source contact region 28, or may be lower than the p-type impurity concentration of the source contact region 28.

The outer contact region 41 is formed in the surface layer portion of the outer well region 40. That is, the outer contact region 41 is formed in a thickness range between the first main surface 3 and the bottom portion of the outer well region 40. The outer contact region 41 increases the p-type impurity concentration of the outer well region 40, and improves the electrical response speed of the outer well region 40.

The outer contact region 41 extends in a band shape along the outermost separating structure 30 (the outer well region 40) in plan view. The outer contact region 41 has a portion extending in the first direction X along the outermost separating structure 30 and a portion extending in the second direction Y along the outermost separating structure 30 in plan view.

In this embodiment, the outer contact region 41 is formed in a polygonal annular shape (in this embodiment, a quadrangle annular shape) having four sides parallel to the peripheral edge of the chip 2 in plan view, and surrounds the inner portion of the first main surface 3 (the outermost separating structure 30). The outer contact region 41 may have an edge portion that connects a portion extending in the first direction X and a portion extending in the second direction Y in an arc shape (preferably, a quarter arc shape).

A plurality of the outer contact regions 41 may be formed at an interval along the extension direction of the outermost separating structure 30. In this case, the plurality of outer contact regions 41 may respectively extend in a band shape along the extension direction of the corresponding separating structures 30.

The outer contact region 41 has a width less than the width of the outer well region 40, and is formed in the outer well region 40. The outer contact region 41 has an inner edge portion on the inner side of the first main surface 3 (the active region 8 side) and an outer edge portion on the peripheral edge side of the first main surface 3.

In this embodiment, the inner edge portion of the outer contact region 41 is connected to the outermost separating structure 30. In this embodiment, the inner edge portion of the outer contact region 41 is connected to the deep contact region 38 along the outermost separating structure 30. The outer well region 40 is electrically connected to the body region 10 via the deep contact region 38. The outer well region 40 may be formed at an interval from the deep contact region 38 (the outermost separating structure 30).

The outer edge portion of the outer contact region 41 is formed at an interval toward the outermost separating structure 30 side from the outer edge portion of the outer well region 40. The outer contact region 41 may have a portion that crosses the outer edge portion of the outer well region 40 and is connected to the second semiconductor region 7.

The outer contact region 41 has a width larger than the width of the deep well region 36. The width of the outer contact region 41 is larger than the width of the outermost separating structure 30. The width of the outer contact region 41 may be larger than the total width of the plurality of separating structures 30. The width of the outer contact region 41 may be larger than the total width of the plurality of shallow well regions 35 and deep well regions 36. The width of the outer contact region 41 may be less than the width of the outer well region 40. The width of the outer contact region 41 may be larger than the width of the outer well region 40.

The width of the outer contact region 41 may be larger than 0 μm and not more than 300 μm. The width of the outer contact region 41 may have a value belonging to at least one range among larger than 0 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, and not less than 275 μm and not more than 300 μm.

The outer contact region 41 has an upper end portion positioned on the first main surface 3 side and a bottom portion positioned on the bottom portion side of the outer well region 40. The upper end portion of the outer contact region 41 is exposed from the first main surface 3.

The bottom portion of the outer contact region 41 is positioned on the first main surface 3 side with respect to the depth position of the bottom portion of the deep well region 36. The bottom portion of the outer well region 40 is positioned on the first main surface 3 side with respect to the depth position of the bottom portion of the shallow well region 35.

The bottom portion of the outer well region 40 is positioned on the first main surface 3 side with respect to a depth position of the bottom portion of the gate well region 25. The bottom portion of the outer well region 40 is positioned on the first main surface 3 side with respect to a depth position of the bottom portion of the source well region 26.

The bottom portion of the outer well region 40 is positioned on the first main surface 3 side with respect to a depth position of the bottom wall of the separating structure 30. The bottom portion of the outer well region 40 is positioned on the first main surface 3 side with respect to a depth position of the bottom wall of the gate structure 15. The bottom portion of the outer well region 40 is positioned on the first main surface 3 side with respect to a depth position of the bottom wall of the source structure 20.

The bottom portion of the outer contact region 41 is positioned on the first main surface 3 side with respect to a depth position of the bottom portion of the outer well region 40. With respect to the depth position of the bottom portion of the body region 10, the bottom portion of the outer well region 40 may be positioned on the first main surface 3 side or may be positioned on the bottom portion side of the outer well region 40.

The bottom portion of the outer contact region 41 may be positioned at a depth substantially equal to the depth of the bottom portion of the upper end portion of the deep contact region 38. With respect to a depth position of the bottom portion of the upper end portion of the deep contact region 38, the bottom portion of the outer contact region 41 may be positioned on the first main surface 3 side or may be positioned on the bottom portion side of the deep contact region 38.

The bottom portion of the outer contact region 41 may be positioned at a depth substantially equal to the depth of the bottom portion of the upper end portion of the shallow contact region 37. With respect to a depth position of the bottom portion of the upper end portion of the shallow contact region 37, the bottom portion of the outer contact region 41 may be positioned on the first main surface 3 side or may be positioned on the bottom portion side of the shallow contact region 37.

The bottom portion of the outer contact region 41 may be positioned at a depth substantially equal to the depth of the bottom portion of the upper end portion of the gate contact region 27. With respect to a depth position of the bottom portion of the upper end portion of the gate contact region 27, the bottom portion of the outer contact region 41 may be positioned on the first main surface 3 side or may be positioned on the bottom portion side of the gate contact region 27.

The bottom portion of the outer contact region 41 may be positioned at a depth substantially equal to the depth of the bottom portion of the upper end portion of the source contact region 28. With respect to a depth position of the bottom portion of the upper end portion of the source contact region 28, the bottom portion of the outer contact region 41 may be positioned on the first main surface 3 side or may be positioned on the bottom portion side of the source contact region 28.

A depth (thickness) of the outer contact region 41 may be larger than 0 μm and not more than 1 μm. The depth of the outer contact region 41 may have a value belonging to at least one range among larger than 0 μm and not more than 0.1 μm, not less than 0.1 μm and not more than 0.2 μm, not less than 0.2 μm and not more than 0.3 μm, not less than 0.3 μm and not more than 0.4 μm, not less than 0.4 μm and not more than 0.5 μm, not less than 0.5 μm and not more than 0.6 μm, not less than 0.6 μm and not more than 0.7 μm, not less than 0.7 μm and not more than 0.8 μm, not less than 0.8 μm and not more than 0.9 μm, and not less than 0.9 μm and not more than 1 μm.

The semiconductor device 1A includes a terminal region 42 of the p-type formed in the surface layer portion of the first main surface 3 in the outer peripheral region 9. The terminal region 42 may be referred to as a “terminal well region,” a “junction termination extension (JTE) region,” etc. The source potential is to be applied to the terminal region 42. The terminal region 42 has a p-type impurity concentration higher than the n-type impurity concentration of the second semiconductor region 7.

The p-type impurity concentration of the terminal region 42 may be lower than the p-type impurity concentration of the deep contact region 38. The p-type impurity concentration of the terminal region 42 may be lower than the p-type impurity concentration of the shallow contact region 37. The p-type impurity concentration of the terminal region 42 may be lower than the p-type impurity concentration of the gate contact region 27. The p-type impurity concentration of the terminal region 42 may be lower than the p-type impurity concentration of the source contact region 28.

The p-type impurity concentration of the terminal region 42 may be higher than the p-type impurity concentration of the outer well region 40, or may be lower than the p-type impurity concentration of the outer well region 40. The p-type impurity concentration of the terminal region 42 may be higher than the p-type impurity concentration of the deep well region 36, or may be lower than the p-type impurity concentration of the deep well region 36. The p-type impurity concentration of the terminal region 42 may be higher than the p-type impurity concentration of the shallow well region 35, or may be lower than the p-type impurity concentration of the shallow well region 35.

The p-type impurity concentration of the terminal region 42 may be higher than the p-type impurity concentration of the gate well region 25, or may be lower than the p-type impurity concentration of the gate well region 25. The p-type impurity concentration of the terminal region 42 may be higher than the p-type impurity concentration of the source well region 26, or may be lower than the p-type impurity concentration of the source well region 26. The p-type impurity concentration of the terminal region 42 may be higher than the p-type impurity concentration of the body region 10, or may be lower than the p-type impurity concentration of the body region 10.

The terminal region 42 is formed in a region between the peripheral edge of the first main surface 3 and the outermost separating structure 30 (the active region 8). Specifically, the terminal region 42 is formed in a region between the peripheral edge of the first main surface 3 and the outer well region 40. The terminal region 42 extends in a band shape along the outermost separating structure 30 (the outer well region 40) in plan view.

The terminal region 42 has a portion extending in the first direction X and a portion extending in the second direction Y. In this embodiment, the terminal region 42 is formed in a polygonal annular shape (in this embodiment, a quadrangle annular shape) having four sides parallel to the peripheral edge of the chip 2 in plan view, and surrounds the outermost separating structure 30 (the outer well region 40).

The terminal region 42 may have an edge portion that connects the portion extending in the first direction X and the portion extending in the second direction Y in an arc shape (preferably, a quadrangular arc shape). A plurality of the terminal regions 42 may be formed at an interval along the extension direction of the outermost separating structure 30. In this case, the plurality of terminal regions 42 may respectively extend in a band shape along the extension direction of the outermost separating structure 30.

The terminal region 42 has a width larger than the width of the deep well region 36. The width of the terminal region 42 is larger than the width of the outermost separating structure 30. The width of the terminal region 42 may be larger than the total width of the plurality of separating structures 30. The width of the terminal region 42 may be larger than the total width of the plurality of shallow well regions 35 and deep well regions 36. The width of the terminal region 42 may be larger than the width of the outer well region 40. The width of the terminal region 42 may be less than the width of the outer well region 40.

The width of the terminal region 42 may be larger than 0 μm and not more than 300 μm. The width of the terminal region 42 may have a value belonging to at least one range among larger than 0 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, and not less than 275 μm and not more than 300 μm.

A ratio (width ratio) of the width of the terminal region 42 to the width of the outer well region 40 may be not less than 0.5 and not more than 5. The width ratio may have a value belonging to any one range among not less than 0.5 and not more than 0.75, not less than 0.75 and not more than 1, not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, not less than 2.75 and not more than 3, not less than 4 and not more than 4.25, not less than 4.25 and not more than 4.5, not less than 4.5 and not more than 4.75, and not less than 4.75 and not more than 5.

The terminal region 42 is formed in the surface layer portion of the second semiconductor region 7, and is electrically connected to the second semiconductor region 7. The terminal region 42 is formed at an interval toward the first main surface 3 side from the bottom portion of the second semiconductor region 7, and faces the first semiconductor region 6 with a portion of the second semiconductor region 7 interposed therebetween. Preferably, the terminal region 42 is formed at an interval toward the first main surface 3 side from the depth position of the intermediate portion of the second semiconductor region 7.

The terminal region 42 is formed at an interval from the first main surface 3 in the thickness direction of the chip 2. That is, the terminal region 42 is formed at an interval toward the bottom portion side of the second semiconductor region 7 from the first main surface 3, and has a portion facing the first main surface 3 with a portion of the second semiconductor region 7 interposed therebetween.

A distance between the first main surface 3 and the terminal region 42 may be larger than 0 μm and not more than 3 μm. The distance may have a value belonging to at least one range among larger than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.5 μm, and not less than 2.5 μm and not more than 3 μm.

The terminal region 42 has an upper end portion positioned on the first main surface 3 side and a bottom portion positioned on the bottom portion side of the second semiconductor region 7. The upper end portion of the terminal region 42 extends in the horizontal direction along the first main surface 3, and forms a pn-junction portion with the second semiconductor region 7. The upper end portion of the terminal region 42 is positioned on the first main surface 3 side with respect to the depth position of the bottom portion of the outer well region 40. The upper end portion of the terminal region 42 is positioned on the bottom portion side of the outer well region 40 with respect to a depth position of the bottom portion of the outer contact region 41.

The upper end portion of the terminal region 42 is positioned on the first main surface 3 side with respect to the depth position of the bottom portion of the deep well region 36. The upper end portion of the terminal region 42 is positioned on the first main surface 3 side with respect to the depth position of the bottom portion of the shallow well region 35. The upper end portion of the terminal region 42 is positioned on the first main surface 3 side with respect to the depth position of the bottom portion of the gate well region 25. The upper end portion of the terminal region 42 is positioned on the first main surface 3 side with respect to the depth position of the bottom portion of the source well region 26.

The upper end portion of the terminal region 42 is positioned on the first main surface 3 side with respect to the depth position of the bottom wall of the separating structure 30. The upper end portion of the terminal region 42 is positioned on the first main surface 3 side with respect to the depth position of the bottom wall of the gate structure 15. The upper end portion of the terminal region 42 is positioned on the first main surface 3 side with respect to the depth position of the bottom wall of the source structure 20. The upper end portion of the terminal region 42 may be positioned on the bottom portion side of the second semiconductor region 7 with respect to the depth position of the bottom portion of the body region 10, or may be positioned on the first main surface 3 side with respect to the depth position of the bottom portion of the body region 10.

The bottom portion of the terminal region 42 extends in the horizontal direction along the first main surface 3, and forms a pn-junction portion with the second semiconductor region 7. The bottom portion of the terminal region 42 may be positioned on the bottom portion side of the second semiconductor region 7 with respect to the depth position of the bottom portion of the outer well region 40, or may be positioned on the first main surface 3 side with respect to the depth position of the bottom portion of the outer well region 40.

The bottom portion of the terminal region 42 is positioned on the first main surface 3 side with respect to the depth position of the bottom portion of the deep well region 36. The bottom portion of the terminal region 42 is positioned on the first main surface 3 side with respect to the depth position of the bottom portion of the shallow well region 35. The bottom portion of the terminal region 42 is positioned on the first main surface 3 side with respect to the depth position of the bottom portion of the gate well region 25. The bottom portion of the terminal region 42 is positioned on the first main surface 3 side with respect to the depth position of the bottom portion of the source well region 26.

The bottom portion of the terminal region 42 may be positioned on the first main surface 3 side with respect to the depth position of the bottom wall of the separating structure 30. The bottom portion of the terminal region 42 may be positioned on the bottom portion side of the second semiconductor region 7 with respect to the depth position of the bottom wall of the separating structure 30.

The bottom portion of the terminal region 42 may be positioned on the first main surface 3 side with respect to the depth position of the bottom wall of the gate structure 15, or may be positioned on the bottom portion side of the second semiconductor region 7 with respect to the depth position of the bottom wall of the gate structure 15. The bottom portion of the terminal region 42 may be positioned on the first main surface 3 side with respect to the depth position of the bottom wall of the source structure 20, or may be positioned on the bottom portion side of the second semiconductor region 7 with respect to the depth position of the bottom wall of the source structure 20.

The terminal region 42 may have a depth (thickness) larger than the distance between the first main surface 3 and the terminal region 42. The depth of the terminal region 42 is a distance between the upper end portion of the terminal region 42 and the bottom portion of the terminal region 42. The depth of the terminal region 42 may be smaller than the distance between the first main surface 3 and the terminal region 42.

The depth of the terminal region 42 may be smaller than a distance between the bottom portion of the second semiconductor region 7 and the terminal region 42. The depth of the terminal region 42 may be larger than the distance between the bottom portion of the second semiconductor region 7 and the terminal region 42. Preferably, the depth of the terminal region 42 is less than the depth of the outer well region 40. The depth of the terminal region 42 may be larger than the depth of the outer well region 40.

The depth (thickness) of the terminal region 42 may be larger than 0 μm and not more than 4 μm. The depth of the terminal region 42 may have a value belonging to at least one range among larger than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.5 μm, not less than 2.5 μm and not more than 3 μm, not less than 3 μm and not more than 3.5 μm, and not less than 3.5 μm and not more than 4 μm.

The terminal region 42 has an inner edge portion on the outermost separating structure 30 (the outer well region 40) side and an outer edge portion on the peripheral edge side of the first main surface 3. The electric field (the depletion layer) formed in vicinities of the outermost separating structure 30 is adjusted by adjusting an arrangement location of the inner edge portion of the terminal region 42.

The inner edge portion of the terminal region 42 is connected to at least the outer edge portion of the outer well region 40. The inner edge portion of the terminal region 42 may be positioned further to the outermost separating structure 30 side than the intermediate portion of the outer well region 40. The inner edge portion of the terminal region 42 may be positioned further to the outer edge portion side of the outer well region 40 than the intermediate portion of the outer well region 40.

The inner edge portion of the terminal region 42 may be positioned in a region between the outer edge portion of the outer well region 40 and the outer edge portion of the outer contact region 41. The inner edge portion of the terminal region 42 may be positioned on the inner edge portion side of the outer well region 40 with respect to the outer edge portion of the outer contact region 41.

The inner edge portion of the terminal region 42 may be connected to the outermost separating structure 30. The inner edge portion of the terminal region 42 may be formed at an interval toward the outer edge portion side of the outer well region 40 from the outermost separating structure 30 (the inner edge portion of the outer well region 40). In this case, the inner edge portion of the terminal region 42 may have a portion connected to the deep contact region 38. The inner edge portion of the terminal region 42 may have a portion connected to the deep well region 36.

In this embodiment, the inner edge portion of the terminal region 42 is connected to the outer edge portion of the outer well region 40 in a region on the bottom portion side of the outer well region 40 with respect to the depth position of the intermediate portion of the outer well region 40. Thereby, the terminal region 42 is electrically connected to the body region 10 and the outer contact region 41 via the outer well region 40.

The inner edge portion of the terminal region 42 may be formed at an interval toward the bottom portion side of the outer well region 40 from the bottom portion of the outer contact region 41, and may face the outer contact region 41 with a portion of the outer well region 40 interposed therebetween. The inner edge portion of the terminal region 42 may be connected to the outer contact region 41.

A connection portion (an overlapping portion) between the outer edge portion of the outer well region 40 and the inner edge portion of the terminal region 42 includes a p-type impurity of the outer well region 40 and a p-type impurity of the terminal region 42. Therefore, the connection portion (the overlapping portion) has a p-type impurity concentration higher than both the p-type impurity concentration of the outer well region 40 and the p-type impurity concentration of the terminal region 42.

The terminal region 42 spreads a depletion layer in the second semiconductor region 7 when a reverse bias voltage is applied. The depletion layer with the terminal region 42 as a starting point spreads in the horizontal direction and the thickness direction, and becomes integral with the depletion layer with the outer well region 40 (the deep well region 36) as a starting point. The terminal region 42 expands the depletion layer with the outer well region 40 (the deep well region 36) as a starting point toward the peripheral edge of the first main surface 3, and relaxes the electric field in the peripheral edge portion (the outer peripheral region 9) of the first main surface 3.

The semiconductor device 1A includes at least one field region 43 of the p-type formed in the surface layer portion of the first main surface 3 in the outer peripheral region 9 (the peripheral edge portion of the first main surface 3). The field region 43 may be referred to as a “guard region,” a “field limit region,” etc. The field region 43 is formed in an electrically floating state. The source potential may be applied to the field region 43.

The number of the field regions 43 is arbitrary. The number of the field regions 43 may be not less than 1 and not more than 15. The number of the field regions 43 may be 1, 2, 3, 4, 5, 6, 7, 8, 9, 10, 11, 12, 13, 14, or 15. The number of the field regions 43 is typically not less than 1 and not more than 10. In this embodiment, the semiconductor device 1A includes six field regions 43 as an example.

The field region 43 has a p-type impurity concentration higher than the n-type impurity concentration of the second semiconductor region 7. The p-type impurity concentration of the field region 43 may be substantially equal to the p-type impurity concentration of the terminal region 42. The p-type impurity concentration of the field region 43 may be higher than the p-type impurity concentration of the terminal region 42, or may be lower than the p-type impurity concentration of the terminal region 42.

The p-type impurity concentration of the field region 43 may be lower than the p-type impurity concentration of the deep contact region 38. The p-type impurity concentration of the field region 43 may be lower than the p-type impurity concentration of the shallow contact region 37. The p-type impurity concentration of the field region 43 may be lower than the p-type impurity concentration of the gate contact region 27. The p-type impurity concentration of the field region 43 may be lower than the p-type impurity concentration of the source contact region 28.

The p-type impurity concentration of the field region 43 may be higher than the p-type impurity concentration of the outer well region 40, or may be lower than the p-type impurity concentration of the outer well region 40. The p-type impurity concentration of the field region 43 may be higher than the p-type impurity concentration of the deep well region 36, or may be lower than the p-type impurity concentration of the deep well region 36. The p-type impurity concentration of the field region 43 may be higher than the p-type impurity concentration of the shallow well region 35, or may be lower than the p-type impurity concentration of the shallow well region 35.

The p-type impurity concentration of the field region 43 may be higher than the p-type impurity concentration of the gate well region 25, or may be lower than the p-type impurity concentration of the gate well region 25. The p-type impurity concentration of the field region 43 may be higher than the p-type impurity concentration of the source well region 26, or may be lower than the p-type impurity concentration of the source well region 26. The p-type impurity concentration of the field region 43 may be higher than the p-type impurity concentration of the body region 10, or may be lower than the p-type impurity concentration of the body region 10.

In this embodiment, the p-type impurity concentrations of a plurality of the field regions 43 are substantially equal to each other. The p-type impurity concentrations of the plurality of field regions 43 are arbitrary and can take on various values in accordance with the electric field to be relaxed. The p-type impurity concentrations of the plurality of field regions 43 may be different from each other.

The p-type impurity concentrations of the plurality of field regions 43 may sequentially increase toward the peripheral edge side of the first main surface 3. The p-type impurity concentrations of the plurality of field regions 43 may increase toward the peripheral edge side of the first main surface 3 in units of two or more groups each including two or more field regions 43.

The p-type impurity concentrations of the plurality of field regions 43 may sequentially decrease toward the peripheral edge side of the first main surface 3. The p-type impurity concentrations of the plurality of field regions 43 may decrease toward the peripheral edge side of the first main surface 3 in units of two or more groups each including two or more field regions 43.

The plurality of field regions 43 are formed at an interval in a region between the peripheral edge of the first main surface 3 and the outermost separating structure 30 (the active region 8). The plurality of field regions 43 are formed at an interval in a region between the peripheral edge of the first main surface 3 and the outer well region 40. The plurality of field regions 43 are formed at an interval in a region between the peripheral edge of the first main surface 3 and the terminal region 42.

The plurality of field regions 43 are formed in the surface layer portion of the second semiconductor region 7, and are electrically connected to the second semiconductor region 7. The plurality of field regions 43 extend in a band shape along the outermost separating structure 30 (the terminal region 42) in plan view.

Each of the plurality of field regions 43 has a portion extending in the first direction X and a portion extending in the second direction Y. In this embodiment, each of the plurality of field regions 43 is formed in a polygonal annular shape (in this embodiment, a quadrangle annular shape) having four sides parallel to the peripheral edge of the chip 2 in plan view, and surrounds the outermost separating structure 30 (the active region 8).

Each of the plurality of field regions 43 may have an edge portion that connects a portion extending in the first direction X and a portion extending in the second direction Y in an arc shape (preferably, a quarter arc shape). The plurality of field regions 43 may be formed at an interval along the extension direction of the outermost separating structure 30. In this case, the plurality of field regions 43 may respectively extend in a band shape along the extension direction of the outermost separating structure 30.

The plurality of field regions 43 may have a width less than the width of the outer well region 40. The width of each of the plurality of field regions 43 may be smaller than the width of the terminal region 42. The width of each of the plurality of field regions 43 may be smaller than the width of the deep well region 36, or may be larger than the width of the deep well region 36.

The width of each of the plurality of field regions 43 may be smaller than the width of the shallow well region 35, or may be larger than the width of the shallow well region 35. The width of each of the plurality of field regions 43 may be larger than the width of the separating structure 30, or may be smaller than the width of the separating structure 30.

In this embodiment, the widths of the plurality of field regions 43 are substantially equal to each other. The widths of the plurality of field regions 43 are arbitrary and can take on various values in accordance with the electric field to be relaxed. The widths of the plurality of field regions 43 may be different from each other.

The widths of the plurality of field regions 43 may sequentially increase toward the peripheral edge side of the first main surface 3. The widths of the plurality of field regions 43 may increase toward the peripheral edge side of the first main surface 3 in units of two or more groups each including two or more field regions 43.

The widths of the plurality of field regions 43 may sequentially decrease toward the peripheral edge side of the first main surface 3. The widths of the plurality of field regions 43 may decrease toward the peripheral edge side of the first main surface 3 in units of two or more groups each including two or more field regions 43.

The width of the field region 43 may be larger than 0 μm and not more than 5 μm. The width of the field region 43 may have a value belonging to at least one range among larger than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The interval between the plurality of field regions 43 may be not more than the width of the field region 43. Preferably, the interval between the plurality of field regions 43 is less than the width of the field region 43. The interval between the plurality of field regions 43 may be larger than the width of the field region 43.

In this embodiment, the intervals between the plurality of field regions 43 are substantially equal to each other. The intervals between the plurality of field regions 43 are arbitrary and can take on various values in accordance with the electric field to be relaxed. The intervals between the plurality of field regions 43 may be different from each other.

The intervals between the plurality of field regions 43 may sequentially increase toward the peripheral edge side of the first main surface 3. The intervals between the plurality of field regions 43 may increase toward the peripheral edge side of the first main surface 3 in units of two or more groups each including two or more field regions 43.

The intervals between the plurality of field regions 43 may sequentially decrease toward the peripheral edge side of the first main surface 3. The intervals between the plurality of field regions 43 may decrease toward the peripheral edge side of the first main surface 3 in units of two or more groups each including two or more field regions 43.

The interval between the field regions 43 may be larger than 0 μm and not more than 5 μm. The interval may have a value belonging to at least one range among larger than 0 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

A ratio (interval ratio) of the interval between the field regions 43 to the width of the field region 43 may be not less than 0.1 and not more than 5. The interval ratio may have a value belonging to at least one range among not less than 0.1 and not more than 0.5, not less than 0.5 and not more than 1, not less than 1 and not more than 1.5, not less than 1.5 and not more than 2, not less than 2 and not more than 2.5, not less than 2.5 and not more than 3, not less than 3 and not more than 3.5, not less than 3.5 and not more than 4, not less than 4 and not more than 4.5, and not less than 4.5 and not more than 5.

The plurality of field regions 43 are formed at an interval toward the first main surface 3 side from the bottom portion of the second semiconductor region 7, and face the first semiconductor region 6 with a portion of the second semiconductor region 7 interposed therebetween. Preferably, the plurality of field regions 43 are formed at an interval toward the first main surface 3 side from the depth position of the intermediate portion of the second semiconductor region 7.

The plurality of field regions 43 are formed at an interval from the first main surface 3 in the thickness direction of the chip 2. That is, the plurality of field regions 43 are formed at an interval toward the bottom portion side of the second semiconductor region 7 from the first main surface 3, and each have a portion facing the first main surface 3 with a portion of the second semiconductor region 7 interposed therebetween. Each of the plurality of field regions 43 is formed in a depth range between the upper end portion and the bottom portion of the terminal region 42, and faces the terminal region 42 in the horizontal direction.

Preferably, a distance between the first main surface 3 and the field region 43 is substantially equal to the distance between the first main surface 3 and the terminal region 42. The distance between the first main surface 3 and the field region 43 may be larger than the distance between the first main surface 3 and the terminal region 42, or may be smaller than the distance between the first main surface 3 and the terminal region 42.

The distance between the first main surface 3 and the field region 43 may be larger than 0 μm and not more than 3 μm. The distance may have a value belonging to at least one range among larger than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.5 μm, and not less than 2.5 μm and not more than 3 μm.

Each of the plurality of field regions 43 has an upper end portion positioned on the first main surface 3 side and a bottom portion positioned on the bottom portion side of the second semiconductor region 7. The upper end portion of the field region 43 extends in the horizontal direction along the first main surface 3, and forms a pn-junction portion with the second semiconductor region 7.

The upper end portion of each of the plurality of field regions 43 is positioned at a depth substantially equal to the depth of the upper end portion of the terminal region 42. The upper end portion of each of the plurality of field regions 43 may be positioned on the first main surface 3 side with respect to a depth position of the upper end portion of the terminal region 42, or may be positioned on the bottom portion side of the second semiconductor region 7 with respect to the depth position of the upper end portion of the terminal region 42.

The upper end portion of each of the plurality of field regions 43 is positioned on the first main surface 3 side with respect to the depth position of the bottom portion of the outer well region 40. The upper end portion of each of the plurality of field regions 43 is positioned on the bottom portion side of the outer well region 40 with respect to the depth position of the bottom portion of the outer contact region 41.

The upper end portion of each of the plurality of field regions 43 is positioned on the first main surface 3 side with respect to the depth position of the bottom portion of the deep well region 36. The upper end portion of each of the plurality of field regions 43 is positioned on the first main surface 3 side with respect to the depth position of the bottom portion of the shallow well region 35. The upper end portion of each of the plurality of field regions 43 is positioned on the first main surface 3 side with respect to the depth position of the bottom portion of the gate well region 25. The upper end portion of each of the plurality of field regions 43 is positioned on the first main surface 3 side with respect to the depth position of the bottom portion of the source well region 26.

The upper end portion of each of the plurality of field regions 43 is positioned on the first main surface 3 side with respect to the depth position of the bottom wall of the separating structure 30. The upper end portion of each of the plurality of field regions 43 is positioned on the first main surface 3 side with respect to the depth position of the bottom wall of the gate structure 15. The upper end portion of each of the plurality of field regions 43 is positioned on the first main surface 3 side with respect to the depth position of the bottom wall of the source structure 20.

In this embodiment, the upper end portion of each of the plurality of field regions 43 is positioned on the bottom portion side of the second semiconductor region 7 with respect to the depth position of the bottom portion of the body region 10. The upper end portion of each of the plurality of field regions 43 may be positioned on the first main surface 3 side with respect to the depth position of the bottom portion of the body region 10.

The bottom portion of each of the plurality of field regions 43 extends in the horizontal direction along the first main surface 3, and forms a pn-junction portion with the second semiconductor region 7. The bottom portion of each of the plurality of field regions 43 is positioned at a depth substantially equal to the depth of the bottom portion of the terminal region 42. The bottom portion of each of the plurality of field regions 43 may be positioned on the first main surface 3 side with respect to a depth position of the bottom portion of the terminal region 42, or may be positioned on the bottom portion side of the second semiconductor region 7 with respect to the depth position of the bottom portion of the terminal region 42.

The bottom portion of each of the plurality of field regions 43 may be positioned on the bottom portion side of the second semiconductor region 7 with respect to the depth position of the bottom portion of the outer well region 40. The bottom portion of each of the plurality of field regions 43 may be positioned on the first main surface 3 side with respect to the depth position of the bottom portion of the outer well region 40.

The bottom portion of each of the plurality of field regions 43 is positioned on the first main surface 3 side with respect to the depth position of the bottom portion of the deep well region 36. The bottom portion of each of the plurality of field regions 43 is positioned on the first main surface 3 side with respect to the depth position of the bottom portion of the shallow well region 35. The bottom portion of each of the plurality of field regions 43 is positioned on the first main surface 3 side with respect to the depth position of the bottom portion of the gate well region 25. The bottom portion of each of the plurality of field regions 43 is positioned on the first main surface 3 side with respect to the depth position of the bottom portion of the source well region 26.

The bottom portion of each of the plurality of field regions 43 may be positioned on the first main surface 3 side with respect to the depth position of the bottom wall of the separating structure 30. The bottom portion of each of the plurality of field regions 43 may be positioned on the bottom portion side of the second semiconductor region 7 with respect to the depth position of the bottom wall of the separating structure 30.

The bottom portion of each of the plurality of field regions 43 may be positioned on the first main surface 3 side with respect to the depth position of the bottom wall of the gate structure 15. The bottom portion of each of the plurality of field regions 43 may be positioned on the bottom portion side of the second semiconductor region 7 with respect to the depth position of the bottom wall of the gate structure 15. The bottom portion of each of the plurality of field regions 43 may be positioned on the first main surface 3 side with respect to the depth position of the bottom wall of the source structure 20. The bottom portion of each of the plurality of field regions 43 may be positioned on the bottom portion side of the second semiconductor region 7 with respect to the depth position of the bottom wall of the source structure 20.

The field region 43 may have a depth (thickness) that is substantially equal to the depth (thickness) of the terminal region 42. The depth of the field region 43 is a distance between the upper end portion and the bottom portion of the field region 43. The depth of the field region 43 may be larger than the depth of the terminal region 42, or may be smaller than the depth of the terminal region 42.

The depth of the field region 43 may be larger than the distance between the first main surface 3 and the field region 43. The depth of the field region 43 may be smaller than the distance between the first main surface 3 and the field region 43. The depth of the field region 43 may be smaller than a distance between the bottom portion of the second semiconductor region 7 and the field region 43. The depth of the field region 43 may be larger than the distance between the bottom portion of the second semiconductor region 7 and the field region 43.

In this embodiment, the depths of the plurality of field regions 43 are substantially equal to each other. The depths of the plurality of field regions 43 are arbitrary and can take on various values in accordance with the electric field to be relaxed. The depths of the plurality of field regions 43 may be different from each other.

The depths of the plurality of field regions 43 may sequentially increase toward the peripheral edge side of the first main surface 3. The depths of the plurality of field regions 43 may increase toward the peripheral edge side of the first main surface 3 in units of two or more groups each including two or more field regions 43.

The depths of the plurality of field regions 43 may sequentially decrease toward the peripheral edge side of the first main surface 3. The depths of the plurality of field regions 43 may decrease toward the peripheral edge side of the first main surface 3 in units of two or more groups each including two or more field regions 43.

The depth of the field region 43 may be larger than 0 μm and not more than 4 μm. The depth of the field region 43 may have a value belonging to at least one range among larger than 0 μm and not more than 0.25 μm, not less than 0.25 μm and not more than 0.5 μm, not less than 0.5 μm and not more than 0.75 μm, not less than 0.75 μm and not more than lum, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.5 μm, not less than 2.5 μm and not more than 3 μm, not less than 3 μm and not more than 3.5 μm, and not less than 3.5 μm and not more than 4 μm.

The plurality of field regions 43 spread a depletion layer in the second semiconductor region 7 when a reverse bias voltage is applied. The depletion layer with the plurality of field regions 43 as starting points spreads in the horizontal direction and the thickness direction, and becomes integral with the depletion layer with the terminal region 42 (the deep well region 36) as a starting point. The plurality of field regions 43 expand the depletion layer with the terminal region 42 (the deep well region 36) as a starting point toward the peripheral edge of the first main surface 3, and relaxes the electric field in the peripheral edge portion (the outer peripheral region 9) of the first main surface 3.

The semiconductor device 1A includes a main surface insulating film 45 that selectively covers the first main surface 3. The main surface insulating film 45 may include at least one among a silicon oxide film, a silicon nitride film, and a silicon oxynitride film. Preferably, the main surface insulating film 45 includes the same type of insulating material as at least one of the insulating materials of the first insulating film 17, the second insulating film 22, and the third insulating film 32. In this embodiment, the main surface insulating film 45 has a single layer structure constituted of a silicon oxide film. Particularly preferably, the main surface insulating film 45 includes the silicon oxide film constituted of the oxide of the chip 2.

The main surface insulating film 45 is selectively connected to the first insulating films 17 of the plurality of gate structures 15, the second insulating films 22 of the plurality of source structures 20, and the third insulating films 32 of the plurality of separating structures 30 in the active region 8, and exposes the first embedded electrodes 18 of the plurality of gate structures 15, the second embedded electrodes 23 of the plurality of source structures 20, and the third embedded electrodes 33 of the plurality of separating structures 30.

In the outer peripheral region 9, the main surface insulating film 45 covers the second semiconductor region 7, the outer well region 40, and the outer contact region 41. In this embodiment, the main surface insulating film 45 is continuous to the first to fourth side surfaces 5A to 5D at the peripheral edge portion of the first main surface 3. The main surface insulating film 45 may be formed at an interval inward from the peripheral edge of the first main surface 3, and may expose the peripheral edge portion (the second semiconductor region 7) of the first main surface 3.

The semiconductor device 1A includes an outer wiring 46 arranged on the main surface insulating film 45 in the outer peripheral region 9. The outer wiring 46 may be referred to as “wiring,” “main surface wiring,” “outer peripheral wiring,” “side wiring,” etc. The outer wiring 46 may include either or both of a p-type conductive polysilicon and an n-type conductive polysilicon. Preferably, the outer wiring 46 has the same type of conductive material (conductivity type) as at least one of the first embedded electrode 18, the second embedded electrode 23, and the third embedded electrode 33.

The outer wiring 46 is arranged in the outer peripheral region 9 at an interval toward the active region 8 side from the peripheral edge of the first main surface 3. The outer wiring 46 is arranged on the outer well region 40, and faces the outer well region 40 with the main surface insulating film 45 interposed therebetween.

The outer wiring 46 extends in a band shape along the peripheral edge of the first main surface 3 (the peripheral edge of the active region 8) along the extension direction of the outer well region 40 in plan view. The outer wiring 46 has a portion extending in the first direction X and a portion extending in the second direction Y.

In this embodiment, the outer wiring 46 is formed in a polygonal annular shape (in this embodiment, a quadrangle annular shape) having four sides parallel to the peripheral edge of the chip 2 in plan view, and surrounds the inner portion of the first main surface 3 (the active region 8). The outer wiring 46 may have an edge portion that connects the portion extending in the first direction X and the portion extending in the second direction Y in an arc shape (preferably, a quadrangular arc shape). The outer wiring 46 may be a shape with ends or an endless shape . . .

The outer wiring 46 has an inner edge portion on the inner portion side of the first main surface 3 (the active region 8 side) and an outer edge portion on the peripheral edge portion side of the first main surface 3. The inner edge portion of the outer wiring 46 is drawn out from the outer peripheral region 9 to the active region 8. The inner edge portion of the outer wiring 46 covers one or a plurality of the separating structures 30, and is connected to one or a plurality of the separating structures 30.

In this embodiment, the inner edge portion of the outer wiring 46 covers the outermost separating structure 30, and is connected to the third embedded electrode 33 of the outermost separating structure 30. In this embodiment, the outer wiring 46 is formed at an interval toward the outer peripheral region 9 side from the plurality of separating structures 30 for the shallow well regions 35. Therefore, the outer wiring 46 is not electrically connected to the plurality of separating structures 30 for the shallow well regions 35.

The outer wiring 46 may be connected to at least one or all of the plurality of separating structures 30 for the shallow well regions 35. The outer wiring 46 is integrally formed with the third embedded electrode 33 of the separating structure 30. That is, the outer wiring 46 is formed as a lead-out portion of the third embedded electrode 33, and is routed on the main surface insulating film 45. The outer wiring 46 faces the deep well region 36 with the outermost separating structure 30 interposed therebetween.

The outer edge portion of the outer wiring 46 is formed at an interval inward (the active region 8 side) from the innermost field region 43 among the plurality of field regions 43. That is, the outer edge portion of the outer wiring 46 does not face the plurality of field regions 43 with the main surface insulating film 45 interposed therebetween. According to this arrangement, a dispersion path of an electric field in the region above the plurality of field regions 43 is suppressed from being shielded by the outer wiring 46, and an electric field (a line of electric force) is dispersed appropriately by the plurality of field regions 43.

The outer edge portion of the outer wiring 46 is formed at an interval inward from the outer edge portion of the terminal region 42. In this embodiment, the outer edge portion of the outer wiring 46 is arranged at an interval inward from the outer edge portion of the outer contact region 41, and has a portion that faces the outer contact region 41 with the main surface insulating film 45 interposed therebetween. The outer edge portion of the outer wiring 46 may have a portion that faces the terminal region 42 in a lamination direction.

The semiconductor device 1A includes an interlayer film 47 with an insulating property that selectively covers the first main surface 3 with the main surface insulating film 45 interposed therebetween. The interlayer film 47 may be referred to as an “insulating film,” an “interlayer insulating film,” an “intermediate insulating film,” etc. The interlayer film 47 may include at least one among a silicon oxide film, a silicon nitride film, and a silicon oxynitride film. Preferably, the interlayer film 47 includes a silicon oxide film.

On the active region 8 side, the interlayer film 47 covers the plurality of gate structures 15 (the first embedded electrodes 18) and the plurality of separating structures 30 (the third embedded electrodes 33). The interlayer film 47 may cover the both end portions of the source structure 20 on the active region 8 side. On the outer peripheral region 9 side, the interlayer film 47 covers the second semiconductor region 7, the outer well region 40, and the outer contact region 41 with the main surface insulating film 45 interposed therebetween.

In this embodiment, the interlayer film 47 is continuous to the first to fourth side surfaces 5A to 5D at the peripheral edge portion of the first main surface 3. The interlayer film 47 may be formed at an interval inward from the peripheral edge of the first main surface 3, and may expose the peripheral edge portion (the second semiconductor region 7) of the first main surface 3.

The interlayer film 47 may have a thickness of not less than 0.5 μm and not more than 3 μm. The thickness of the interlayer film 47 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm.

The semiconductor device 1A includes a plurality of gate openings 48 formed in the interlayer film 47 in the active region 8 (refer to FIG. 3). The plurality of gate openings 48 are formed in a multiple-to-one correspondence with the one corresponding gate structure 15. In this embodiment, the plurality of gate openings 48 penetrate through the interlayer film 47, and expose one end portion or the other end portion of each of the plurality of gate structures 15 (the first embedded electrodes 18).

Each of the plurality of gate openings 48 may have an opening end that is curved in an arc shape. The plurality of gate openings 48 may be formed in a quadrangle shape, a rectangular shape (band shape) extending in the first direction X, a rectangular shape (band shape) extending in the second direction Y, a circular shape, etc., in plan view. Each of the plurality of gate openings 48 may have an opening end that is curved in an arc shape.

The semiconductor device 1A includes a plurality of source openings 49 formed in the interlayer film 47 in the active region 8. The plurality of source openings 49 are formed in a portion of the interlayer film 47 that covers the active region 8. The plurality of source openings 49 are respectively formed in a one-to-one correspondence with the plurality of source structures 20 in regions between the plurality of gate structures 15. Each of the plurality of source openings 49 extends in a band shape in the second direction Y along the corresponding source structure 20.

Each of the plurality of source openings 49 penetrates through the main surface insulating film 45 and the interlayer film 47, and exposes the one corresponding source structure 20, the source region 11, the plurality of gate contact regions 27, and the plurality of source contact regions 28. Each of the plurality of source openings 49 may have an opening end that is curved in an arc shape.

The plurality of source openings 49 may be formed in a multiple-to-one correspondence with the one corresponding source structure 20. In this case, the plurality of source openings 49 may be formed at an interval along the one corresponding source structure 20. Also, in this case, the plurality of source openings 49 may be formed in a quadrangular shape, a rectangular shape (band shape), a circular shape, etc., in plan view.

The semiconductor device 1A includes at least one (in this embodiment, one) outer opening 50 formed in the interlayer film 47 in the outer peripheral region 9. The outer opening 50 penetrates through the main surface insulating film 45 and the interlayer film 47, and exposes the outer edge portion of the outer wiring 46 and the outer contact region 41. The outer opening 50 extends in a band shape along the outer edge portion of the outer wiring 46 and the outer contact region 41 in plan view.

In this embodiment, the outer opening 50 is formed in a polygonal annular shape (specifically, a quadrangle annular shape) surrounding the inner portion (the active region 8) of the first main surface 3 along the outer contact region 41 and the outer wiring 46 in plan view. The outer opening 50 may have an opening end that is curved in an arc shape.

The semiconductor device 1A may have a plurality of the outer openings 50. In this case, the plurality of outer openings 50 may be formed at an interval along the outer contact region 41 and the outer wiring 46 so as to surround the inner portion (the active region 8) of the first main surface 3. In this case, the plurality of outer openings 50 may be formed in a quadrangle shape (square shape), a rectangular shape, a hexagonal shape, a circular shape, etc., in plan view.

The semiconductor device 1A includes a source electrode 51 arranged on the first main surface 3. The source electrode 51 is a terminal electrode to which the source potential is to be applied from an exterior. The source electrode 51 may be referred to as a “source pad electrode,” a “first pad electrode,” a “first main surface electrode,” a “first terminal electrode,” etc.

The source electrode 51 is arranged on a portion of the interlayer film 47 that covers the active region 8. The source electrode 51 enters the plurality of source openings 49 from above the interlayer film 47, and is electrically connected to the source region 11, the plurality of gate contact regions 27, and the plurality of source contact regions 28 in the plurality of source openings 49.

In this embodiment, the source electrode 51 has a first pad portion 51a, a second pad portion 51b, and a third pad portion 51c. The first pad portion 51a has a comparatively large plane area, and forms a main body of the source electrode 51. In this embodiment, the first pad portion 51a is formed in a polygonal shape (in this embodiment, a quadrangle shape) having four sides parallel to the peripheral edge of the chip 2 in plan view, and is shifted to the fourth side surface 5D side with respect to the central portion of the first main surface 3.

The second pad portion 51b has a plane area less than the plane area of the first pad portion 51a, and is drawn out in a band shape (a quadrangular shape) from one end of the first pad portion 51a in the second direction Y (the end portion on the first side surface 5A side) toward the third side surface 5C. The third pad portion 51c has a plane area less than the plane area of the first pad portion 51a, is drawn out in a band shape (a quadrangular shape) from the other end portion of the first pad portion 51a in the second direction Y (the end portion on the second side surface 5B side) toward the third side surface 5C, and faces the second pad portion 51b in the second direction Y.

The plane area of the third pad portion 51c may be substantially equal to the plane area of the second pad portion 51b. The plane area of the third pad portion 51c may be larger than the plane area of the second pad portion 51b, or may be less than the plane area of the second pad portion 51b. Either or both of the second pad portion 51b and the third pad portion 51c may be used as a terminal portion for current monitoring.

The source electrode 51 does not necessarily have both the second pad portion 51b and the third pad portion 51c at the same time. The source electrode 51 may have just either of the second pad portion 51b and the third pad portion 51c. The source electrode 51 may be constituted of just the first pad portion 51a, and does not have to have both the second pad portion 51b and the third pad portion 51c.

In this embodiment, the source electrode 51 has a laminated structure including a lower electrode film 52 and a main electrode film 53 laminated in that order from the chip 2 side. In this embodiment, the lower electrode film 52 has a laminated structure including a first electrode film 54 and a second electrode film 55. In this embodiment, the first electrode film 54 includes a Ti film, and the second electrode film 55 includes a TiN film. The lower electrode film 52 does not necessarily have a laminated structure, and may have a single layer structure constituted of one of either of the first electrode film 54 (the Ti film) and the second electrode film 55 (the TiN film).

The first electrode film 54 has a thickness less than the thickness of the interlayer film 47. The thickness of the first electrode film 54 may be not less than 10 nm and not more than 100 nm. The thickness of the first electrode film 54 may have a value belonging to at least one range among not less than 10 nm and not more than 25 nm, not less than 25 nm and not more than 50 nm, not less than 50 nm and not more than 75 nm, and not less than 75 nm and not more than 100 nm.

The second electrode film 55 has a thickness less than the thickness of the interlayer film 47. Preferably, the thickness of the second electrode film 55 is larger than the thickness of the first electrode film 54. The thickness of the second electrode film 55 may be not less than 50 nm and not more than 200 nm. The thickness of the second electrode film 55 may have a value belonging to at least one range among not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The first electrode film 54 collectively covers, in a film shape, a region of the interlayer film 47 in which the plurality of source openings 49 are formed, and enters the plurality of source openings 49 from above the interlayer film 47. The first electrode film 54 has a portion that covers an insulating main surface of the interlayer film 47 in a film shape, a portion that covers wall surfaces of the plurality of source openings 49 in a film shape, and a portion that covers the first main surface 3 in a film shape in the plurality of source openings 49. The first electrode film 54 is mechanically and electrically connected to the source region 11 and the plurality of source contact regions 28 in the source opening 49.

The second electrode film 55 directly covers the first electrode film 54. The second electrode film 55 collectively covers, in a film shape, a region of the interlayer film 47 in which the plurality of source openings 49 are formed with the first electrode film 54 interposed therebetween, and enters the plurality of source openings 49 from above the interlayer film 47.

The second electrode film 55 has a portion that covers the insulating main surface of the interlayer film 47 in a film shape with the first electrode film 54 interposed therebetween, a portion that covers the wall surfaces of the plurality of source openings 49 in a film shape with the first electrode film 54 interposed therebetween, and a portion that covers the first main surface 3 in a film shape with the first electrode film 54 interposed therebetween in the plurality of source openings 49. The second electrode film 55 is electrically connected to the source region 11 and the plurality of source contact regions 28 via the first electrode film 54 in the source opening 49.

The main electrode film 53 includes a conductive material different from the conductive material of the lower electrode film 52 (the first electrode film 54 and the second electrode film 55). The main electrode film 53 may include at least one among an Al film, an Al alloy film, a Cu film, and a Cu alloy film. The Al alloy film may include at least one among an AlSi alloy film, an AlCu alloy film, and an AlSiCu alloy film. The main electrode film 53 has a thickness larger than the thickness (the total thickness) of the lower electrode film 52. Preferably, the thickness of the main electrode film 53 is larger than the thickness of the interlayer film 47.

The thickness of the main electrode film 53 may be not less than 0.5 μm and not more than 5 μm. The thickness of the main electrode film 53 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The main electrode film 53 directly covers the lower electrode film 52 (the second electrode film 55). The main electrode film 53 collectively covers, in a film shape, a region of the interlayer film 47 in which the plurality of source openings 49 are formed, and backfills the plurality of source openings 49.

The main electrode film 53 has a portion that covers the insulating main surface of the interlayer film 47 with the lower electrode film 52 interposed therebetween, a portion that covers the wall surfaces of the plurality of source openings 49 with the lower electrode film 52 interposed therebetween, and a portion that covers the first main surface 3 with the lower electrode film 52 interposed therebetween. The main electrode film 53 is electrically connected to the source region 11 and the plurality of source contact regions 28 via the lower electrode film 52 in the plurality of source openings 49.

The semiconductor device 1A includes a source wiring 56 arranged around the source electrode 51 on the interlayer film 47. The same potential (the source potential) as the potential (the source potential) applied to the source electrode 51 is to be applied to the source wiring 56.

The source wiring 56 may be referred to as a “terminal electrode (wiring),” a “wiring,” a “first wiring,” a “finger electrode,” a “source finger,” etc.

The source wiring 56 has a wiring width less than the electrode width of the source electrode 51, and is selectively routed on the interlayer film 47. In this embodiment, the source wiring 56 is drawn out from the source electrode 51 (the first pad portion 51a) toward the fourth side surface 5D side.

The source wiring 56 is drawn out from the active region 8 to the outer peripheral region 9, and has a portion that faces the outer wiring 46 with the interlayer film 47 interposed therebetween. In this embodiment, the source wiring 56 covers the outer wiring 46 across an entire periphery. The source wiring 56 enters the outer opening 50 from above the interlayer film 47, and is electrically connected to the outer contact region 41 and the outer wiring 46 in the outer opening 50.

That is, the source wiring 56 is electrically connected to one or a plurality (in this embodiment, one) of the separating structures 30 (the third embedded electrodes 33) via the outer wiring 46, and is electrically connected to the outer well region 40 and the terminal region 42 via the outer contact region 41. The source potential applied to the source electrode 51 is to be applied to the separating structure 30 via the outer wiring 46, and at the same time, is to be applied to the outer well region 40 and the terminal region 42 via the outer wiring 46.

The source wiring 56 extends in a band shape along the peripheral edge of the first main surface 3 (the peripheral edge of the active region 8) along the extension direction of the outer contact region 41 in plan view. In this embodiment, the source wiring 56 is formed in a polygonal annular shape (in this embodiment, a quadrangle annular shape) having four sides parallel to the peripheral edge of the chip 2 in plan view, and surrounds the inner portion of the first main surface 3 (the active region 8). The source wiring 56 may have an edge portion connecting, in an arcuate shape (preferably, a quarter arcuate shape), a portion extending in the first direction X and a portion extending in the second direction Y. The source wiring 56 may be a shape with ends or an endless shape.

The source wiring 56 has an inner edge portion on the inner portion side of the first main surface 3 (the active region 8 side) and an outer edge portion on the peripheral edge portion side of the first main surface 3. The inner edge portion of the source wiring 56 is positioned in the active region 8, and faces one or a plurality (in this embodiment, a plurality) of the separating structures 30 with the interlayer film 47 interposed therebetween.

The outer edge portion of the source wiring 56 is formed at an interval from the peripheral edge of the first main surface 3 toward the inner side (the active region 8 side). The outer edge portion of the source wiring 56 is formed at an interval inward from the innermost field region 43 among the plurality of field regions 43. That is, the source wiring 56 does not face the plurality of field regions 43 with the interlayer film 47 interposed therebetween.

According to this arrangement, a dispersion path of an electric field in the region above the plurality of field regions 43 is suppressed from being shielded by the source wiring 56, and an electric field (a line of electric force) is dispersed appropriately by the plurality of field regions 43.

The outer edge portion of the source wiring 56 is formed at an interval inward from the outer edge portion of the terminal region 42, and faces the terminal region 42 with the interlayer film 47 interposed therebetween. In this embodiment, the outer edge portion of the source wiring 56 is arranged at an interval toward the outer edge portion side of the terminal region 42 from the outer edge portion of the outer contact region 41, and faces an entirety of the outer contact region 41 with the main surface insulating film 45 interposed therebetween.

As with the source electrode 51, the source wiring 56 has a laminated structure including a lower electrode film 52 and a main electrode film 53 laminated in that order from the chip 2 side. In this embodiment, the lower electrode film 52 has a laminated structure including a first electrode film 54 and a second electrode film 55.

The first electrode film 54 collectively covers, in a film shape, a region of the interlayer film 47 in which the outer opening 50 is formed, and enters the outer opening 50 from above the interlayer film 47. The first electrode film 54 has a portion that covers the insulating main surface of the interlayer film 47 in a film shape, a portion that covers the wall surface of the outer opening 50 in a film shape, and a portion that covers the outer wiring 46 and the first main surface 3 in a film shape in the outer opening 50. The first electrode film 54 is mechanically and electrically connected to the outer contact region 41 and the outer wiring 46 in the outer opening 50.

The second electrode film 55 directly covers the first electrode film 54. The second electrode film 55 collectively covers, in a film shape, a region of the interlayer film 47 in which the outer openings 50 are formed with the first electrode film 54 interposed therebetween, and enters the outer opening 50 from above the interlayer film 47.

The second electrode film 55 has a portion that covers the insulating main surface of the interlayer film 47 in a film shape with the first electrode film 54 interposed therebetween, a portion that covers the wall surfaces of the outer openings 50 in a film shape with the first electrode film 54 interposed therebetween, and a portion that covers the first main surface 3 in a film shape with the first electrode film 54 interposed therebetween in the outer openings 50. The second electrode film 55 is electrically connected to the outer contact region 41 and the outer wiring 46 via the first electrode film 54 in the outer opening 50.

The main electrode film 53 directly covers the lower electrode film 52 (the second electrode film 55). The main electrode film 53 collectively covers, in a film shape, a region of the interlayer film 47 in which the outer openings 50 are formed, and backfills the outer openings 50.

The main electrode film 53 has a portion that covers the insulating main surface of the interlayer film 47 with the lower electrode film 52 interposed therebetween, a portion that covers the wall surfaces of the outer openings 50 with the lower electrode film 52 interposed therebetween, and a portion that covers the first main surface 3 with the lower electrode film 52 interposed therebetween. The main electrode film 53 is electrically connected to the outer contact region 41 and the outer wiring 46 via the lower electrode film 52 in the outer opening 50.

The semiconductor device 1A includes a gate electrode 57 arranged on the first main surface 3. The gate electrode 57 is a terminal electrode to which the gate potential is to be applied from an exterior. The gate electrode 57 may be referred to as a “second pad electrode,” a “second main surface electrode,” a “second terminal electrode,” etc. Although not illustrated, as with the source electrode 51, the gate electrode 57 includes a lower electrode film 52 and a main electrode film 53 laminated in that order from the interlayer film 47 side.

The gate electrode 57 is arranged on a portion of the interlayer film 47 that covers the active region 8 at an interval from the source electrode 51. In this embodiment, the gate electrode 57 is arranged in a region on the third side surface 5C side with respect to the first pad portion 51a, and faces the first pad portion 51a in the first direction X. The gate electrode 57 is interposed in a region between the second pad portion 51b and the third pad portion 51c, and faces both the second pad portion 51b and the third pad portion 51c in the second direction Y.

The gate electrode 57 is formed in a polygonal shape (in this embodiment, a quadrangle shape) having four sides parallel to the peripheral edge of the chip 2 in plan view. The gate electrode 57 has a plane area less than a plane area of the source electrode 51. The gate electrode 57 has a plane area less than the plane area of the first pad portion 51a. The gate electrode 57 may have a plane area less than the plane area of the second pad portion 51b (the third pad portion 51c).

The gate electrode 57 partially faces the plurality of gate structures 15 and the plurality of source structures 20 with the interlayer film 47 interposed therebetween. Specifically, the gate electrode 57 is arranged at an interval inward from the both end portions of the plurality of gate structures 15, and faces the inner portions of the plurality of gate structures 15 with the interlayer film 47 interposed therebetween. In this embodiment, the gate electrode 57 does not have a direct electrical connection location to the plurality of gate structures 15.

The gate electrode 57 may be electrically connected to the plurality of gate structures 15 via the plurality of gate openings 48. The portions of the plurality of gate structures 15 that are positioned at the gate electrode 57 may be removed. In this case, the gate electrode 57 may face the body region 10 with the main surface insulating film 45 and the interlayer film 47 interposed therebetween. The gate electrode 57 may partially face one or a plurality of the separating structures 30 with the interlayer film 47 interposed therebetween.

The semiconductor device 1A includes a gate wiring 58 drawn out from the gate electrode 57 onto the first main surface 3. The gate wiring 58 may be referred to as a “wiring,” a “second wiring,” a “finger electrode,” a “gate finger,” etc. The gate wiring 58 transmits the gate potential applied to the gate electrode 57 to other regions. Although not illustrated, as with the source electrode 51 (the gate electrode 57), the gate wiring 58 includes a lower electrode film 52 and a main electrode film 53 laminated in that order from the chip 2 side.

The gate wiring 58 is drawn from the gate electrode 57 onto a portion of the interlayer film 47 that covers the active region 8, and is routed to a region between the source electrode 51 and the source wiring 56 at an interval from the source electrode 51 and the source wiring 56.

The gate wiring 58 has a portion extending in a band shape in the first direction X and a portion extending in a band shape in the second direction Y in plan view, and intersects (specifically, is orthogonal to) end portions (in this embodiment, the both end portions) of the plurality of gate structures 15. In this embodiment, the gate wiring 58 is formed in a band shape with ends that has four sides parallel to the peripheral edge of the first main surface 3, and surrounds the source electrode 51.

The gate wiring 58 enters the plurality of gate openings 48 from above the interlayer film 47, and is mechanically and electrically connected to end portions (the both end portions) of the plurality of gate structures 15 (the first embedded electrodes 18) in the plurality of gate openings 48. Thereby, the gate potential applied to the gate electrode 57 is to be applied to the plurality of gate structures 15 via the gate wiring 58.

The semiconductor device 1A includes a drain electrode 59 that covers the second main surface 4. The drain electrode 59 is a terminal electrode to which the drain potential is to be applied from an exterior. The drain electrode 59 may be referred to as a “third pad electrode,” a “third main surface electrode,” a “third terminal electrode,” etc.

The drain electrode 59 is electrically connected to the first semiconductor region 6. The drain electrode 59 may cover an entirety of the second main surface 4 so as to be continuous to the peripheral edge of the second main surface 4 (the first to fourth side surfaces 5A to 5D). The drain electrode 59 may partially cover the second main surface 4 so as to expose the peripheral edge portion of the second main surface 4.

A breakdown voltage applicable between the source electrode 51 and the drain electrode 59 (between the first main surface 3 and the second main surface 4) may be not less than 500 V and not more than 3000 V. The breakdown voltage may have a value belonging to any one range among not less than 500 V and not more than 750 V, not less than 750 V and not more than 1000 V, not less than 1000 V and not more than 1250 V, not less than 1250 V and not more than 1500 V, not less than 1500 V and not more than 1750 V, not less than 1750 V and not more than 2000 V, not less than 2000 V and not more than 2250 V, not less than 2250 V and not more than 2500 V, not less than 2500 V and not more than 2750 V, and not less than 2750 V and not more than 3000 V.

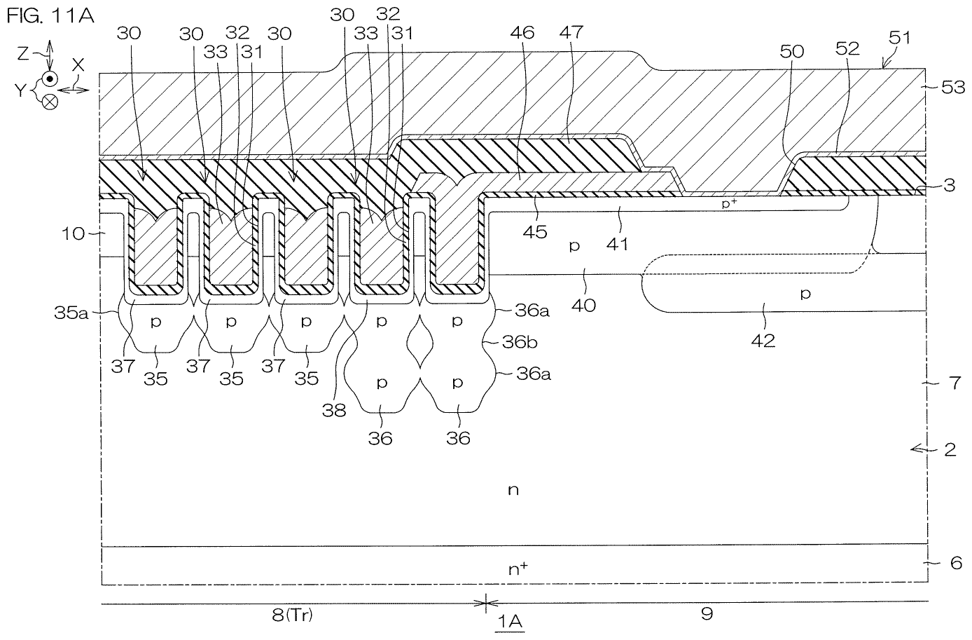

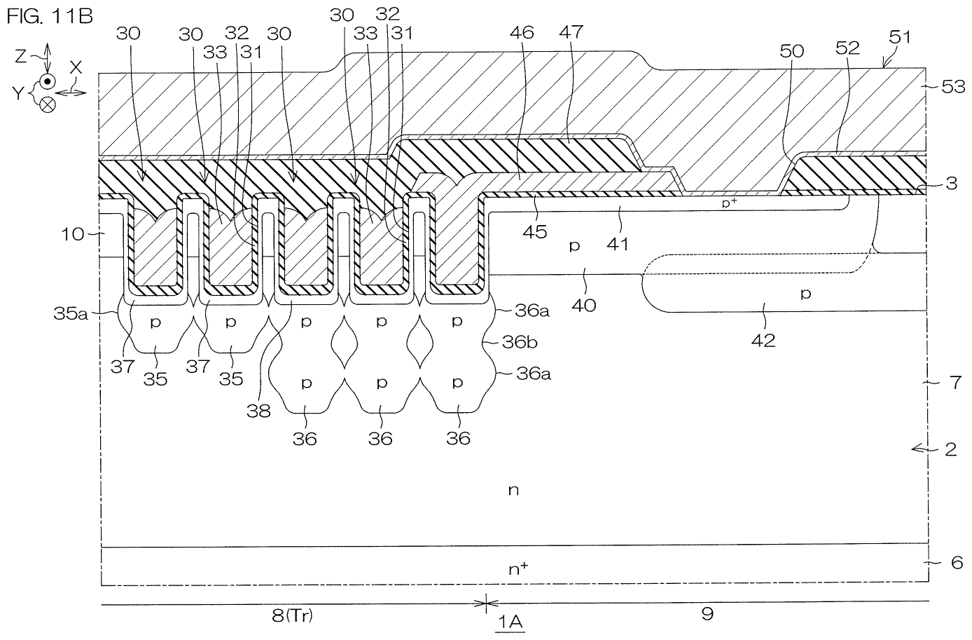

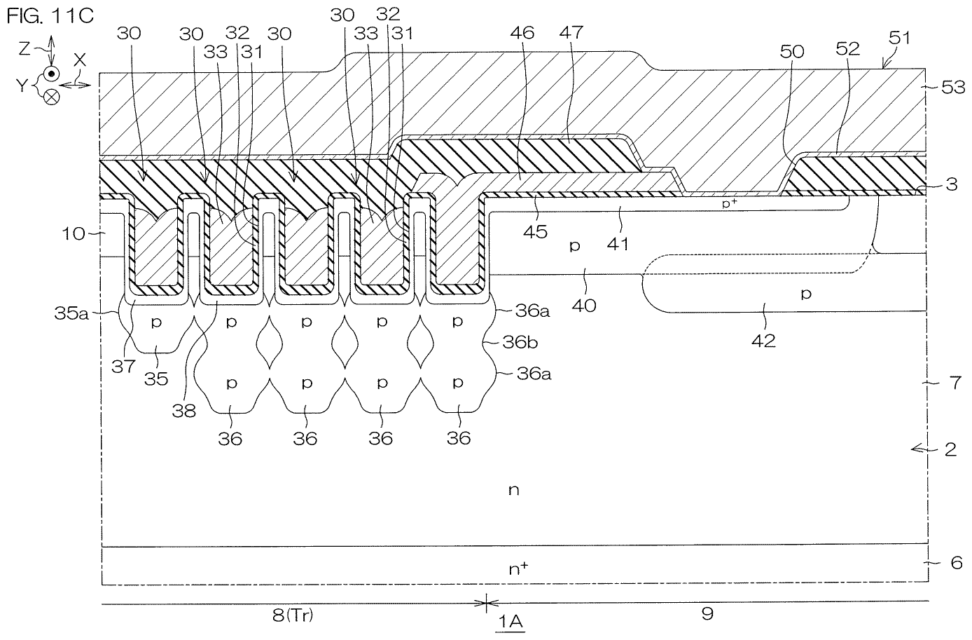

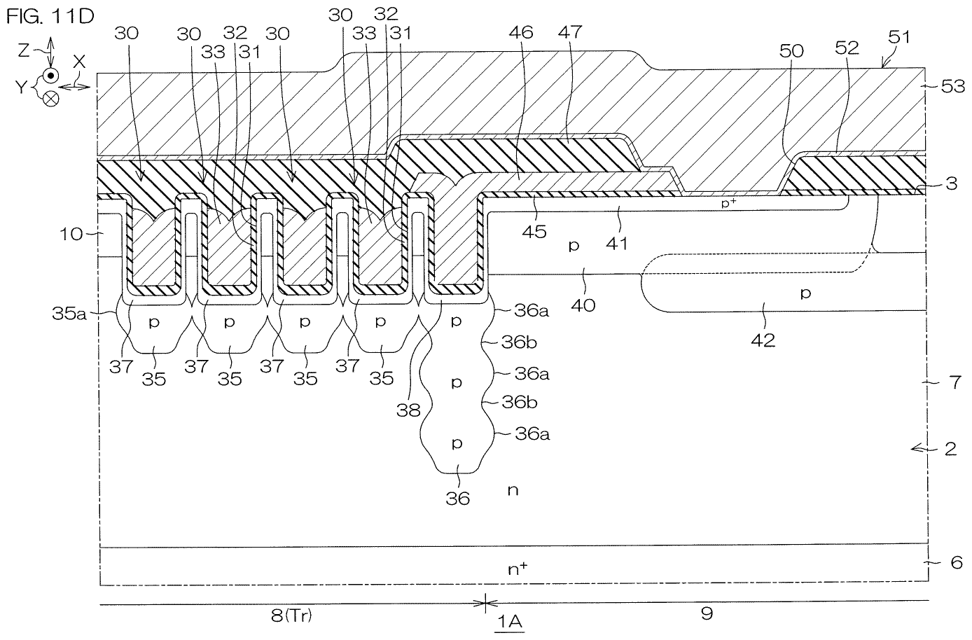

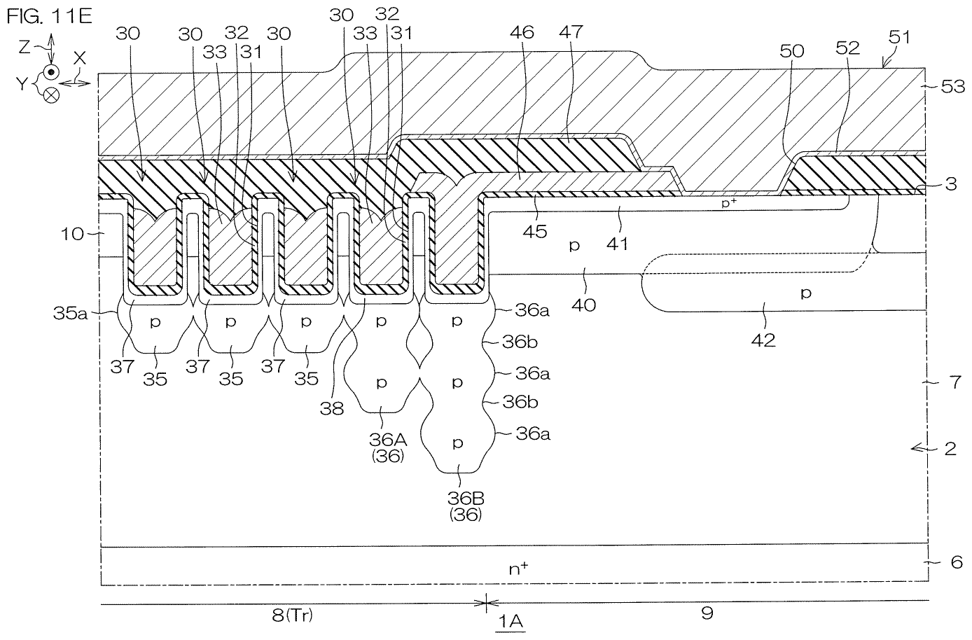

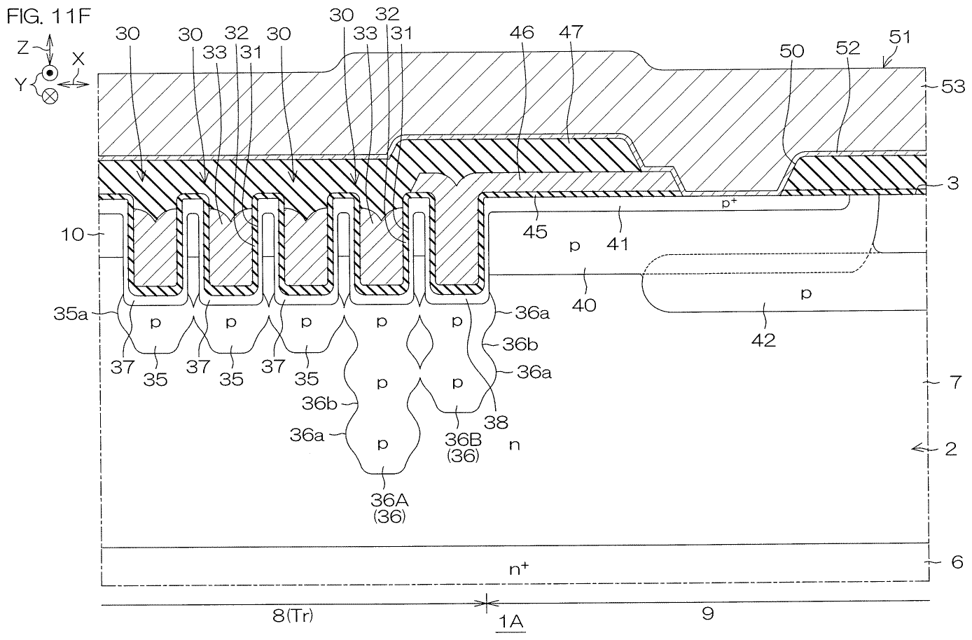

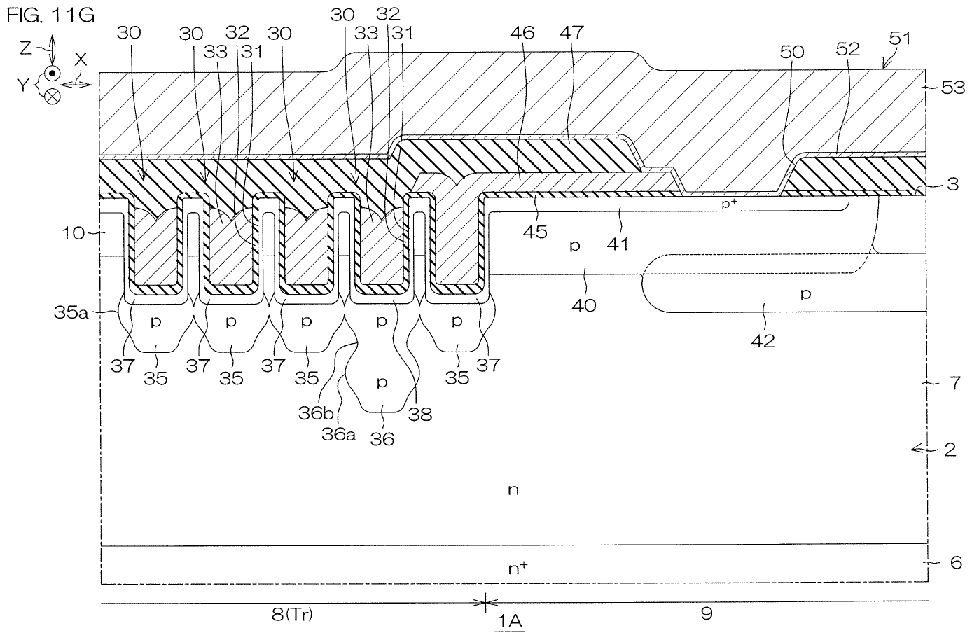

FIG. 11A to FIG. 11G are sectional views illustrating deep well regions 36 according to second to eighth configuration examples. The semiconductor device 1A may include at least one of the deep well regions 36 according to the first to eighth configuration examples. The semiconductor device 1A may include, in the same sectional region or different sectional regions, at least two of the deep well regions 36 according to the first to eighth configuration examples at the same time.

Referring to FIG. 11A (second configuration example), the semiconductor device 1A may include the two deep well regions 36. The number of the plurality of deep well regions 36 is smaller than the number of the plurality of shallow well regions 35.

In this embodiment, the two deep well regions 36 have depths that are substantially equal to each other. The two deep well regions 36 are respectively formed in thickness ranges between the bottom portion of the second semiconductor region 7 and the bottom walls of the two separating structures 30, and overlap the corresponding separating structures 30 in a one-to-one correspondence in the thickness direction.

The two deep well regions 36 are formed at an interval toward the outer peripheral region 9 side from the separating structure 30 for the shallow well region 35, and do not overlap the separating structure 30 for the shallow well region 35 in the thickness direction. The two deep well regions 36 are respectively formed in regions below the two separating structures 30 that are positioned outermost among the plurality of separating structures 30.

The two deep well regions 36 may be connected to each other in the horizontal direction. The innermost deep well region 36 may be connected to the shallow well region 35. Each of the two deep well regions 36 has a plurality (two or more) of the bulging portions 36a and one or more of the constricted portions 36b in the thickness direction of the chip 2.

One or a plurality of the bulging portions 36a of the two deep well regions 36 may be connected to each other in the horizontal direction. The constricted portions 36b of the two deep well regions 36 are formed at an interval in the horizontal direction, and may face each other in the horizontal direction with a portion of the second semiconductor region 7 interposed therebetween.

The upper bulging portions 36a of the two deep well regions 36 are positioned at a depth substantially equal to the depth of the bulging portions 35a of the plurality of shallow well regions 35. The lower bulging portions 36a of the two deep well regions 36 are respectively formed in a shape tapering toward the bottom portion. The lower bulging portion 36a is positioned on the bottom portion side of the second semiconductor region 7 with respect to a depth position of the bottom portion of each of the plurality of shallow well regions 35, and does not face the plurality of shallow well regions 35 in the horizontal direction.

The upper bulging portion 36a of the innermost deep well region 36 is connected to the bulging portion 35a of the outermost shallow well region 35. The upper bulging portion 36a may be formed at an interval in the horizontal direction from the outermost shallow well region 35.

The constricted portion 36b of the innermost deep well region 36 is formed at an interval in the horizontal direction from the outermost shallow well region 35. The constricted portion 36b is formed in a region on the separating structure 30 side with respect to the bottom portion of the outermost shallow well region 35, and faces the outermost shallow well region 35 in the horizontal direction. The constricted portion 36b may be positioned on the bottom portion side of the second semiconductor region 7 with respect to the bottom portion of the outermost shallow well region 35.

Referring to FIG. 11B (third configuration example), the semiconductor device 1A may include the three deep well regions 36. The number of the plurality of deep well regions 36 is larger than the number of the plurality of shallow well regions 35.

In this embodiment, the three deep well regions 36 have depths that are substantially equal to each other. The three deep well regions 36 are respectively formed in thickness ranges between the bottom portion of the second semiconductor region 7 and the bottom walls of the three separating structures 30, and overlap the corresponding separating structures 30 in a one-to-one correspondence in the thickness direction.

The three deep well regions 36 are formed at an interval toward the outer peripheral region 9 side from the separating structure 30 for the shallow well region 35, and do not overlap the separating structure 30 for the shallow well region 35 in the thickness direction. The three deep well regions 36 are respectively formed in regions below the three separating structures 30 that are positioned outermost among the plurality of separating structures 30.

The three deep well regions 36 may be connected to each other in the horizontal direction. The innermost deep well region 36 may be connected to the shallow well region 35. Each of the three deep well regions 36 has a plurality (two or more) of the bulging portions 36a and one or more of the constricted portions 36b in the thickness direction of the chip 2.

One or a plurality of the bulging portions 36a of the three deep well regions 36 may be connected to each other in the horizontal direction. The constricted portions 36b of the three deep well regions 36 are formed at an interval in the horizontal direction, and may face each other in the horizontal direction with a portion of the second semiconductor region 7 interposed therebetween.

The upper bulging portions 36a of the three deep well regions 36 are positioned at a depth substantially equal to the depth of the bulging portions 35a of the plurality of shallow well regions 35. The lower bulging portions 36a of the three deep well regions 36 are respectively formed in a shape tapering toward the bottom portion. The lower bulging portion 36a is positioned on the bottom portion side of the second semiconductor region 7 with respect to a depth position of the bottom portion of each of the plurality of shallow well regions 35, and does not face the plurality of shallow well regions 35 in the horizontal direction.

The upper bulging portion 36a of the innermost deep well region 36 is connected to the bulging portion 35a of the outermost shallow well region 35. The upper bulging portion 36a may be formed at an interval in the horizontal direction from the outermost shallow well region 35.

The constricted portion 36b of the innermost deep well region 36 is formed at an interval in the horizontal direction from the outermost shallow well region 35. The constricted portion 36b is formed in a region on the separating structure 30 side with respect to the bottom portion of the outermost shallow well region 35, and faces the outermost shallow well region 35 in the horizontal direction. The constricted portion 36b may be positioned on the bottom portion side of the second semiconductor region 7 with respect to the bottom portion of the outermost shallow well region 35.

Referring to FIG. 11C (fourth configuration example), in the semiconductor device 1A, the semiconductor device 1A may include the four deep well regions 36. The number of the plurality of deep well regions 36 is larger than the number of the plurality of shallow well regions 35.

In this embodiment, the four deep well regions 36 have depths that are substantially equal to each other. The four deep well regions 36 are respectively formed in thickness ranges between the bottom portion of the second semiconductor region 7 and the bottom walls of the four separating structures 30, and overlap the corresponding separating structures 30 in a one-to-one correspondence in the thickness direction.

The four deep well regions 36 are formed at an interval toward the outer peripheral region 9 side from the separating structure 30 for the shallow well region 35, and do not overlap the separating structure 30 for the shallow well region 35 in the thickness direction. The four deep well regions 36 are respectively formed in regions below the four separating structures 30 that are positioned outermost among the plurality of separating structures 30.

The four deep well regions 36 may be connected to each other in the horizontal direction. The innermost deep well region 36 may be connected to the shallow well region 35. Each of the four deep well regions 36 has a plurality (two or more) of the bulging portions 36a and one or more of the constricted portions 36b in the thickness direction of the chip 2.

One or a plurality of the bulging portions 36a of the four deep well regions 36 may be connected to each other in the horizontal direction. The constricted portions 36b of the four deep well regions 36 are formed at an interval in the horizontal direction, and may face each other in the horizontal direction with a portion of the second semiconductor region 7 interposed therebetween.

The upper bulging portions 36a of the four deep well regions 36 are positioned at a depth substantially equal to the depth of the bulging portions 35a of the plurality of shallow well regions 35. The lower bulging portions 36a of the four deep well regions 36 are respectively formed in a shape tapering toward the bottom portion. The lower bulging portion 36a is positioned on the bottom portion side of the second semiconductor region 7 with respect to a depth position of the bottom portion of each of the plurality of shallow well regions 35, and does not face the plurality of shallow well regions 35 in the horizontal direction.

The upper bulging portion 36a of the innermost deep well region 36 is connected to the bulging portion 35a of the outermost shallow well region 35. The upper bulging portion 36a may be formed at an interval in the horizontal direction from the outermost shallow well region 35.

The constricted portion 36b of the innermost deep well region 36 is formed at an interval in the horizontal direction from the outermost shallow well region 35. The constricted portion 36b is formed in a region on the separating structure 30 side with respect to the bottom portion of the outermost shallow well region 35, and faces the outermost shallow well region 35 in the horizontal direction. The constricted portion 36b may be positioned on the bottom portion side of the second semiconductor region 7 with respect to the bottom portion of the outermost shallow well region 35.

Referring to FIG. 11D (fifth configuration example), the semiconductor device 1A may include one or a plurality (in this embodiment, one) of the deep well regions 36 having three or more of the bulging portions 36a and two or more of the constricted portions 36b. The plurality of bulging portions 36a include the bulging portion 36a on the upper side (the separating structure 30 side), an intermediate bulging portion 36a, and the bulging portion 36a on the lower side (the bottom portion side of the second semiconductor region 7).

The upper bulging portion 36a is positioned at a depth substantially equal to the depth of the bulging portion 35a of each of the plurality of shallow well regions 35. In this embodiment, the upper bulging portion 36a is connected to the bulging portion 35a of the shallow well region 35. The upper bulging portion 36a may be formed at an interval in the horizontal direction from the shallow well region 35.

The intermediate bulging portion 36a is positioned on the bottom portion side of the second semiconductor region 7 with respect to the depth position of the bottom portion of each of the plurality of shallow well regions 35, and does not face the plurality of shallow well regions 35 in the horizontal direction. In this embodiment, a p-type impurity concentration of an intermediate portion of the intermediate bulging portion 36a is less than a p-type impurity concentration of an intermediate portion of the upper bulging portion 36a.

The lower bulging portion 36a is positioned on the bottom portion side of the second semiconductor region 7 with respect to a depth position of the bottom portion of each of the plurality of shallow well regions 35, and does not face the plurality of shallow well regions 35 in the horizontal direction. The lower bulging portion 36a is formed in a shape tapering toward the bottom portion.

In this embodiment, a p-type impurity concentration of an intermediate portion of the lower bulging portion 36a is less than a p-type impurity concentration of an intermediate portion of the intermediate bulging portion 36a. That is, the p-type impurity concentrations of the plurality of bulging portions 36a gradually decrease from the bottom wall side of the separating structure 30 toward the bottom portion side of the second semiconductor region 7.

The plurality of constricted portions 36b include the constricted portion 36b on the upper side and the constricted portion 36b on the lower side. The upper constricted portion 36b is formed at an interval in the horizontal direction from the outermost shallow well region 35. The upper constricted portion 36b is formed in a region on the separating structure 30 side with respect to the bottom portion of the outermost shallow well region 35, and faces the outermost shallow well region 35 in the horizontal direction. The upper constricted portion 36b may be positioned on the bottom portion side of the second semiconductor region 7 with respect to the bottom portion of the outermost shallow well region 35.

The upper constricted portion 36b includes the p-type impurity on a lower end portion side of the upper bulging portion 36a and a p-type impurity on an upper end portion side of the intermediate bulging portion 36a. The p-type impurity concentration of the upper constricted portion 36b may be higher than the p-type impurity concentration on the lower end portion side of the upper bulging portion 36a and the p-type impurity concentration on the upper end portion side of the intermediate bulging portion 36a. The p-type impurity concentration of the upper constricted portion 36b may be lower than the p-type impurity concentration of the intermediate portion of the upper bulging portion 36a and the p-type impurity concentration of the intermediate portion of the intermediate bulging portion 36a.

The lower constricted portion 36b is formed in a region on the bottom portion side of the second semiconductor region 7 with respect to the bottom portions of the plurality of shallow well regions 35, and does not face the outermost shallow well region 35 in the horizontal direction. The lower constricted portion 36b includes a p-type impurity on a lower end portion side of the intermediate bulging portion 36a and the p-type impurity on an upper end portion side of the lower bulging portion 36a.

The p-type impurity concentration of the lower constricted portion 36b may be higher than the p-type impurity concentration on the lower end portion side of the intermediate bulging portion 36a and the p-type impurity concentration on the upper end portion side of the lower bulging portion 36a. The p-type impurity concentration of the lower constricted portion 36b may be lower than the p-type impurity concentration of the intermediate portion of the intermediate bulging portion 36a and the p-type impurity concentration of the intermediate portion of the lower bulging portion 36a.

Referring to FIG. 11E (sixth configuration example), the semiconductor device 1A may include a plurality of the deep well regions 36 having mutually different depths. In this embodiment, the plurality of deep well regions 36 includes one or a plurality (in this embodiment, one) of first deep well regions 36A and one or a plurality (in this embodiment, one) of second deep well regions 36B.

The first deep well region 36A is positioned on the peripheral edge side of the first main surface 3 (the outer peripheral region 9 side) with respect to the plurality of shallow well regions 35. The first deep well region 36A is formed in a region below (specifically, directly below) the separating structure 30 positioned on the outer peripheral region 9 side (the peripheral edge side of the first main surface 3) among the plurality of separating structures 30. In this embodiment, the first deep well region 36A is formed in a region below the separating structure 30 that is positioned further inward than the outermost separating structure 30.

The first deep well region 36A has a first depth larger than the depths of the plurality of shallow well regions 35. The first deep well region 36A has a bottom portion that is positioned further to the bottom portion side of the second semiconductor region 7 than the bottom portions of the plurality of shallow well regions 35.

The first deep well region 36A is formed in a thickness range between the bottom portion of the second semiconductor region 7 and the bottom wall of the corresponding separating structure 30, and overlaps the corresponding separating structure 30 in a one-to-one correspondence in the thickness direction. That is, the first deep well region 36A is formed at an interval toward the outer peripheral region 9 side from the separating structure 30 for the shallow well region 35, and does not overlap the separating structure 30 for the shallow well region 35 in the thickness direction.

The first deep well region 36A has a plurality (two or more) of the bulging portions 36a and one or more of the constricted portions 36b in the thickness direction of the chip 2. The plurality of bulging portions 36a include the upper bulging portion 36a and the lower bulging portion 36a.

The upper bulging portion 36a is positioned at a depth substantially equal to the depth of the bulging portion 35a of each of the plurality of shallow well regions 35. The upper bulging portion 36a is connected to the bulging portion 35a of the outermost shallow well region 35. The upper bulging portion 36a may be formed at an interval in the horizontal direction from the outermost shallow well region 35.

The lower bulging portion 36a is formed in a shape tapering toward the bottom portion. The lower bulging portion 36a is positioned on the bottom portion side of the second semiconductor region 7 with respect to a depth position of the bottom portion of each of the plurality of shallow well regions 35, and does not face the plurality of shallow well regions 35 in the horizontal direction.

The constricted portion 36b is formed at an interval in the horizontal direction from the outermost shallow well region 35. The constricted portion 36b is formed in a region on the separating structure 30 side with respect to the bottom portion of the outermost shallow well region 35, and faces the outermost shallow well region 35 in the horizontal direction. The constricted portion 36b may be positioned on the bottom portion side of the second semiconductor region 7 with respect to the bottom portion of the outermost shallow well region 35.

The second deep well region 36B is positioned on the peripheral edge side of the first main surface 3 (the outer peripheral region 9 side) with respect to the first deep well region 36A. The second deep well region 36B is formed in a region below (specifically, directly below) the separating structure 30 positioned on the outer peripheral region 9 side (the peripheral edge side of the first main surface 3) among the plurality of separating structures 30. In this embodiment, the second deep well region 36B is formed in a region below the outermost separating structure 30.

The second deep well region 36B has a second depth larger than the first depth of the first deep well region 36A, and has a bottom portion that is positioned further to the bottom portion side of the second semiconductor region 7 than the bottom portion of the first deep well region 36A. The depths of the plurality of deep well regions 36 gradually increase toward the peripheral edge side of the first main surface 3 (the outer peripheral region 9 side) with the plurality of shallow well regions 35 as starting points.

The second deep well region 36B is formed in a thickness range between the bottom portion of the second semiconductor region 7 and the bottom wall of the corresponding separating structure 30, and overlaps the corresponding separating structure 30 in a one-to-one correspondence in the thickness direction. That is, the second deep well region 36B is formed at an interval toward the outer peripheral region 9 side from the separating structure 30 for the first deep well region 36A, and does not overlap the separating structure 30 for the first deep well region 36A in the thickness direction.

The second deep well region 36B has (three or more) of the bulging portions 36a and (two or more) of the constricted portions 36b in the thickness direction of the chip 2. The number of the bulging portions 36a in the second deep well region 36B is larger than the number of the bulging portions 36a in the first deep well region 36A. The number of the constricted portions 36b in the second deep well region 36B is larger than the number of the constricted portions 36b in the first deep well region 36A.

The plurality of bulging portions 36a in the second deep well region 36B include the bulging portion 36a on the upper side (the separating structure 30 side), the intermediate bulging portion 36a, and the bulging portion 36a on the lower side (the bottom portion side of the second semiconductor region 7).

The upper bulging portion 36a is positioned at a depth substantially equal to the depth of the upper bulging portion 36a of the first deep well region 36A. The upper bulging portion 36a is connected to the upper bulging portion 36a of the first deep well region 36A. The upper bulging portion 36a may be formed at an interval in the horizontal direction from the first deep well region 36A.

The intermediate bulging portion 36a is positioned at a depth substantially equal to the depth of the lower bulging portion 36a of the first deep well region 36A. The intermediate bulging portion 36a is connected to the lower bulging portion 36a of the first deep well region 36A. The intermediate bulging portion 36a may be formed at an interval in the horizontal direction from the first deep well region 36A.

The lower bulging portion 36a is positioned on the bottom portion side of the second semiconductor region 7 with respect to a depth position of the bottom portion of the first deep well region 36A, and does not face the first deep well region 36A in the horizontal direction. The lower bulging portion 36a is formed in a shape tapering toward the bottom portion.

The plurality of constricted portions 36b of the second deep well region 36B include the constricted portion 36b on the upper side (the separating structure 30 side) and the constricted portion 36b on the lower side (the bottom portion side of the second semiconductor region 7). The upper constricted portion 36b is formed at an interval in the horizontal direction from the constricted portion 36b of the first deep well region 36A, and faces the constricted portion 36b of the first deep well region 36A in the horizontal direction with a portion of the second semiconductor region 7 interposed therebetween.

The lower constricted portion 36b is formed at an interval in the horizontal direction from the bottom portion of the first deep well region 36A, and faces the bottom portion of the first deep well region 36A in the horizontal direction with a portion of the second semiconductor region 7 interposed therebetween.

With respect to the depth position of the constricted portion 36b of the first deep well region 36A, the upper constricted portion 36b may be positioned on the separating structure 30 side or may be positioned on the bottom portion side of the second semiconductor region 7. With respect to the bottom portion of the first deep well region 36A, the lower constricted portion 36b may be positioned on the separating structure 30 side or may be positioned on the bottom portion side of the second semiconductor region 7.

Referring to FIG. 11F (seventh configuration example), the semiconductor device 1A may include a plurality of the deep well regions 36 having mutually different depths. In this embodiment, the plurality of deep well regions 36 includes one or a plurality (in this embodiment, one) of first deep well regions 36A and one or a plurality (in this embodiment, one) of second deep well regions 36B.

The first deep well region 36A is positioned on the peripheral edge side of the first main surface 3 (the outer peripheral region 9 side) with respect to the plurality of shallow well regions 35. The first deep well region 36A is formed in a region below (specifically, directly below) the separating structure 30 positioned on the outer peripheral region 9 side (the peripheral edge side of the first main surface 3) among the plurality of separating structures 30. In this embodiment, the first deep well region 36A is formed in a region below the separating structure 30 that is positioned further inward than the outermost separating structure 30.

The first deep well region 36A has a first depth larger than the depths of the plurality of shallow well regions 35. The first deep well region 36A has a bottom portion that is positioned further to the bottom portion side of the second semiconductor region 7 than the bottom portions of the plurality of shallow well regions 35.

The first deep well region 36A is formed in a thickness range between the bottom portion of the second semiconductor region 7 and the bottom wall of the corresponding separating structure 30, and overlaps the corresponding separating structure 30 in a one-to-one correspondence in the thickness direction. That is, the first deep well region 36A is formed at an interval toward the outer peripheral region 9 side from the separating structure 30 for the shallow well region 35, and does not overlap the separating structure 30 for the shallow well region 35 in the thickness direction.

The first deep well region 36A has (three or more) of the bulging portions 36a and (two or more) of the constricted portions 36b in the thickness direction of the chip 2. The plurality of bulging portions 36a include the bulging portion 36a on the upper side (the separating structure 30 side), an intermediate bulging portion 36a, and the bulging portion 36a on the lower side (the bottom portion side of the second semiconductor region 7).

The upper bulging portion 36a is positioned at a depth substantially equal to the depth of the bulging portion 35a of each of the plurality of shallow well regions 35. The upper bulging portion 36a is connected to the bulging portion 35a of the outermost shallow well region 35. The upper bulging portion 36a may be formed at an interval in the horizontal direction from the outermost shallow well region 35.

The intermediate bulging portion 36a is positioned on the bottom portion side of the second semiconductor region 7 with respect to the bottom portion of the outermost shallow well region 35, and does not face the plurality of shallow well regions 35 in the horizontal direction.

The intermediate bulging portion 36a may be positioned on the separating structure 30 side with respect to the bottom portion of the outermost shallow well region 35, and may face the plurality of shallow well regions 35 in the horizontal direction.

The lower bulging portion 36a is positioned on the bottom portion side of the second semiconductor region 7 with respect to a depth position of the bottom portion of the outermost shallow well regions 35, and does not face the plurality of shallow well regions 35 in the horizontal direction. The lower bulging portion 36a is formed in a shape tapering toward the bottom portion.

The plurality of constricted portions 36b include the constricted portion 36b on the upper side (the separating structure 30 side) and the constricted portion 36b on the lower side (the bottom portion side of the second semiconductor region 7). The upper constricted portion 36b is formed at an interval in the horizontal direction from the outermost shallow well region 35. The upper constricted portion 36b is formed in a region on the separating structure 30 side with respect to the bottom portion of the outermost shallow well region 35, and faces the outermost shallow well region 35 in the horizontal direction. The upper constricted portion 36b may be positioned on the bottom portion side of the second semiconductor region 7 with respect to the bottom portion of the outermost shallow well region 35.

The lower constricted portion 36b is formed in a region on the bottom portion side of the second semiconductor region 7 with respect to the bottom portions of the plurality of shallow well regions 35, and does not face the outermost shallow well region 35 in the horizontal direction.

The second deep well region 36B is positioned on the peripheral edge side of the first main surface 3 (the outer peripheral region 9 side) with respect to the first deep well region 36A. The second deep well region 36B is formed in a region below (specifically, directly below) the separating structure 30 positioned on the outer peripheral region 9 side (the peripheral edge side of the first main surface 3) among the plurality of separating structures 30. In this embodiment, the second deep well region 36B is formed in a region below the outermost separating structure 30.

The second deep well region 36B has a second depth smaller than the first depth of the first deep well region 36A, and has a bottom portion that is positioned further to the separating structure 30 side than the bottom portion of the first deep well region 36A. The depths of the plurality of deep well regions 36 gradually decrease from the first deep well region 36A toward the peripheral edge side of the first main surface 3 (the outer peripheral region 9 side).

The second deep well region 36B is formed in a thickness range between the bottom portion of the second semiconductor region 7 and the bottom wall of the corresponding separating structure 30, and overlaps the outermost separating structure 30 in a one-to-one correspondence in the thickness direction. The second deep well region 36B is formed at an interval toward the outer peripheral region 9 side from the separating structure 30 for the first deep well region 36A, and does not overlap the separating structure 30 for the first deep well region 36A in the thickness direction.

The second deep well region 36B has (two or more) of the bulging portions 36a and one or more of the constricted portions 36b in the thickness direction of the chip 2. The number of the bulging portions 36a in the second deep well region 36B is smaller than the number of the bulging portions 36a in the first deep well region 36A. The number of the constricted portions 36b in the second deep well region 36B is smaller than the number of the constricted portions 36b in the first deep well region 36A.

The plurality of bulging portions 36a include the bulging portion 36a on the upper side (the separating structure 30 side) and the bulging portion 36a on the lower side (the bottom portion side of the second semiconductor region 7). The upper bulging portion 36a is positioned at a depth substantially equal to the depth of the upper bulging portion 36a of the first deep well region 36A. The upper bulging portion 36a is connected to the upper bulging portion 36a of the first deep well region 36A. The upper bulging portion 36a may be formed at an interval in the horizontal direction from the first deep well region 36A.

The lower bulging portion 36a is positioned on the bottom portion side of the second semiconductor region 7 with respect to a depth position of the bottom portion of each of the plurality of shallow well regions 35, and does not face the plurality of shallow well regions 35 in the horizontal direction. The lower bulging portion 36a is positioned on the separating structure 30 side with respect to the depth position of the bottom portion of the first deep well region 36A.

The lower bulging portion 36a is formed at a depth substantially equal to the depth of the intermediate bulging portion 36a of the first deep well region 36A. The lower bulging portion 36a is connected to the intermediate bulging portion 36a of the first deep well region 36A. The lower bulging portion 36a may be formed at an interval from the first deep well region 36A, and may face the first deep well region 36A with a portion of the second semiconductor region 7 interposed therebetween.

With respect to the intermediate bulging portion 36a of the first deep well region 36A, the lower bulging portion 36a may be positioned on the separating structure 30 side or may be positioned on the bottom portion side of the second semiconductor region 7. The lower bulging portion 36a is formed in a shape tapering toward the bottom portion.

The constricted portion 36b is formed at a depth substantially equal to the depth of the bottom portions of the plurality of shallow well regions 35. With respect to the bottom portions of the plurality of shallow well regions 35, the constricted portion 36b may be positioned on the separating structure 30 side or may be positioned on the bottom portion side of the second semiconductor region 7.

The constricted portion 36b is formed at an interval in the horizontal direction from the upper constricted portion 36b of the first deep well region 36A, and faces the constricted portion 36b of the first deep well region 36A in the horizontal direction with a portion of the second semiconductor region 7 interposed therebetween. With respect to the depth position of the constricted portion 36b of the first deep well region 36A, the upper constricted portion 36b may be positioned on the separating structure 30 side or may be positioned on the bottom portion side of the second semiconductor region 7.

Referring to FIG. 11G (eighth configuration example), the semiconductor device 1A may include the shallow well region 35 formed below the outermost separating structure 30, and may include the deep well region 36 formed below the separating structure 30 other than the outermost separating structure 30.

That is, one or a plurality of the deep well regions 36 according to the first to seventh configuration examples are not necessarily formed below the outermost separating structure 30. In this embodiment, an example is illustrated in which the single deep well region 36 is formed in a region below the single separating structure 30 adjacent to the outermost separating structure 30.

As described above, the semiconductor device 1A includes the chip 2, the second semiconductor region 7 (the semiconductor region) of the n-type (first conductivity type), the active region 8, the outer peripheral region 9, the separating structures 30 of the trench type, and the deep well region 36 of the p-type (second conductivity type). The chip 2 has the first main surface 3. The second semiconductor region 7 is formed in the surface layer portion of the first main surface 3. The active region 8 is provided in the inner portion of the first main surface 3. The outer peripheral region 9 is provided in the peripheral edge portion of the first main surface 3.

The separating structure 30 is formed in the first main surface 3 so as to be positioned in the second semiconductor region 7, and demarcates the active region 8 and the outer peripheral region 9. The deep well region 36 is formed in a region below the separating structure 30 so as to be positioned in the second semiconductor region 7, and is electrically connected to the second semiconductor region 7.

According to this arrangement, the semiconductor device 1A having a novel layout can be provided. For example, according to the semiconductor device 1A, the depletion layer spreads into the second semiconductor region 7 with the deep well region 36 as a starting point. Thereby, the electric field on the separating structure 30 is relaxed, and a decrease in withstand voltage (breakdown voltage) due to electric field concentration is prevented. That is, a decrease in withstand voltage with a boundary region between the active region 8 and the outer peripheral region 9 as a starting point is prevented.

The chip 2 may contain SiC. According to this arrangement, the semiconductor device 1A as an SiC semiconductor device having a novel layout can be provided. According to the semiconductor device 1A, the withstand voltage is further improved by the physical properties of SiC. In particular, in the case of the SiC semiconductor device, since the SiC semiconductor device is used under a relatively high voltage environment, an electric field relaxation effect (an effect of preventing a decrease in withstand voltage) by the deep well region 36 is effective.

The deep well region 36 may be formed in a vertically long columnar shape extending in the thickness direction of the chip 2. According to this arrangement, the electric field to the deep well region 36 can be dispersed in the thickness direction of the deep well region 36. Thereby, a localized electric field concentration on the deep well region 36 is relaxed, and a decrease in withstand voltage is prevented.

The deep well region 36 may be formed at an interval toward the first main surface 3 side from the bottom portion of the second semiconductor region 7. According to this arrangement, the depletion layer spreads appropriately into the second semiconductor region 7 in the thickness direction and the horizontal direction with the deep well region 36 as a starting point. Thereby, a decrease in withstand voltage due to electric field concentration is prevented appropriately.

The deep well region 36 may have the bulging portion 36a that protrudes in the horizontal direction along the first main surface 3 and the constricted portion 36b that is recessed in the horizontal direction with respect to the bulging portion 36a and is provided at a depth position different from that of the bulging portion 36a. According to this arrangement, the electric field concentration on the deep well region 36 can be dispersed appropriately in the thickness direction by the bulging portion 36a and the constricted portion 36b. Thereby, the localized electric field concentration is relaxed.

The deep well region 36 may include a plurality of impurity regions (36a) of the p-type formed at different depth positions so as to be connected to each other. According to this arrangement, the bulging portion 36a and the constricted portion 36b can be formed appropriately using the plurality of impurity regions (36a).

The plurality of separating structures 30 may be formed at an interval on the first main surface 3. In this case, the deep well region 36 may be formed in a region below at least one of the separating structures 30. According to this arrangement, the electric field on the plurality of separating structures 30 is relaxed by the deep well region 36.

The deep well region 36 may be formed in a region below the at least one separating structure 30 positioned on the outer peripheral region 9 side among the plurality of separating structures 30. According to this arrangement, the electric field on the at least one separating structure 30 positioned on the outer peripheral region 9 side is relaxed appropriately. In this case, the deep well region 36 does not have to be formed in a region below the at least one separating structure 30 positioned on the active region 8 side among the plurality of separating structures 30.

The semiconductor device 1A may include the shallow well region 35 of the p-type. The shallow well region 35 may be formed in a region below the at least one separating structure 30 so as to be positioned in the second semiconductor region 7, and may be electrically connected to the second semiconductor region 7. In this case, the deep well region 36 may have a depth larger than the depth of the shallow well region 35, and may be formed in a region below the separating structure 30 in a region other than the shallow well region 35.

According to this arrangement, the depletion layer spreads into the second semiconductor region 7 with the shallow well region 35 as a starting point, and at the same time, the depletion layer spreads into the second semiconductor region 7 with the deep well region 36 as a starting point. According to this arrangement, electric field concentration on the plurality of separating structures 30 is prevented by both the shallow well region 35 and the deep well region 36. The depletion layer on the deep well region 36 side spreads in a region lower than the depletion layer on the shallow well region 35 side. Thereby, the localized electric field concentration on the shallow well region 35 is relaxed by the deep well region 36.

The plurality of shallow well regions 35 may be formed in regions below the plurality of separating structures 30. According to this arrangement, electric field concentration on the plurality of separating structures 30 is prevented by both the plurality of shallow well regions 35 and deep well regions 36. Also, the localized electric field concentration on the plurality of shallow well regions 35 is relaxed by the deep well region 36.

One or a plurality of the shallow well regions 35 may be formed in regions below one or a plurality of the separating structures 30 positioned on the active region 8 side among the plurality of separating structures 30. The deep well region 36 may be formed in a region below the separating structure 30 positioned on the outer peripheral region 9 side among the plurality of separating structures 30.

According to this arrangement, electric field concentration on one or a plurality of the separating structures 30 positioned on the active region 8 side is relaxed by one or a plurality of the shallow well regions 35. Also, the electric field concentration on the separating structures 30 positioned on the outer peripheral region 9 side is relaxed by the deep well region 36.

Also, according to this arrangement, the depletion layer spreads from one or a plurality of the shallow well regions 35 toward a shallow region on the active region 8 side. On the other hand, the depletion layer spreads from the deep well region 36 to a deep region on the outer peripheral region 9 side. Therefore, the edge portion of the depletion layer with one or a plurality of the shallow well regions 35 as starting points is spread downward by the deep well region 36 in the region on the outer peripheral region 9 side. Thereby, the electric field concentration is relaxed appropriately in the vicinity of the separating structure 30 positioned on the outer peripheral region 9 side.

In this case, the deep well region 36 may be formed in a region below the outermost separating structure 30 positioned on the outer peripheral region 9 side among the plurality of separating structures 30. According to this arrangement, the electric field concentration is relaxed appropriately in the vicinity of the outermost separating structure 30.

The semiconductor device 1A may include the body region 10 of the p-type. The body region 10 may be formed in the surface layer portion of the second semiconductor region 7 in the active region 8. In this case, the separating structure 30 may be positioned lower than the bottom portion of the body region 10. The deep well region 36 may be positioned lower than the bottom portion of the body region 10.

According to this arrangement, in the active region 8, the depletion layer spreads to a shallow region with the body region 10 as a starting point. On the other hand, on the outer peripheral region 9 side, the depletion layer spreads to a deep region with the deep well region 36 as a starting point. Therefore, the edge portion of the depletion layer with the body region 10 as a starting point is spread downward by the deep well region 36 in the region on the outer peripheral region 9 side. Thereby, the electric field concentration is relaxed appropriately in the vicinity of the separating structure 30 positioned on the outer peripheral region 9 side.

The semiconductor device 1A may include the gate structures 15 of the trench type to which the gate potential is to be applied. The gate structures 15 may be formed in the first main surface 3 in the active region 8. In this case, the deep well region 36 may be formed lower than the bottom wall of the gate structure 15.

According to this arrangement, the edge portion of the depletion layer spreading to the region below the gate structure 15 is spread appropriately downward by the deep well region 36 in the region on the outer peripheral region 9 side. Thereby, the electric field concentration is relaxed appropriately in the vicinity of the separating structure 30 positioned on the outer peripheral region 9 side.

In this case, the separating structure 30 may have a depth not less than the depth of the gate structure 15. According to this arrangement, the formation location of the deep well region 36 can be set appropriately in the region lower than the bottom wall of the gate structure 15.

The semiconductor device 1A may include the source structures 20 of the trench type to which the source potential is to be applied. The source structures 20 may be formed in the first main surface 3 in the active region 8. In this case, the deep well region 36 may be formed lower than the bottom wall of the source structure 20.

According to this arrangement, the edge portion of the depletion layer spreading to the region below the source structure 20 is spread appropriately downward by the deep well region 36 in the region on the outer peripheral region 9 side. Thereby, the electric field concentration is relaxed appropriately in the vicinity of the separating structure 30 positioned on the outer peripheral region 9 side.

In this case, the separating structure 30 may have a depth not less than the depth of the source structure 20. According to this arrangement, the formation location of the deep well region 36 can be set appropriately in the region lower than the bottom wall of the source structure 20.

The semiconductor device 1A may include the outer well region 40 of the p-type. The outer well region 40 may be formed in the surface layer portion of the second semiconductor region 7 along the separating structure 30 in the outer peripheral region 9. According to this arrangement, the depletion layer with the deep well region 36 as a starting point is expanded toward the outer peripheral region 9 side by the depletion layer with the outer well region 40 as a starting point. Thereby, electric field concentration in the vicinity of the separating structure 30 is relaxed appropriately.

The outer well region 40 may have a depth smaller than the depth of the deep well region 36, or may have a depth larger than the depth of the deep well region 36. The depth of the outer well region 40 may be smaller than the depth of the separating structure 30, or may be larger than the depth of the separating structure 30.

The semiconductor device 1A may include the terminal region 42 of the p-type. The terminal region 42 may be formed in a region between the peripheral edge of the first main surface 3 and the outer well region 40 in the surface layer portion of the first main surface 3 of the outer peripheral region 9. According to this arrangement, the depletion layer with the outer well region 40 as a starting point is expanded toward the outer peripheral region 9 side by the depletion layer with the terminal region 42 as a starting point. Thereby, electric field concentration in the vicinity of the separating structure 30 and the vicinity of the outer well region 40 is relaxed appropriately.

The semiconductor device 1A may include the plurality of field regions 43 of the p-type. The plurality of field regions 43 may be formed, in the region between the peripheral edge of the first main surface 3 of the outer peripheral region 9 and the separating structure 30, in the surface layer portion of the second semiconductor region 7 at an interval. According to this arrangement, the depletion layer with the deep well region 36 as a starting point is expanded toward the peripheral edge side of the chip 2 by the depletion layer with the plurality of field regions 43 as starting points. Thereby, electric field concentration in the vicinity of the separating structure 30 is relaxed appropriately.

The semiconductor device 1A may include the outer wiring 46 and the source electrode 51 (terminal electrode). The outer wiring 46 may be electrically connected to the separating structure 30 on the separating structure 30. The source electrode 51 may be provided on the outer wiring 46, and may be electrically connected to the outer wiring 46. According to this arrangement, a source potential as a terminal potential is to be applied to the separating structure 30. That is, the deep well region 36 can be formed in the region below the separating structure 30 (that is, the separating structure 30 in which the source is provided) to which a specific potential is applied.

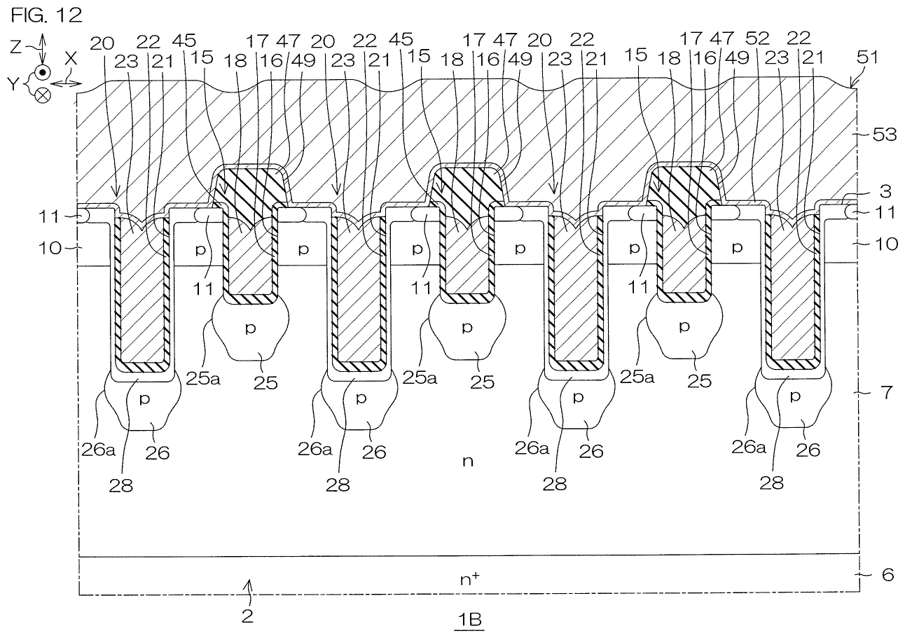

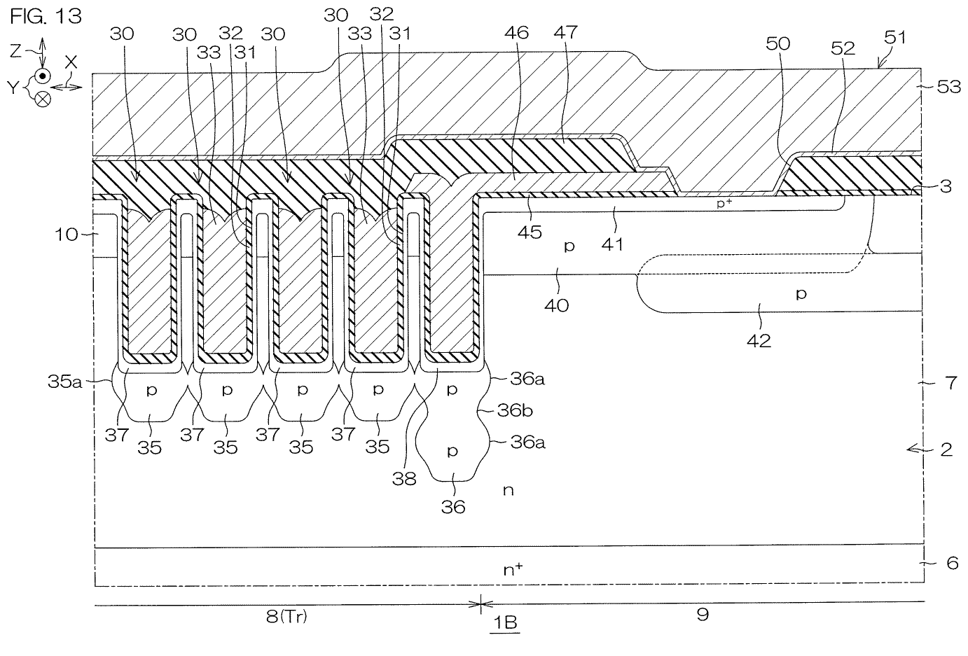

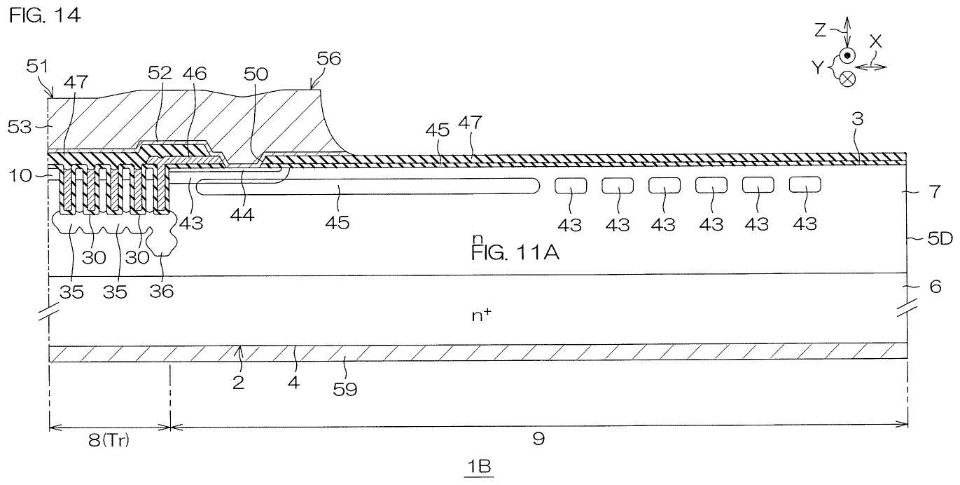

FIG. 12 is a sectional view illustrating the active region 8 of a semiconductor device 1B according to a second embodiment. FIG. 13 is a sectional view illustrating the deep well region 36 of the semiconductor device 1B illustrated in FIG. 12. FIG. 14 is a sectional view illustrating the outer peripheral region 9 of the semiconductor device 1B illustrated in FIG. 12. Referring to FIG. 12 to FIG. 14, the semiconductor device 1B has a form in which the arrangements of the plurality of gate structures 15, the plurality of source structures 20, and the plurality of separating structures 30 according to the semiconductor device 1A are changed.

The plurality of source structures 20 described above have a depth larger than the depth of the plurality of gate structures 15. The bottom walls of the plurality of source structures 20 are positioned on the bottom portion side of the second semiconductor region 7 with respect to the bottom walls of the plurality of gate structures 15.

The ratio (depth ratio) of the depth of the source structure 20 to the depth of the gate structure 15 may be larger than 1 and not more than 3. The depth ratio may have a value belonging to at least one range among larger than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3.

The plurality of separating structures 30 described above have a depth larger than the depth of the plurality of gate structures 15. The bottom walls of the plurality of separating structures 30 are positioned on the bottom portion side of the second semiconductor region 7 with respect to the bottom walls of the plurality of gate structures 15.

The depth of the plurality of separating structures 30 may be not less than the depth of the plurality of source structures 20. Preferably, the depth of the plurality of separating structures 30 is substantially equal to the depth of the plurality of source structures 20. Preferably, the bottom walls of the plurality of separating structures 30 are positioned at a depth substantially equal to the depth of the bottom walls of the plurality of source structures 20. The depth of the plurality of separating structures 30 may be larger than the depth of the plurality of source structures 20, or may be smaller than the depth of the plurality of source structures 20.

The ratio (depth ratio) of the depth of the separating structures 30 to the depth of the gate structures 15 may be larger than 1 and not more than 3. The depth ratio may have a value belonging to at least one range among larger than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3.

The plurality of gate well regions 25, the plurality of source well regions 26, the plurality of gate contact regions 27, the plurality of source contact regions 28, one or a plurality (in this embodiment, a plurality) of the shallow well regions 35, one or a plurality (in this embodiment, one) of the deep well regions 36, one or a plurality (in this embodiment, a plurality) of the shallow contact regions 37, and one or a plurality (in this embodiment, one) of the deep contact regions 38 described above are formed in the same layout as in the case of the first embodiment.

In this embodiment, the semiconductor device 1B includes the deep well region 36 according to the first configuration example. The semiconductor device 1B may include at least one of the deep well regions 36 according to the first to eighth configuration examples. The semiconductor device 1B may include, in the same sectional region or different sectional regions, at least two of the deep well regions 36 according to the first to eighth configuration examples at the same time.

In this embodiment, the plurality of source well regions 26 are positioned further to the bottom portion side of the second semiconductor region 7 than the bottom walls of the plurality of gate structures 15, and face each other in the horizontal direction with a portion of the second semiconductor region 7 interposed therebetween. The bottom portions of the plurality of source well regions 26 are positioned on the bottom portion side of the second semiconductor region 7 with respect to the bottom portions of the plurality of gate well regions 25.

The plurality of source well regions 26 are positioned on the bottom portion side of the second semiconductor region 7 with respect to the bottom portions of the plurality of gate well regions 25, and do not face the plurality of gate well regions 25 in the horizontal direction. The plurality of source well regions 26 may have portions positioned on the first main surface 3 side with respect to the bottom portions of the plurality of gate well regions 25, and may face the plurality of gate well regions 25 in the horizontal direction.

In this embodiment, the plurality of shallow well regions 35 are positioned further to the bottom portion side of the second semiconductor region 7 than the bottom walls of the plurality of gate structures 15. The bottom portions of the plurality of shallow well regions 35 are positioned on the bottom portion side of the second semiconductor region 7 with respect to the bottom portions of the plurality of gate well regions 25.

In this embodiment, the plurality of shallow well regions 35 are positioned on the bottom portion side of the second semiconductor region 7 with respect to the bottom portions of the plurality of gate well regions 25, and do not face the plurality of gate well regions 25 in the horizontal direction. The plurality of shallow well regions 35 may have portions positioned on the first main surface 3 side with respect to the bottom portions of the plurality of gate well regions 25, and may face the plurality of gate well regions 25 in the horizontal direction.

The plurality of shallow well regions 35 are formed at a depth position that is substantially equal to the depth position of the plurality of source well regions 26, and face the plurality of source well regions 26 in the horizontal direction with a portion of the second semiconductor region 7 interposed therebetween. The bottom portion of the shallow well region 35 may be positioned at a depth substantially equal to the depth of the bottom portion of the source well region 26.

With respect to the bottom portions of the source well regions 26, the bottom portions of the shallow well regions 35 may be positioned on the first main surface 3 side or may be positioned on the bottom portion side of the second semiconductor region 7. The depth of the shallow well region 35 may be larger than the depth of the source well region 26, or may be less than the depth of the source well region 26.

In this embodiment, the deep well region 36 is positioned further to the bottom portion side of the second semiconductor region 7 than the bottom walls of the plurality of gate structures 15. The bottom portion of the deep well region 36 is positioned on the bottom portion side of the second semiconductor region 7 with respect to the bottom portions of the plurality of gate well regions 25, the bottom portions of the plurality of source well regions 26, and the bottom portions of the plurality of shallow well regions 35.

In this embodiment, the deep well region 36 is positioned on the bottom portion side of the second semiconductor region 7 with respect to the bottom portions of the plurality of gate well regions 25, and do not face the plurality of gate well regions 25 in the horizontal direction. The deep well region 36 may have a portion positioned on the first main surface 3 side with respect to the bottom portions of the plurality of gate well regions 25, and may face the plurality of gate well regions 25 in the horizontal direction.

The depth of the deep well region 36 is larger than the depth of the source well region 26. That is, the bottom portion of the deep well region 36 is positioned on the bottom portion side of the second semiconductor region 7 with respect to the bottom portion of the source well region 26. The depth of the deep well region 36 is larger than the depth of the shallow well region 35. That is, the bottom portion of the deep well region 36 is positioned on the bottom portion side of the second semiconductor region 7 with respect to the bottom portion of the shallow well region 35.

The deep well region 36 faces the plurality of source well regions 26 and the plurality of shallow well regions 35 in the horizontal direction. The deep well region 36 is positioned on the bottom portion side of the second semiconductor region 7 with respect to the bottom portions of the plurality of source well regions 26, and has a portion that does not face the plurality of source well regions 26 in the horizontal direction.

The deep well region 36 is connected to the outermost shallow well region 35 in the horizontal direction. The deep well region 36 may be formed at an interval in the horizontal direction from the outermost shallow well region 35, and may face the outermost shallow well region 35 in the horizontal direction with a portion of the second semiconductor region 7 interposed therebetween.

The deep well region 36 has a plurality (two or more) of the bulging portions 36a and one or more of the constricted portions 36b in the thickness direction of the chip 2. The plurality of bulging portions 36a include the upper bulging portion 36a and the lower bulging portion 36a.

The upper bulging portion 36a is positioned at a depth substantially equal to the depths of the bulging portions 26a of the plurality of source well regions 26 and the bulging portions 35a of the plurality of shallow well regions 35. The upper bulging portion 36a is connected to the bulging portion 35a of the outermost shallow well region 35. The upper bulging portion 36a may be formed at an interval in the horizontal direction from the outermost shallow well region 35.

The lower bulging portion 36a is formed in a shape tapering toward the bottom portion. The lower bulging portion 36a is positioned on the bottom portion side of the second semiconductor region 7 with respect to depth positions of the bottom portions of the plurality of source well regions 26 and the bottom portions of the plurality of shallow well regions 35, and does not face the plurality of source well regions 26 and the plurality of shallow well regions 35 in the horizontal direction.

The constricted portion 36b is formed in a region on the separating structure 30 side with respect to the bottom portions of the plurality of source well regions 26 and the bottom portions of the plurality of shallow well regions 35, and faces the plurality of source well regions 26 in the horizontal direction. The constricted portion 36b may be positioned on the bottom portion side of the second semiconductor region 7 with respect to the bottom portions of the plurality of source well regions 26 and the bottom portions of the plurality of shallow well regions 35.

The constricted portion 36b is formed at an interval in the horizontal direction from the outermost shallow well region 35. The constricted portion 36b is formed in a region on the separating structure 30 side with respect to the bottom portion of the outermost shallow well region 35, and faces the outermost shallow well region 35 in the horizontal direction. The constricted portion 36b may be positioned on the bottom portion side of the second semiconductor region 7 with respect to the bottom portion of the outermost shallow well region 35.

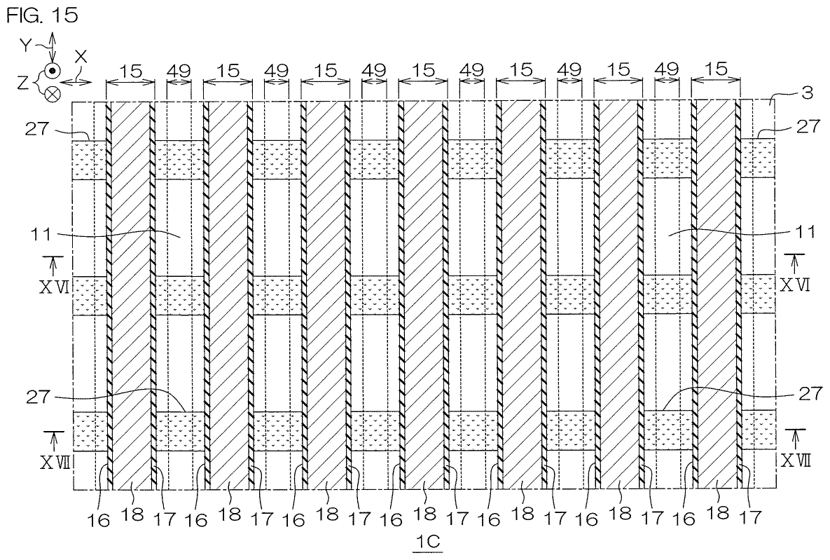

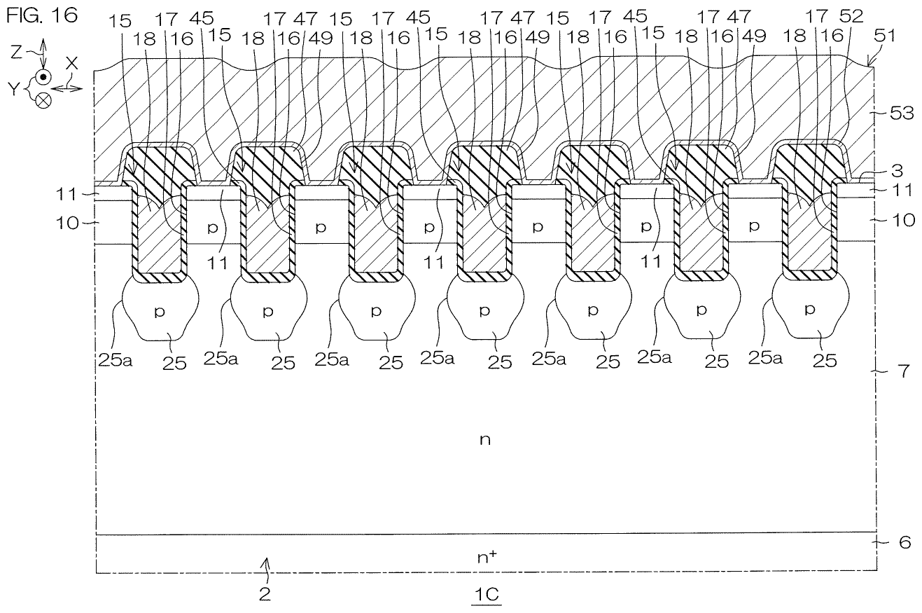

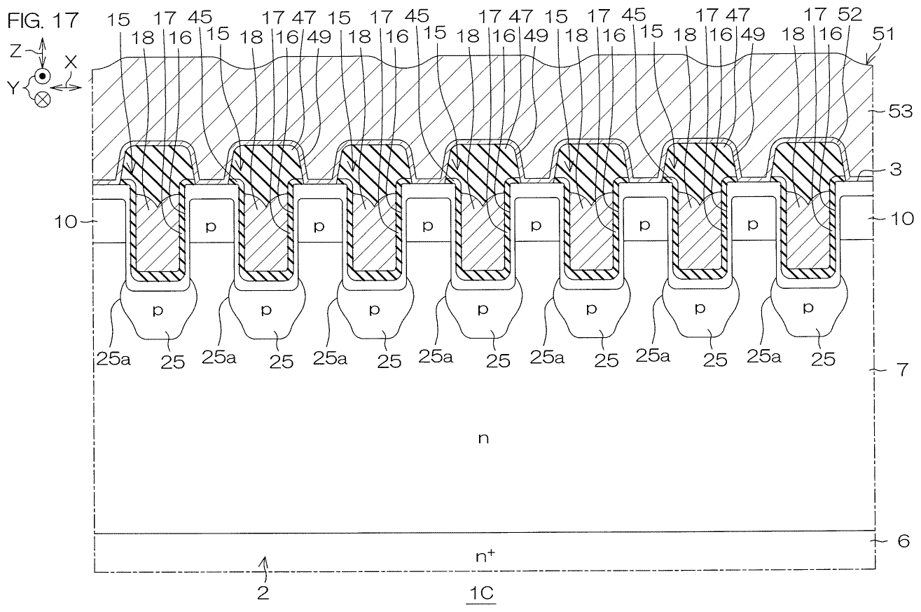

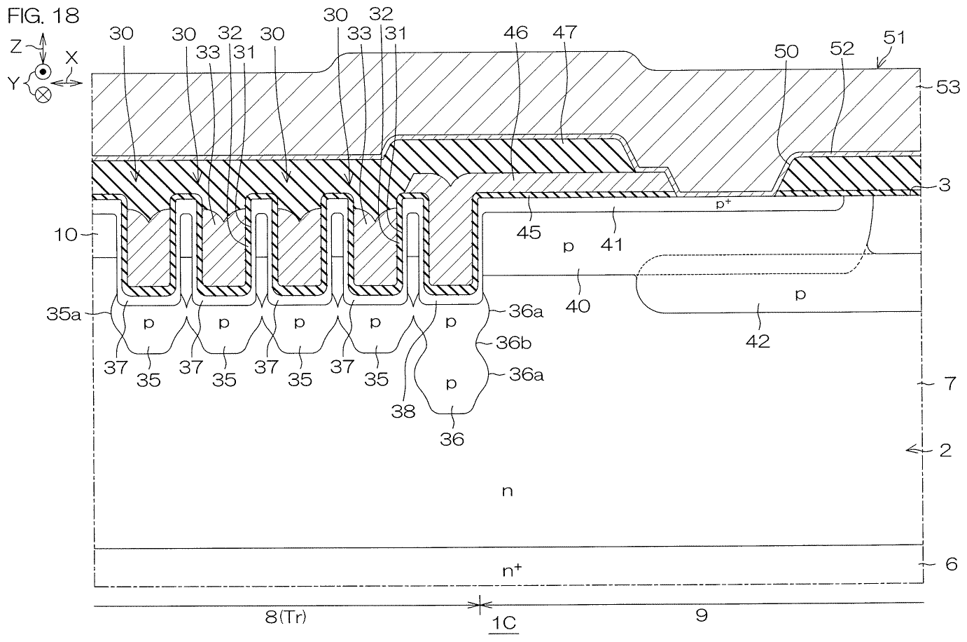

FIG. 15 is an enlarged plan view illustrating the active region 8 of a semiconductor device 1C according to a third embodiment. FIG. 16 is a sectional view taken along line XVI-XVI illustrated in FIG. 15. FIG. 17 is a sectional view taken along line XVII-XVII illustrated in FIG. 15. FIG. 18 is a sectional view illustrating the outer peripheral region 9 of the semiconductor device 1C illustrated in FIG. 15.

Referring to FIG. 15 to FIG. 18, the semiconductor device 1C has a form in which the arrangements of the plurality of gate structures 15, the plurality of source structures 20, and the plurality of separating structures 30 according to the semiconductor device 1A are changed. Specifically, unlike the semiconductor device 1A, the semiconductor device 1C includes the plurality of gate structures 15 and the plurality of separating structures 30, and does not include the plurality of source structures 20. The semiconductor device 1C does not include the source well region 26 and the source contact region 28.

In this embodiment, the plurality of gate structures 15 are aligned at an interval in the first direction X (=m-axis direction) so as to be adjacent to each other, and each extend in a band shape in the second direction Y (=a-axis direction). The plurality of separating structures 30 are arranged at the peripheral edge portion of the active region 8 at an interval from the plurality of gate structures 15. Each of the plurality of separating structures 30 may be formed in a polygonal annular shape (a quadrangle annular shape) collectively surrounding the plurality of gate structures 15 in plan view.

The plurality of separating structures 30 may have a depth not less than the depth of the plurality of gate structures 15. Preferably, the depth of the plurality of separating structures 30 is substantially equal to the depth of the plurality of gate structures 15. The depth of the plurality of separating structures 30 may be larger than the depth of the plurality of gate structures 15, or may be smaller than the depth of the plurality of gate structures 15.

The plurality of gate well regions 25, the plurality of gate contact regions 27, one or a plurality (in this embodiment, a plurality) of the shallow well regions 35, one or a plurality (in this embodiment, one) of the deep well regions 36, one or a plurality (in this embodiment, a plurality) of the shallow contact regions 37, and one or a plurality (in this embodiment, one) of the deep contact regions 38 described above are formed in the same layout as in the case of the first embodiment.

In this embodiment, the semiconductor device 1C includes the deep well region 36 according to the first configuration example. The semiconductor device 1C may include at least one of the deep well regions 36 according to the first to eighth configuration examples. The semiconductor device 1C may include, in the same sectional region or different sectional regions, at least two of the deep well regions 36 according to the first to eighth configuration examples at the same time.

In this embodiment, the plurality of gate contact regions 27 are formed at an interval in the first direction X and the second direction Y. With respect to the one gate structure 15 and the other gate structures 15, the plurality of gate contact regions 27 along one gate structure 15 face the plurality of gate contact regions 27 along the other gate structures 15 in the first direction X in plan view.

That is, the plurality of gate contact regions 27 are aligned in a matrix at an interval in the first direction X and the second direction Y as a whole in plan view. In this case, the plurality of gate contact regions 27 along the one gate structure 15 may be connected to the plurality of gate contact regions 27 along the other gate structures 15 in the surface layer portion of the body region 10.

The plurality of gate contact regions 27 along the one gate structure 15 may face the plurality of gate contact regions 27 along the other gate structures 15 in regions between the gate contact regions 27 in the first direction X in plan view. That is, the plurality of gate contact regions 27 may be aligned in a staggered manner at an interval in the first direction X and the second direction Y as a whole in plan view.

In this embodiment, the plurality of shallow well regions 35 are positioned further to the bottom portion side of the second semiconductor region 7 than the bottom walls of the plurality of gate structures 15. The plurality of shallow well regions 35 are formed at a depth substantially equal to the depth of the plurality of gate well regions 25, and face the plurality of gate well regions 25 in the horizontal direction.

The bottom portions of the plurality of shallow well regions 35 may be positioned at a depth substantially equal to the depth of the bottom portions of the gate well regions 25. With respect to the bottom portions of the gate well regions 25, the bottom portions of the plurality of shallow well regions 35 may be positioned on the first main surface 3 side or may be positioned on the bottom portion side of the second semiconductor region 7. The depth of the shallow well region 35 may be larger than the depth of the gate well region 25, or may be less than the depth of the gate well region 25.

In this embodiment, the deep well region 36 is positioned further to the bottom portion side of the second semiconductor region 7 than the bottom walls of the plurality of gate structures 15. The depth of the deep well region 36 is larger than the depth of the gate well region 25 and the depth of the shallow well region 35.

In this embodiment, the upper end portion of the deep well region 36 is positioned on the separating structure 30 side with respect to the bottom portions of the plurality of gate well regions 25 and the bottom portions of the plurality of shallow well regions 35. The upper end portion of the deep well region 36 faces the plurality of gate well regions 25 and the plurality of shallow well regions 35 in the horizontal direction.

The bottom portion of the deep well region 36 is positioned on the bottom portion side of the second semiconductor region 7 with respect to the bottom portions of the plurality of gate well regions 25 and the bottom portions of the plurality of shallow well regions 35. The bottom portion of the deep well region 36 does not face the plurality of gate well regions 25 and the plurality of shallow well regions 35 in the horizontal direction.

The deep well region 36 is connected to the outermost shallow well region 35 in the horizontal direction. The deep well region 36 may be formed at an interval in the horizontal direction from the outermost shallow well region 35, and may face the outermost shallow well region 35 in the horizontal direction with a portion of the second semiconductor region 7 interposed therebetween.

The deep well region 36 has a plurality (two or more) of the bulging portions 36a and one or more of the constricted portions 36b in the thickness direction of the chip 2. The plurality of bulging portions 36a include the upper bulging portion 36a and the lower bulging portion 36a.

The upper bulging portion 36a is positioned at a depth substantially equal to the depths of the bulging portions 25a of the plurality of gate well regions 25 and the bulging portions 35a of the plurality of shallow well regions 35. The upper bulging portion 36a is connected to the bulging portion 35a of the outermost shallow well region 35. The upper bulging portion 36a may be formed at an interval in the horizontal direction from the outermost shallow well region 35.

The lower bulging portion 36a is formed in a shape tapering toward the bottom portion. The lower bulging portion 36a is positioned on the bottom portion side of the second semiconductor region 7 with respect to depth positions of the bottom portions of the plurality of gate well regions 25 and the bottom portions of the plurality of shallow well regions 35, and does not face the plurality of gate well regions 25 and the plurality of shallow well regions 35 in the horizontal direction.

The constricted portion 36b is formed in a region on the separating structure 30 side with respect to the bottom portions of the plurality of gate well regions 25 and the bottom portions of the plurality of shallow well regions 35, and faces the plurality of gate well regions 25 and the plurality of shallow well regions 35 in the horizontal direction. The constricted portion 36b may be positioned on the bottom portion side of the second semiconductor region 7 with respect to the bottom portions of the plurality of gate well regions 25 and the bottom portions of the plurality of shallow well regions 35.

The constricted portion 36b is formed at an interval in the horizontal direction from the outermost shallow well region 35. The constricted portion 36b is formed in a region on the separating structure 30 side with respect to the bottom portion of the outermost shallow well region 35, and faces the outermost shallow well region 35 in the horizontal direction. The constricted portion 36b may be positioned on the bottom portion side of the second semiconductor region 7 with respect to the bottom portion of the outermost shallow well region 35.

As in the case of the semiconductor device 1A, the semiconductor device 1C includes the plurality of source openings 49 formed in the interlayer film 47. In this embodiment, the plurality of source openings 49 are respectively formed in regions between the plurality of adjacent gate structures 15, and respectively expose the source regions 11 and the plurality of gate contact regions 27.

As in the case of the semiconductor device 1A, the semiconductor device 1C includes the source electrode 51 arranged on the first main surface 3. The source electrode 51 has a laminated structure including a lower electrode film 52 and a main electrode film 53 laminated in that order from the chip 2 side. As in the case of the semiconductor device 1A, the lower electrode film 52 has a laminated structure including the first electrode film 54 and the second electrode film 55.

The first electrode film 54 collectively covers, in a film shape, a region of the interlayer film 47 in which the plurality of source openings 49 are formed, and enters the plurality of source openings 49 from above the interlayer film 47. The first electrode film 54 is mechanically and electrically connected to the source regions 11 and the plurality of gate contact regions 27 in the plurality of source opening 49.

The second electrode film 55 collectively covers, in a film shape, a region of the interlayer film 47 in which the plurality of source openings 49 are formed with the first electrode film 54 interposed therebetween, and enters the plurality of source openings 49 from above the interlayer film 47. The second electrode film 55 is electrically connected to the source regions 11 and the plurality of gate contact regions 27 via the first electrode film 54 in the plurality of source openings 49.

The main electrode film 53 collectively covers, in a film shape, a region of the interlayer film 47 in which the plurality of source openings 49 are formed, and backfills the plurality of source openings 49. The main electrode film 53 is electrically connected to the source regions 11 and the plurality of gate contact regions 27 via the lower electrode film 52 in the plurality of source openings 49.

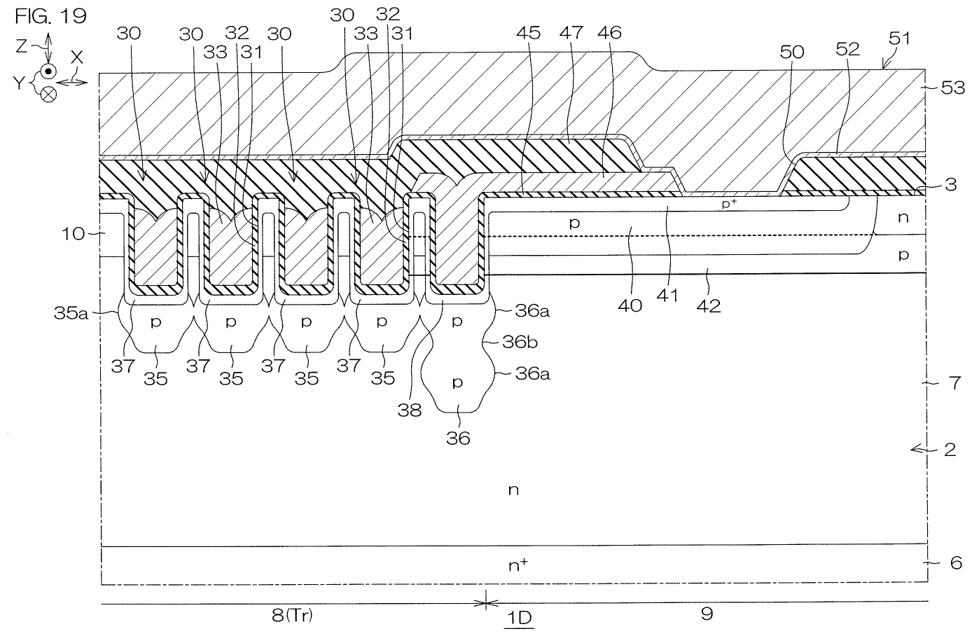

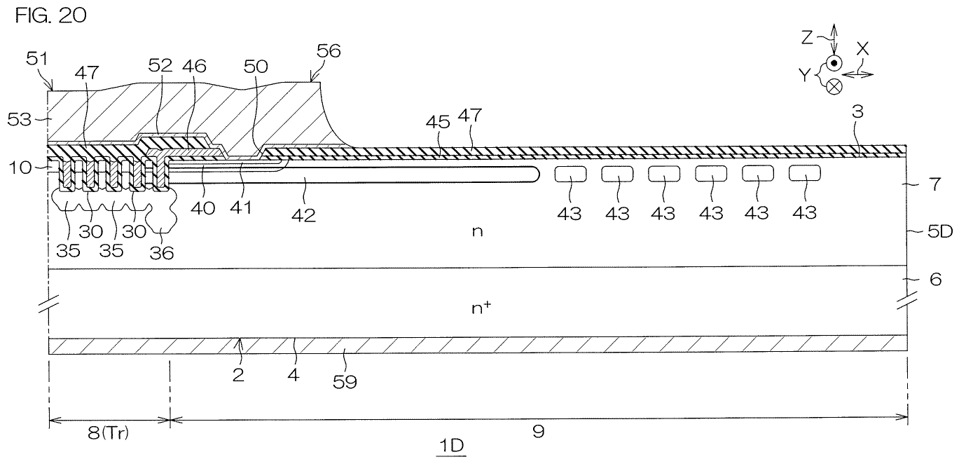

FIG. 19 is a plan view illustrating a semiconductor device 1D according to a fourth embodiment. FIG. 20 is a sectional view illustrating a peripheral edge portion of the active region 8 of the semiconductor device 1D illustrated in FIG. 19 together with the terminal region 42 according to a first configuration example. Although the deep well region 36 according to the first configuration example is illustrated in FIG. 19 and FIG. 20, as in the case of the semiconductor device 1A, the semiconductor device 1D may have at least one of the deep well regions 36 according to the first to eighth configuration examples.

As in the case of the semiconductor device 1A, the semiconductor device 1D includes the terminal region 42 formed in the surface layer portion of the first main surface 3 in the outer peripheral region 9. The terminal region 42 has a form in which the terminal region 42 according to the semiconductor device 1A is deformed. Hereinafter, portions different from the terminal region 42 according to the semiconductor device 1A shall be described, and description of common portions shall be omitted. The description of the terminal region 42 according to the semiconductor device 1A is applied to the omitted description.

As in the case of the semiconductor device 1A, the terminal region 42 has an inner edge portion on the active region 8 side and an outer edge portion on the peripheral edge side of the first main surface 3. The inner edge portion of the terminal region 42 has an inner edge portion positioned further to the active region 8 side than one or a plurality of the separating structures 30.

In this embodiment, the inner edge portion of the terminal region 42 is positioned further to the active region 8 side than the separating structure 30 (that is, the outermost separating structure 30) positioned at least on the first main surface 3 side. That is, in this embodiment, the terminal region 42 has a portion (the inner edge portion) positioned in a region between the plurality of separating structures 30. In this embodiment, the terminal region 42 is connected to the body region 10, the shallow contact region 37, and the deep contact region 38 in the active region 8.

The inner edge portion of the terminal region 42 may be connected to the separating structure 30 adjacent to the outermost separating structure 30. The inner edge portion of the terminal region 42 may be formed at an interval from the separating structure 30 adjacent to the outermost separating structure 30.

As in the case of the semiconductor device 1A, the terminal region 42 has an upper end portion positioned on the first main surface 3 side and a bottom portion positioned on the bottom portion side of the second semiconductor region 7. The arrangement of the terminal region 42 on the outer peripheral region 9 side is the same as in the case of the semiconductor device 1A. Hereinafter, the arrangement of the terminal region 42 on the active region 8 side shall be described.

The upper end portion of the terminal region 42 extends in the horizontal direction along the first main surface 3 in the active region 8. The upper end portion of the terminal region 42 is positioned on the first main surface 3 side with respect to the depth position of the bottom portion of the deep well region 36 in the active region 8.

The upper end portion of the terminal region 42 is positioned on the first main surface 3 side with respect to the depth position of the bottom portion of the shallow well region 35 in the active region 8. The upper end portion of the terminal region 42 is positioned on the first main surface 3 side with respect to the depth position of the bottom portion of the gate well region 25 in the active region 8. The upper end portion of the terminal region 42 is positioned on the first main surface 3 side with respect to the depth position of the bottom portion of the source well region 26 in the active region 8.

The upper end portion of the terminal region 42 is positioned on the first main surface 3 side with respect to the depth position of the bottom wall of the separating structure 30 in the active region 8. The upper end portion of the terminal region 42 is positioned on the first main surface 3 side with respect to the depth position of the bottom wall of the gate structure 15 in the active region 8. The upper end portion of the terminal region 42 is positioned on the first main surface 3 side with respect to the depth position of the bottom wall of the source structure 20 in the active region 8.

The upper end portion of the terminal region 42 is positioned on the first main surface 3 side with respect to the depth position of the bottom portion of the body region 10 in the active region 8, and is connected to the body region 10. The upper end portion of the terminal region 42 may be positioned on the bottom portion side of the second semiconductor region 7 with respect to the depth position of the bottom portion of the body region 10 in the active region 8.

The upper end portion of the terminal region 42 may be positioned on the bottom portion side of the second semiconductor region 7 with respect to the depth positions of the upper end portion of the shallow contact region 37 and the upper end portion of the deep contact region 38. The upper end portion of the terminal region 42 may be connected to the upper end portion of the shallow contact region 37 and the upper end portion of the deep contact region 38.

The bottom portion of the terminal region 42 extends in the horizontal direction along the first main surface 3 in the active region 8. The bottom portion of the terminal region 42 is positioned on the first main surface 3 side with respect to the depth position of the bottom portion of the deep well region 36 in the active region 8. The bottom portion of the terminal region 42 is positioned on the first main surface 3 side with respect to the depth position of the bottom portion of the shallow well region 35 in the active region 8.

The bottom portion of the terminal region 42 is positioned on the first main surface 3 side with respect to the depth position of the bottom portion of the gate well region 25 in the active region 8. The bottom portion of the terminal region 42 is positioned on the first main surface 3 side with respect to the depth position of the bottom portion of the source well region 26 in the active region 8. In this embodiment, the bottom portion of the terminal region 42 is positioned on the first main surface 3 side with respect to the depth position of the bottom wall of the separating structure 30 in the active region 8.

That is, the separating structure 30 penetrates through the inner edge portion of the terminal region 42 in the thickness direction. In this embodiment, the bottom portion of the terminal region 42 is positioned on the bottom wall side of the separating structure 30 with respect to the depth position of the bottom portion of the body region 10, and forms a pn-junction portion with the second semiconductor region 7. That is, the bottom portion of the terminal region 42 forms a pn-junction portion with the second semiconductor region 7 in the region between the plurality of separating structures 30.

The bottom portion of the terminal region 42 may be positioned on the bottom portion side of the second semiconductor region 7 with respect to the depth position of the bottom wall of the separating structure 30 in the active region 8. In this case, the bottom portion of the terminal region 42 may be connected to one or both of the shallow well region 35 and the deep well region 36.

In the active region 8, the bottom portion of the terminal region 42 may be positioned on the first main surface 3 side with respect to the depth position of the bottom wall of the gate structure 15, or may be positioned on the bottom portion side of the second semiconductor region 7 with respect to the depth position of the bottom wall of the gate structure 15. In the active region 8, the bottom portion of the terminal region 42 may be positioned on the first main surface 3 side with respect to the depth position of the bottom wall of the source structure 20, or may be positioned on the bottom portion side of the second semiconductor region 7 with respect to the depth position of the bottom wall of the source structure 20.

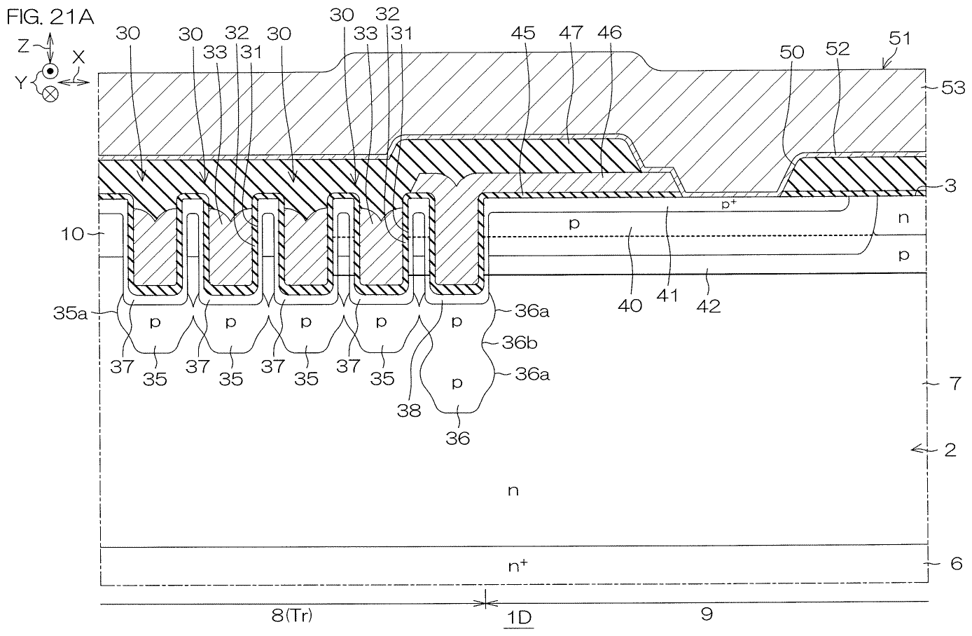

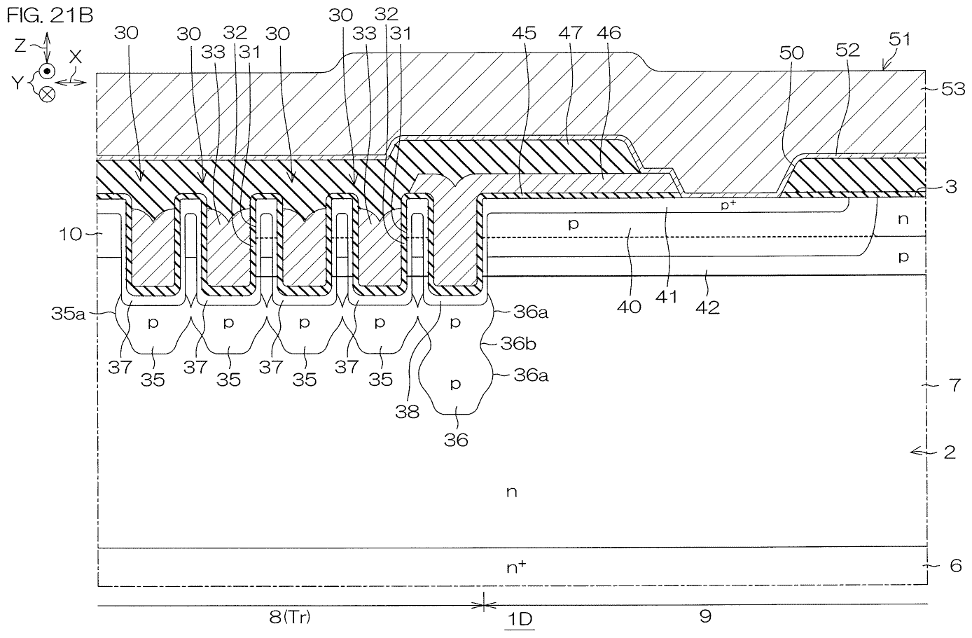

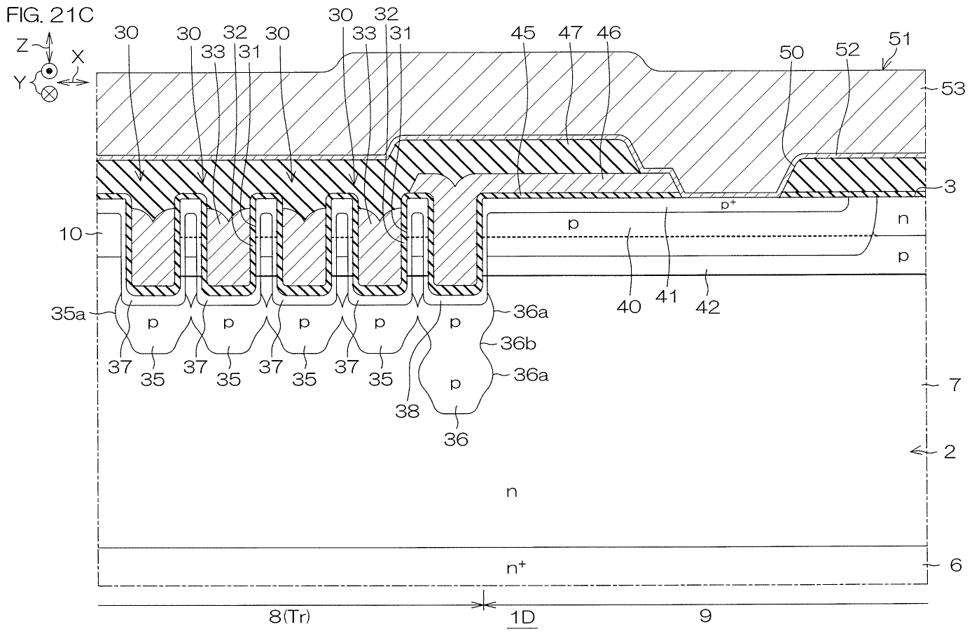

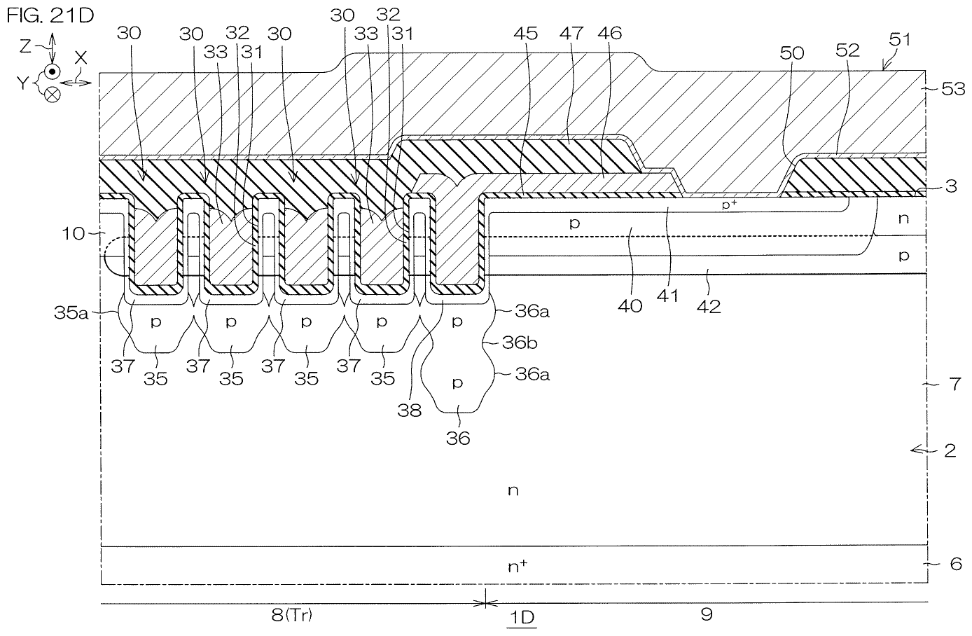

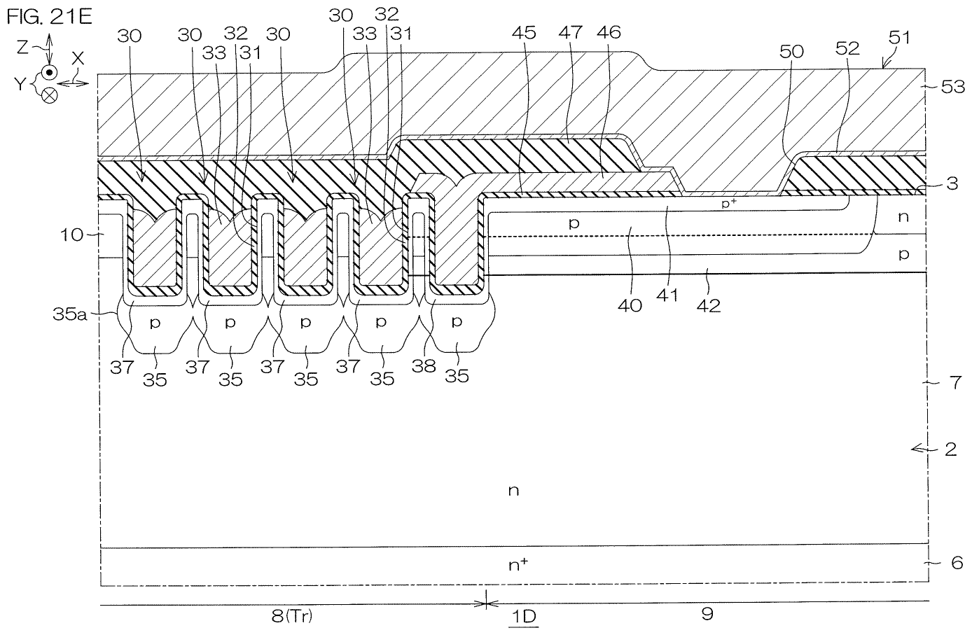

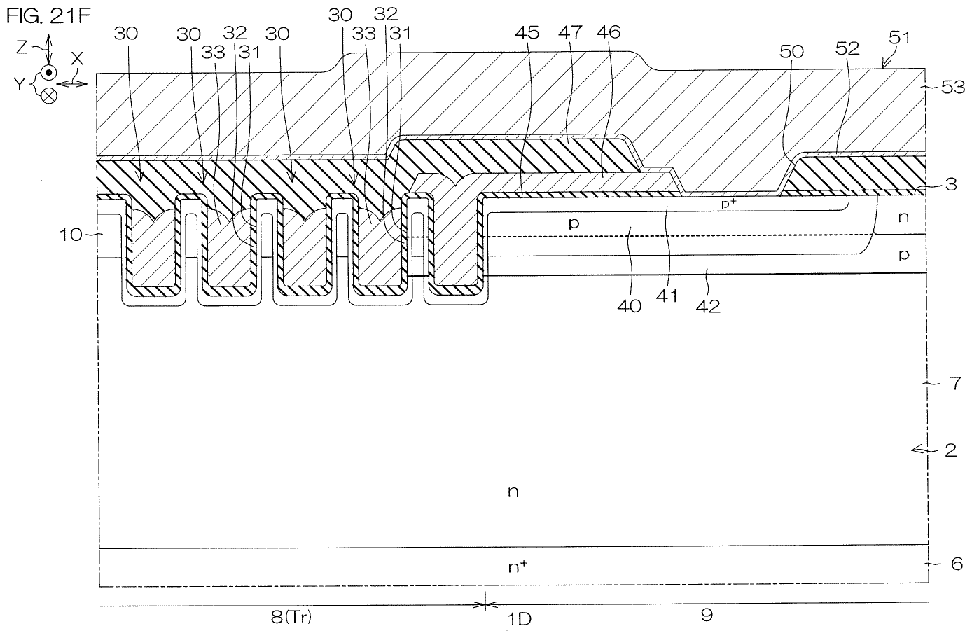

FIG. 21A to FIG. 21F are sectional views illustrating the terminal region 42 according to second to seventh configuration examples. The semiconductor device 1D may include at least one of the terminal regions 42 according to the first to seventh configuration examples. The semiconductor device 1D may include, in the same sectional region or different sectional regions, at least two of the terminal regions 42 according to the first to seventh configuration examples at the same time.

Referring to FIG. 21A (second configuration example), the inner edge portion of the terminal region 42 may be positioned further to the active region 8 side than the plurality of separating structures 30. In this embodiment, the inner edge portion of the terminal region 42 is positioned further to the active region 8 side than the two separating structures 30 including the outermost separating structure 30. The inner edge portion of the terminal region 42 may be connected to the separating structure 30 on the active region 8 side, or may be formed at an interval from the separating structure 30 on the active region 8 side.

Referring to FIG. 21B (third configuration example), the inner edge portion of the terminal region 42 may be positioned further to the active region 8 side than the plurality of separating structures 30. In this embodiment, the inner edge portion of the terminal region 42 is positioned further to the active region 8 side than the three separating structures 30 including the outermost separating structure 30. The inner edge portion of the terminal region 42 may be connected to the separating structure 30 on the active region 8 side, or may be formed at an interval from the separating structure 30 on the active region 8 side.

Referring to FIG. 21C (fourth configuration example), the inner edge portion of the terminal region 42 may be positioned further to the active region 8 side than the plurality of separating structures 30. In this embodiment, the inner edge portion of the terminal region 42 is positioned further to the active region 8 side than the four separating structures 30 including the outermost separating structure 30. The inner edge portion of the terminal region 42 may be connected to the separating structure 30 on the active region 8 side, or may be formed at an interval from the separating structure 30 on the active region 8 side.

Referring to FIG. 21D (fifth configuration example), the inner edge portion of the terminal region 42 may be positioned further to the active region 8 side than all of the separating structures 30. The inner edge portion of terminal region 42 may be positioned in the region between the innermost separating structure 30 and the outermost gate structure 15. In this case, the inner edge portion of the terminal region 42 may be connected to the gate structure 15, or may be formed at an interval from the gate structure 15. The inner edge portion of the terminal region 42 may be connected to the body region 10 in the region between the innermost separating structure 30 and the outermost gate structure 15.

The inner edge portion of terminal region 42 may be positioned in the region between the innermost separating structure 30 and the outermost source structure 20. In this case, the inner edge portion of the terminal region 42 may be connected to the source structure 20, or may be formed at an interval from the source structure 20. The inner edge portion of the terminal region 42 may be connected to the body region 10 in the region between the innermost separating structure 30 and the outermost source structure 20.

Referring to FIG. 21E (sixth configuration example), in a case where the inner edge portion of the terminal region 42 is positioned further to the active region 8 side than one or a plurality of the separating structures 30, the deep well region 36 is not necessarily formed, and the shallow well region 35 and the shallow contact region 37 may be formed for one or a plurality of the separating structures 30.

Referring to FIG. 21F (seventh configuration example), in a case where the inner edge portion of the terminal region 42 is positioned further to the active region 8 side than one or a plurality of the separating structures 30, it is not necessary to form either or both of the shallow well region 35 and the deep well region 36. In this case, one or both of the shallow contact region 37 and the deep contact region 38 do not have to be formed.

As described above, the semiconductor device 1D includes the chip 2, the second semiconductor region 7 (the semiconductor region) of the n-type, the active region 8, the outer peripheral region 9, the separating structures 30 of the trench type, and the terminal region 42 of the p-type (second conductivity type). The chip 2 has the first main surface 3. The second semiconductor region 7 is formed in the surface layer portion of the first main surface 3. The active region 8 is provided in the inner portion of the first main surface 3. The outer peripheral region 9 is provided in the peripheral edge portion of the first main surface 3.

The separating structure 30 is formed in the first main surface 3 so as to be positioned in the second semiconductor region 7, and demarcates the active region 8 and the outer peripheral region 9. The terminal region 42 is arranged on the peripheral edge side of the chip 2 with respect to the separating structure 30 so as to be positioned in the second semiconductor region 7 in the outer peripheral region 9.

According to this arrangement, the semiconductor device 1D having a novel layout can be provided. For example, according to the semiconductor device 1D, the depletion layer spreads into the second semiconductor region 7 with the terminal region 42 as a starting point. Thereby, the electric field in the vicinity of the separating structure 30 is relaxed, and a decrease in withstand voltage (breakdown voltage) due to electric field concentration is prevented. That is, a decrease in withstand voltage with a boundary region between the active region 8 and the outer peripheral region 9 as a starting point is prevented.

The chip 2 may contain SiC. According to this arrangement, the semiconductor device 1D as an SiC semiconductor device having a novel layout can be provided. According to the semiconductor device 1D, the withstand voltage is further improved by the physical properties of SiC. In particular, in the case of the SiC semiconductor device, since the SiC semiconductor device is used under a relatively high voltage environment, an electric field relaxation effect (an effect of preventing a decrease in withstand voltage) by the terminal region 42 is effective.

The terminal region 42 may have an inner edge portion positioned further to the active region 8 side than the separating structure 30. According to this arrangement, in the region further to the active region 8 side than the separating structure 30, the depletion layer spreads into the second semiconductor region 7 with the terminal region 42 as a starting point. Thereby, the electric field in the vicinity of the separating structure 30 is relaxed, and a decrease in withstand voltage (breakdown voltage) due to electric field concentration is prevented.

The plurality of separating structures 30 may be formed at an interval on the first main surface 3. In this case, the inner edge portion of the terminal region 42 may be positioned further to the active region 8 side than the outermost separating structure 30 arranged on the peripheral edge side of the chip 2. According to this arrangement, the electric field in the vicinity of the outermost separating structure 30 is relaxed, and a decrease in withstand voltage (breakdown voltage) due to electric field concentration is prevented. The inner edge portion of the terminal region 42 may be positioned further to the active region 8 side than the plurality of separating structures 30. According to this arrangement, the electric field in the vicinity of the plurality of separating structures 30 is relaxed appropriately.

The terminal region 42 may have a portion positioned on the first main surface 3 side with respect to the depth position of the bottom wall of the separating structure 30. The terminal region 42 may have a bottom portion positioned on the first main surface 3 side with respect to the depth position of the bottom wall of the separating structure 30. The terminal region 42 may be formed in the surface layer portion of the first main surface 3 at an interval from the first main surface 3.

The semiconductor device 1D may include the shallow well region 35 (well region) of the p-type. The shallow well region 35 may be formed in a region below the separating structure 30 so as to be positioned in the second semiconductor region 7, and may be electrically connected to the second semiconductor region 7.

According to this arrangement, the depletion layer spreads into the second semiconductor region 7 with the shallow well region 35 as a starting point, and at the same time, the depletion layer spreads into the second semiconductor region 7 with the terminal region 42 as a starting point. According to this arrangement, electric field concentration on the separating structures 30 is prevented by both the shallow well region 35 and the terminal region 42. In this case, the terminal region 42 may be electrically connected to the shallow well region 35. The terminal region 42 may have the bottom portion positioned on the first main surface 3 side with respect to the depth position of the bottom portion of the shallow well region 35.

The semiconductor device 1D may include the deep well region 36 (well region) of the p-type. The deep well region 36 may be formed in a region below the separating structure 30 so as to be positioned in the second semiconductor region 7, and may be electrically connected to the second semiconductor region 7.

According to this arrangement, the depletion layer spreads into the second semiconductor region 7 with the deep well region 36 as a starting point, and at the same time, the depletion layer spreads into the second semiconductor region 7 with the terminal region 42 as a starting point. According to this arrangement, electric field concentration on the separating structures 30 is prevented by both the deep well region 36 and the terminal region 42. In this case, the terminal region 42 may be electrically connected to the deep well region 36. The terminal region 42 may have the bottom portion positioned on the first main surface 3 side with respect to the depth position of the bottom portion of the deep well region 36.

The semiconductor device 1D may include the outer well region 40 of the p-type. The outer well region 40 may be arranged on the peripheral edge side of the chip 2 with respect to the separating structure 30 so as to be positioned in the second semiconductor region 7 in the outer peripheral region 9. In this case, the terminal region 42 may have a portion positioned on the peripheral edge side of the chip 2 with respect to the outer well region 40.

According to this arrangement, the depletion layer with the outer well region 40 as a starting point is expanded toward the peripheral edge side of the chip 2 by the depletion layer with the terminal region 42 as a starting point. Thereby, electric field concentration in the vicinity of the separating structure 30 is relaxed appropriately.

The terminal region 42 may be positioned lower than the bottom portion of the outer well region 40. According to this arrangement, the depletion layer with the outer well region 40 as a starting point is expanded appropriately toward the peripheral edge side of the chip 2 by the depletion layer with the terminal region 42 as a starting point.

The semiconductor device 1D may include the body region 10 of the p-type. The body region 10 may be formed in the surface layer portion of the semiconductor region in the active region 8. In this case, the separating structure 30 may be positioned in the region below the bottom portion of the body region 10. The terminal region 42 may have a portion positioned lower than the bottom portion of the body region 10.

According to this arrangement, in the active region 8, the depletion layer spreads to a shallow region with the body region 10 as a starting point. On the other hand, on the outer peripheral region 9 side, the depletion layer spreads to a deep region with the terminal region 42 as a starting point. Therefore, the edge portion of the depletion layer with the body region 10 as a starting point is spread downward by the terminal region 42 in the region on the outer peripheral region 9 side. Thereby, the electric field concentration is relaxed appropriately in the vicinity of the separating structure 30 positioned on the outer peripheral region 9 side.

The semiconductor device 1D may include the gate structures 15 of the trench type. The gate structures 15 may be formed in the first main surface 3 in the active region 8. In this case, the terminal region 42 may be formed lower than the bottom wall of the gate structure 15.

According to this arrangement, the edge portion of the depletion layer spreading to the region below the gate structure 15 is spread appropriately downward by the terminal region 42 in the region on the outer peripheral region 9 side. Thereby, the electric field concentration is relaxed appropriately in the vicinity of the separating structure 30 positioned on the outer peripheral region 9 side. The separating structure 30 may have a depth not less than the depth of the gate structure 15.

The semiconductor device 1D may include the source structures 20 of the trench type. The source structures 20 may be formed in the first main surface 3 in the active region 8. In this case, the terminal region 42 may be formed lower than the bottom wall of the source structure 20. According to this arrangement, the edge portion of the depletion layer spreading to the region below the source structure 20 is spread appropriately downward by the terminal region 42 in the region on the outer peripheral region 9 side. Thereby, the electric field concentration is relaxed appropriately in the vicinity of the separating structure 30 positioned on the outer peripheral region 9 side. The separating structure 30 may have a depth not less than the depth of the source structure 20.

The semiconductor device 1D may include the plurality of field regions 43 of the p-type. The plurality of field regions 43 may be formed, in the region between the peripheral edge of the first main surface 3 of the outer peripheral region 9 and the terminal region 42, in the surface layer portion of the second semiconductor region 7 at an interval. According to this arrangement, the depletion layer with the terminal region 42 as a starting point is expanded toward the peripheral edge side of the chip 2 by the depletion layer with the plurality of field regions 43 as starting points. Thereby, electric field concentration in the vicinity of the separating structure 30 is relaxed appropriately.

The semiconductor device 1D may include the outer wiring 46 and the source electrode 51 (terminal electrode). The outer wiring 46 may be electrically connected to the terminal region 42 on the first main surface 3. The source electrode 51 may be electrically connected to the outer wiring 46 on the first main surface 3. According to this arrangement, a source potential as a terminal potential is to be applied to the terminal region 42.

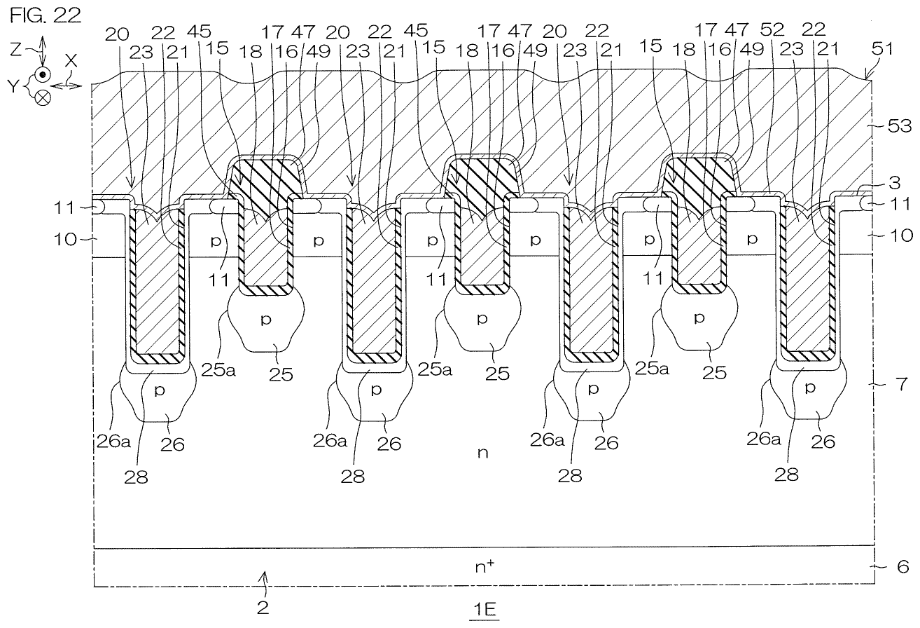

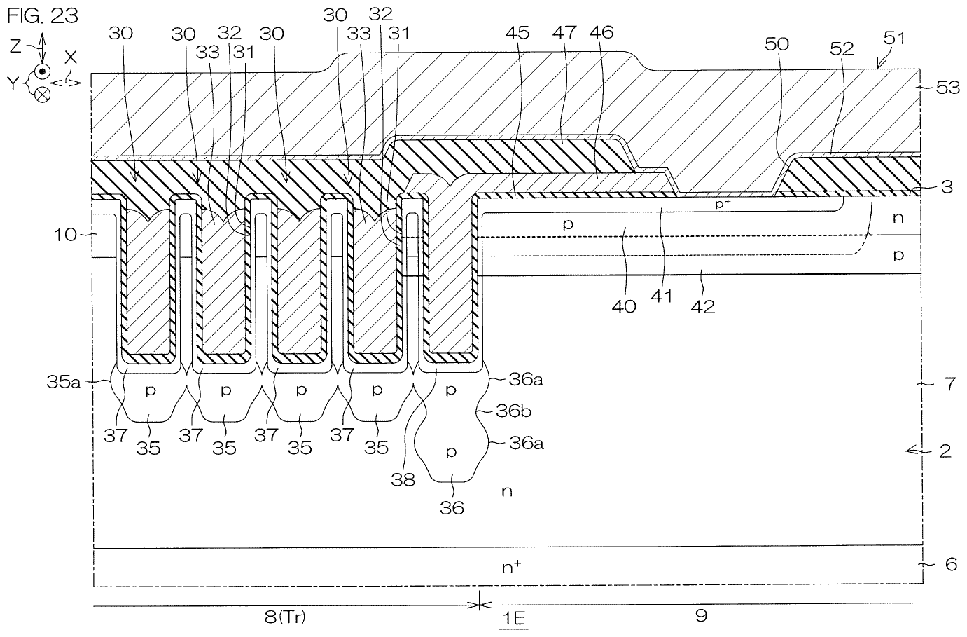

FIG. 22 is a sectional view illustrating the active region 8 of a semiconductor device 1E according to a fifth embodiment. FIG. 23 is a sectional view illustrating a peripheral edge portion of the active region 8 of the semiconductor device 1E illustrated in FIG. 22 together with the terminal region 42 according to the first configuration example.

Referring to FIG. 22 and FIG. 23, the semiconductor device 1E has an arrangement including the terminal region 42 (refer to FIG. 19) according to the first configuration example in the semiconductor device 1B. The semiconductor device 1E may include at least one of the terminal regions 42 according to the first to seventh configuration examples. The semiconductor device 1E may include, in the same sectional region or different sectional regions, at least two of the terminal regions 42 according to the first to seventh configuration examples at the same time.

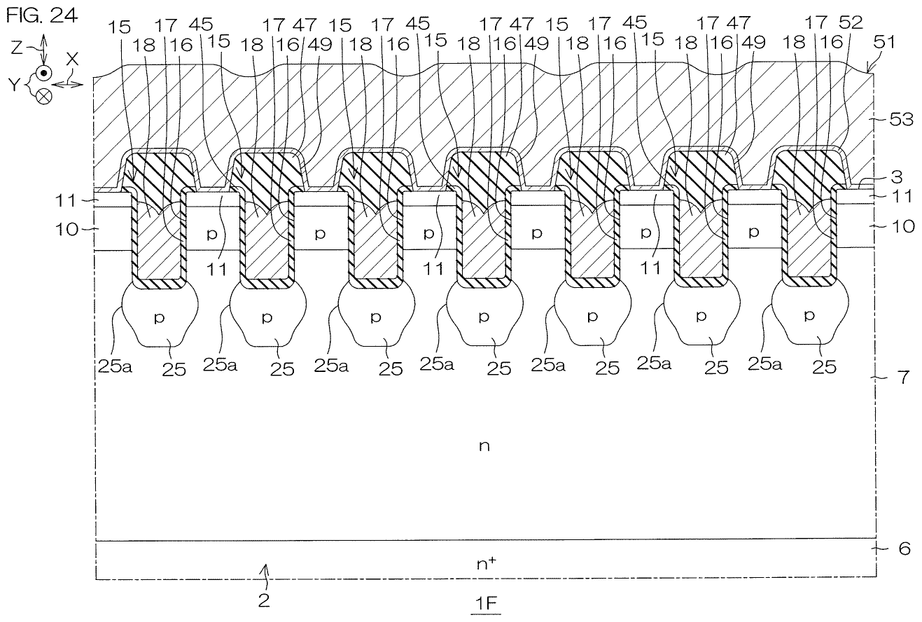

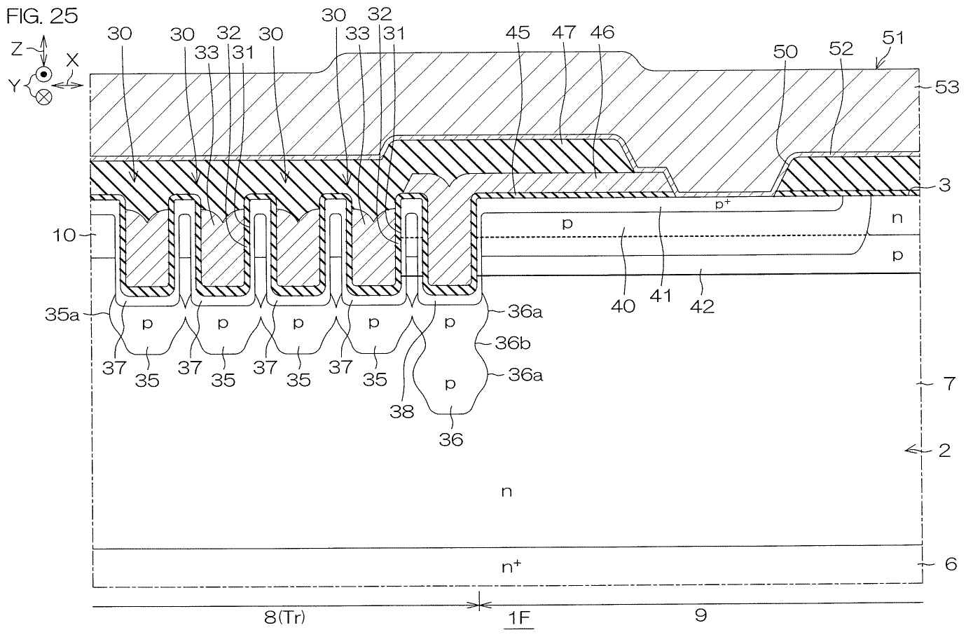

FIG. 24 is a sectional view illustrating the active region 8 of a semiconductor device 1F according to a sixth embodiment. FIG. 25 is a sectional view illustrating a peripheral edge portion of the active region 8 of the semiconductor device 1F illustrated in FIG. 24 together with the terminal region 42 according to the first configuration example.

Referring to FIG. 24 and FIG. 25, the semiconductor device 1F has an arrangement including the terminal region 42 (refer to FIG. 19) according to the first configuration example in the semiconductor device 1C. The semiconductor device 1F may include at least one of the terminal regions 42 according to the first to seventh configuration examples. The semiconductor device 1E may include, in the same sectional region or different sectional regions, at least two of the terminal regions 42 according to the first to seventh configuration examples at the same time.

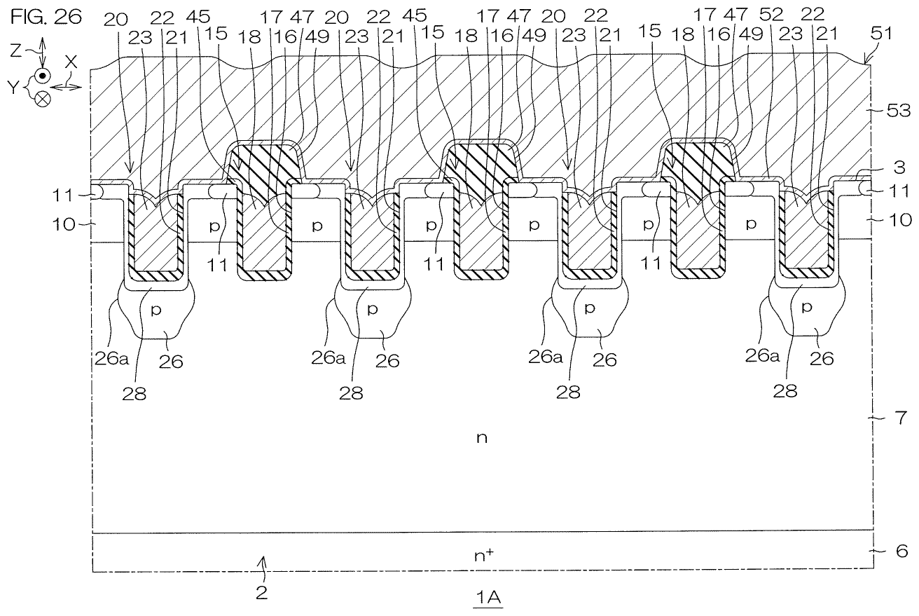

Hereinafter, modification examples applied to the semiconductor devices 1A to 1F shall be described. Hereinafter, an arrangement in which the modification example is applied to the semiconductor device 1A shall be described, but the modification example can also be applied to the semiconductor devices 1B to 1F. FIG. 26 is a sectional view illustrating a semiconductor device 1A according to a modification example. Referring to FIG. 26, the semiconductor device 1A does not necessarily have the gate well region 25 and the gate contact region 27, and the gate well region 25 and the gate contact region 27 may be removed.

The embodiments (including the modification examples) described above can be implemented in yet other modes. For example, in each of the embodiments described above, an example in which the outer wiring 46 is connected to the source electrode 51 was illustrated. However, the outer wiring 46 may be electrically disconnected from the source electrode 51. In this case, the outer wiring 46 may be formed in an electrically floating state as a floating wiring or a field wiring (a so-called field pre-plate).

In each of the embodiments described above, the chip 2 including the SiC monocrystal is adopted. However, the chip 2 may include a silicon monocrystal instead. Similarly, the first semiconductor region 6 may include a silicon monocrystal. Similarly, the second semiconductor region 7 may include a silicon monocrystal.

In each of the embodiments described above, a structure in which the conductivity type of a semiconductor region of the “n-type” is inverted to the “p-type” and the conductivity type of a semiconductor region of the “p-type” is inverted to the “n-type” may be adopted. The specific arrangement in this case is obtained by replacing “n-type” with “p-type” and replacing “p-type” with “n-type” at the same time in the above description and attached drawings.

In each of the embodiments described above, a collector region of the p-type may be formed in a surface layer portion of the second main surface 4 of the chip 2. In this case, the transistor structure Tr includes an IGBT (insulated gate bipolar transistor) structure in place of the MISFET structure. The specific arrangement in this case is obtained by replacing the “source” of the MISFET structure with an “emitter” of the IGBT structure and replacing the “drain” of the MISFET structure with a “collector” of the IGBT structure in the above description. In this case, the chip 2 may have a single layer structure constituted of a semiconductor substrate of the n-type.

Hereinafter, examples of features extracted from the present description and the drawings shall be indicated below. Hereinafter, the alphanumeric characters, etc., in parentheses represent the corresponding constituent elements, etc., in the embodiment described above, but are not intended to limit the scope of each clause to the embodiment. The “semiconductor device” in the following clauses may be replaced with an “SiC semiconductor device,” a “wide bandgap semiconductor device,” “a semiconductor switching device,” a “MISFET device,” an “IGBT device,” a “semiconductor rectifier,” etc., as needed.
[A1] A semiconductor device (1A to 1F) comprising: a chip (2) that has a main surface (3); a semiconductor region (7) of a first conductivity type (n-type) that is formed in a surface layer portion of the main surface (3); an active region (8) that is provided in an inner portion of the main surface (3); an outer peripheral region (9) that is provided in a peripheral edge portion of the main surface (3); a separating structure (30) of a trench type that is formed in the main surface (3) so as to be positioned in the semiconductor region (7) and demarcates the active region (8) and the outer peripheral region (9); and a well region (36) of a second conductivity type (p-type) that is formed in a region below the separating structure (30) so as to be positioned in the semiconductor region (7) and is electrically connected to the semiconductor region (7).
[A2] The semiconductor device (1A to 1F) according to A1, wherein the chip (2) contains SiC.
[A3] The semiconductor device (1A to 1F) according to A1 or A2, wherein the well region (36) is formed in a vertically long columnar shape extending in a thickness direction of the chip (2).
[A4] The semiconductor device (1A to 1F) according to any one of A1 to A3, wherein the well region (36) is formed at an interval toward the main surface (3) side from a bottom portion of the semiconductor region (7).
[A5] The semiconductor device (1A to 1F) according to any one of A1 to A4, wherein the well region (36) has a bulging portion (36a) that protrudes in a horizontal direction along the main surface (3) and a constricted portion (36b) that is recessed in the horizontal direction with respect to the bulging portion (36a) at a depth position different from that of the bulging portion (36a).
[A6] The semiconductor device (1A to 1F) according to any one of A1 to A5, wherein the well region (36) includes impurity regions of the second conductivity type (p-type) that are formed at different depth positions so as to be connected to each other.
[A7] The semiconductor device (1A to 1F) according to any one of A1 to A6, wherein the separating structures (30) are formed at an interval on the main surface (3), and the well region (36) is formed in a region below at least one of the separating structures (30).
[A8] The semiconductor device (1A to 1F) according to A7, wherein the well region (36) is formed in a region below the separating structure (30) positioned on the outer peripheral region (9) side among the separating structures (30).
[A9] The semiconductor device (1A to 1F) according to A7 or A8, wherein the well region (36) is not formed in a region below the separating structure (30) positioned on the active region (8) side among the separating structures (30).
[A10] The semiconductor device (1A to 1F) according to any one of A7 to A9, further comprising: a shallow well region (35) of the second conductivity type (p-type) that is formed in a region below at least one of the separating structures (30) so as to be positioned in the semiconductor region (7) and is electrically connected to the semiconductor region (7); and wherein the well region (36) has a depth larger than a depth of the shallow well region (35), and is formed in a region below the separating structure (30) in a region other than the shallow well region (35).
[A11] The semiconductor device (1A to 1F) according to A10, wherein the shallow well regions (35) are respectively formed in regions below the separating structures (30).
[A12] The semiconductor device (1A to 1F) according to any one of A1 to A11, further comprising: a body region (10) of the second conductivity type (p-type) that is formed in a surface layer portion of the semiconductor region (7) in the active region (8); and wherein the separating structure (30) is positioned in a region lower than a bottom portion of the body region (10), and the well region (36) is positioned lower than the bottom portion of the body region (10).
[A13] The semiconductor device (1A to 1F) according to any one of A1 to A12, further comprising: a gate structure (15) of the trench type that is formed in the main surface (3) in the active region (8); and wherein the well region (36) is formed lower than a bottom wall of the gate structure (15).
[A14] The semiconductor device (1A to 1F) according to A13, wherein the separating structure (30) has a depth not less than a depth of the gate structure (15).
[A15] The semiconductor device (1A to 1F) according to any one of A1 to A14, further comprising: a source structure (20) of the trench type that is formed in the main surface (3) in the active region (8); and wherein the well region (36) is formed lower than a bottom wall of the gate structure (15).
[A16] The semiconductor device (1A to 1F) according to A15, wherein the separating structure (30) has a depth not less than a depth of the source structure (20).
[A17] The semiconductor device (1A to 1F) according to any one of A1 to A16, further comprising: an outer well region (40) of the second conductivity type (p-type) that is formed in a surface layer portion of the semiconductor region (7) along the separating structure (30) in the outer peripheral region (9).
[A18] The semiconductor device (1A to 1F) according to A17, wherein the outer well region (40) has a depth smaller than a depth of the well region (36).
[A19] The semiconductor device (1A to 1F) according to any one of A1 to A18, further comprising: field regions (43) of the second conductivity type (p-type) that are formed at an interval in a surface layer portion of the semiconductor region (7) in a region between a peripheral edge of the main surface (3) and the separating structure (30).
[A20] The semiconductor device (1A to 1F) according to any one of A1 to A19, further comprising: an outer wiring (46) that is electrically connected to the separating structure (30) on the main surface (3); and a terminal electrode (51) that is electrically connected to the outer wiring (46) on the main surface (3).
[B1] A semiconductor device (1A to 1F) comprising: a chip (2) that has a main surface (3); a semiconductor region (7) of a first conductivity type (n-type) that is formed in a surface layer portion of the main surface (3); an active region (8) that is provided in an inner portion of the main surface (3); an outer peripheral region (9) that is provided in a peripheral edge portion of the main surface (3); a separating structure (30) of a trench type that is formed in the main surface (3) so as to be positioned in the semiconductor region (7) and demarcates the active region (8) and the outer peripheral region (9); and a terminal region (42) of a second conductivity type (p-type) that is arranged on a peripheral edge side of the chip (2) with respect to the separating structure (30) so as to be positioned in the semiconductor region (7) in the outer peripheral region (9).
[B2] The semiconductor device (1A to 1F) according to B1, wherein the chip (2) contains SiC.
[B3] The semiconductor device (1A to 1F) according to B1 or B2, wherein the terminal region (42) has an inner edge portion positioned further to the active region (8) side than the separating structure (30).
[B4] The semiconductor device (1A to 1F) according to B3, wherein the separating structures (30) are formed at an interval on the main surface (3), and the inner edge portion of the terminal region (42) is arranged further to the active region (8) side than the outermost separating structure (30) positioned on a peripheral edge side of the chip (2).
[B5] The semiconductor device (1A to 1F) according to B4, wherein the inner edge portion of the terminal region (42) is positioned further to the active region (8) side than the separating structures (30).
[B6] The semiconductor device (1A to 1F) according to any one of B1 to B5, wherein the terminal region (42) has a portion positioned on the main surface (3) side with respect to a depth position of a bottom wall of the separating structure (30).
[B7] The semiconductor device (1A to 1F) according to any one of B1 to B6, wherein the terminal region (42) has a bottom portion positioned on the main surface (3) side with respect to a depth position of a bottom wall of the separating structure (30).
[B8] The semiconductor device (1A to 1F) according to any one of B1 to B7, wherein the terminal region (42) is formed in a surface layer portion of the main surface (3) at an interval from the main surface (3).
[B9] The semiconductor device (1A to 1F) according to any one of B1 to B8, further comprising: a well region (35, 36) of the second conductivity type (p-type) that is formed in a region below the separating structure (30) so as to be positioned in the semiconductor region (7) and is electrically connected to the semiconductor region (7).
[B10] The semiconductor device (1A to 1F) according to B9, wherein the terminal region (42) is electrically connected to the well region (35, 36).
[B11] The semiconductor device (1A to 1F) according to B9 or B10, wherein the terminal region (42) has a bottom portion positioned on the main surface (3) side with respect to a depth position of a bottom portion of the well region (35, 36).
[B12] The semiconductor device (1A to 1F) according to any one of B1 to B11, further comprising: an outer well region (40) of the second conductivity type (p-type) that is arranged on a peripheral edge side of the chip (2) with respect to the separating structure (30) so as to be positioned in the semiconductor region (7) in the outer peripheral region (9); and wherein the terminal region (42) has a portion positioned on a peripheral edge side of the chip (2) with respect to the outer well region (40).
[B13] The semiconductor device (1A to 1F) according to B12, wherein the terminal region (42) is positioned lower than a bottom portion of the outer well region (40).
[B14] The semiconductor device (1A to 1F) according to any one of B1 to B13, further comprising: a body region (10) of the second conductivity type (p-type) that is formed in a surface layer portion of the semiconductor region (7) in the active region (8); and wherein the separating structure (30) is positioned in a region lower than a bottom portion of the body region (10), and the terminal region (42) has a portion positioned lower than the bottom portion of the body region (10).
[B15] The semiconductor device (1A to 1F) according to any one of B1 to B14, further comprising: a gate structure (15) of the trench type that is formed in the main surface (3) in the active region (8).
[B16] The semiconductor device (1A to 1F) according to B15, wherein the separating structure (30) has a depth not less than a depth of the gate structure (15).
[B17] The semiconductor device (1A to 1F) according to any one of B1 to B16, further comprising: a source structure (20) of the trench type that is formed in the main surface (3) in the active region (8).
[B18] The semiconductor device (1A to 1F) according to B17, wherein the separating structure (30) has a depth not less than a depth of the source structure (20).
[B19] The semiconductor device (1A to 1F) according to any one of B1 to B18, further comprising: field regions (43) of the second conductivity type (p-type) that are formed at an interval in a surface layer portion of the semiconductor region (7) in a region between a peripheral edge of the main surface (3) and the terminal region (42).
[B20] The semiconductor device (1A to 1F) according to any one of B1 to B19, further comprising: an outer wiring (46) that is electrically connected to the terminal region (42) on the main surface (3); and a terminal electrode (51) that is electrically connected to the outer wiring (46) on the main surface (3).
[C1] A semiconductor device (1A to 1F) comprising: a chip (2) that has a main surface (3); a first separating structure (30) of a trench type that is formed in the main surface (3); a second separating structure (30) of the trench type that is formed in the main surface (3) to be adjacent to the first separating structure (30); a first well region (35) that is formed in a region below the first separating structure (30); and a second well region (36) that is formed in a region below the second separating structure (30) and has a depth larger than a depth of the first well region (35).
[C2] A semiconductor device (1A to 1F) comprising: a chip (2) that has a main surface (3); a gate structure (15) of a trench type that is formed in the main surface (3); a separating structure (30) of the trench type that is formed in the main surface (3) at an interval from the gate structure (15); and a well region (35, 36) that is formed in a region below the separating structure (30) so as to be positioned lower than a bottom wall of the gate structure (15).
[C3] A semiconductor device (1A to 1F) comprising: a chip (2) that has a main surface (3); a source structure (20) of a trench type that is formed in the main surface (3); a separating structure (30) of the trench type that is formed in the main surface (3) at an interval from the source structure (20); and a well region (35, 36) that is formed in a region below the separating structure (30) so as to be positioned lower than a bottom wall of the source structure (20).

The features according to the items can be combined as appropriate with each other. While a specific embodiment of the present invention has been described in detail above, this is merely a specific example used to clarify the technical contents. The various technical ideas extracted from this Description can be combined as appropriate with each other without being limited by the order of description, the order of configuration examples, the order of modification examples, etc., in this Description.

What is claimed is:

1. A semiconductor device comprising:
a chip that has a main surface;
a semiconductor region of a first conductivity type that is formed in a surface layer portion of the main surface;
an active region that is provided in an inner portion of the main surface;
an outer peripheral region that is provided in a peripheral edge portion of the main surface;
a separating structure of a trench type that is formed in the main surface so as to be positioned in the semiconductor region and demarcates the active region and the outer peripheral region; and
a well region of a second conductivity type that is formed in a region below the separating structure so as to be positioned in the semiconductor region and is electrically connected to the semiconductor region.

2. The semiconductor device according to claim 1,
wherein the chip contains SiC.

3. The semiconductor device according to claim 1,
wherein the well region is formed in a vertically long columnar shape extending in a thickness direction of the chip.

4. The semiconductor device according to claim 1,
wherein the well region is formed at an interval toward the main surface side from a bottom portion of the semiconductor region.

5. The semiconductor device according to claim 1,
wherein the well region has a bulging portion that protrudes in a horizontal direction along the main surface and a constricted portion that is recessed in the horizontal direction with respect to the bulging portion at a depth position different from that of the bulging portion.

6. The semiconductor device according to claim 1,
wherein the well region includes impurity regions of the second conductivity type that are formed at different depth positions so as to be connected to each other.

7. The semiconductor device according to claim 1,
wherein the separating structures are formed at an interval on the main surface, and
the well region is formed in a region below at least one of the separating structures.

8. The semiconductor device according to claim 7,
wherein the well region is formed in a region below the separating structure positioned on the outer peripheral region side among the separating structures.

9. The semiconductor device according to claim 7,
wherein the well region is not formed in a region below the separating structure positioned on the active region side among the separating structures.

10. The semiconductor device according to claim 7, further comprising:
a shallow well region of the second conductivity type that is formed in a region below at least one of the separating structures so as to be positioned in the semiconductor region and is electrically connected to the semiconductor region; and
wherein the well region has a depth larger than a depth of the shallow well region, and is formed in a region below the separating structure in a region other than the shallow well region.

11. The semiconductor device according to claim 10,
wherein the shallow well regions are respectively formed in regions below the separating structures.

12. The semiconductor device according to claim 1, further comprising:
a body region of the second conductivity type that is formed in a surface layer portion of the semiconductor region in the active region; and
wherein the separating structure is positioned in a region lower than a bottom portion of the body region, and
the well region is positioned lower than the bottom portion of the body region.

13. The semiconductor device according to claim 1, further comprising:
a gate structure of the trench type that is formed in the main surface in the active region; and
wherein the well region is formed lower than a bottom wall of the gate structure.

14. The semiconductor device according to claim 13,
wherein the separating structure has a depth not less than a depth of the gate structure.

15. The semiconductor device according to claim 1, further comprising:
a source structure of the trench type that is formed in the main surface in the active region; and
wherein the well region is formed lower than a bottom wall of the source structure.

16. The semiconductor device according to claim 15,
wherein the separating structure has a depth not less than a depth of the source structure.

17. The semiconductor device according to claim 1, further comprising:
an outer well region of the second conductivity type that is formed in a surface layer portion of the semiconductor region along the separating structure in the outer peripheral region.

18. The semiconductor device according to claim 17,
wherein the outer well region has a depth smaller than a depth of the well region.

19. The semiconductor device according to claim 1, further comprising:
field regions of the second conductivity type that are formed at an interval in a surface layer portion of the semiconductor region in a region between a peripheral edge of the main surface and the separating structure.

20. The semiconductor device according to claim 1, further comprising:
an outer wiring that is electrically connected to the separating structure on the main surface; and
a terminal electrode that is electrically connected to the outer wiring on the main surface.
